(19) United States
(12) Patent Application Publication
(10) Pub. No.: US 2024/0186401 A1
(43) Pub. Date: Jun. 6, 2024

(54) Replacement Metal Gate Integration for Gate All Around Transistors

(71) Applicant: International Business Machines Corporation, Armonk, NY (US)

(72) Inventors: Ruqiang Bao, Niskayuna, NY (US); Effendi Leobandung, Stormville, NY (US); Eric Miller, Albany, NY (US)

(21) Appl. No.: 18/072,840

(22) Filed: Dec. 1, 2022

(51) Int. Cl. H01L 29/66; H01L 21/8238; H01L 29/423; H01L 29/775; H01L 29/786

(52) U.S. Cl. CPC H01L 29/66545; H01L 21/823821; H01L 29/42392; H01L 29/66439; H01L 29/775; H01L 29/78696

(57) ABSTRACT

Semiconductor devices having separate (i.e., non-overlapping) gate all around replacement metal gates are provided. In one aspect, a semiconductor device includes: a wafer; and at least a first transistor of a first polarity (e.g., a pFET) and a second transistor of a second polarity (e.g., an nFET) on the wafer, where a gate electrode of the first transistor and a gate electrode of the second transistor have a single pair of vertically adjoining sidewalls. The workfunction-setting metals employed in the gate electrodes of the first and second transistors can vary, as can the composition, thickness, etc. of the gate dielectric that is present beneath the gate electrodes. A method of fabricating the present semiconductor devices is also provided.

### FIELD OF THE INVENTION

The present invention relates to gate all around transistor semiconductor devices, and more particularly, to semiconductor devices having distinct gate all around replacement metal gates that are exclusive to the respective n-channel and p-channel field effect transistors of the semiconductor device, and techniques for fabrication thereof.

### BACKGROUND OF THE INVENTION

Non-planar device architectures advantageously enable beneficial design features such as gate all around field-effect transistor technology. A gate all around design provides enhanced performance even at scaled dimensions. For instance, by wrapping the gate around the channels, a significant reduction in leakage current is achieved.

Gate all around architectures often involve the integration of transistors of opposite polarity into the same device, such as p-channel field-effect transistors (pFETs) and n-channel field-effect transistors (nFETs). Doing so, however, presents some notable design challenges such as during formation of the gate structures of the transistors.

Namely, different metals can be used in the pFET gates as opposed to the nFET gates, and vice versa, in order to achieve the desired characteristics of the respective gates, pFET or nFET. Conventional integration flows involve overlapping the nFET and nFET gate metals. For instance, in an nFET-first type of integration flow, the pFET gate metals get stacked on top of the nFET gate metals in the nFET transistors. Conversely, in a pFET-first type of integration flow, the nFET gate metals get stacked on top of the pFET gate metals in the pFET transistors.

With device scaling, gate dimensions are reduced. As a result, the thinner gate metals become less effective in shielding the impact of the opposite polarity gate metal when stacked. For instance, the thinner pFET gate metals cannot completely shield the impact of the stacked nFET gate metals on the pFET transistor, and vice versa.

### SUMMARY OF THE INVENTION

The present invention provides semiconductor devices having separate (i.e., non-overlapping) gate all around replacement metal gates that are exclusive to the respective n-channel and p-channel field effect transistors. In one aspect of the invention, a semiconductor device is provided. The semiconductor device includes: a wafer; and at least a first transistor of a first polarity (e.g., a pFET) and a second transistor of a second polarity (e.g., an nFET) on the wafer, where a gate electrode of the first transistor and a gate electrode of the second transistor have a single pair of vertically adjoining sidewalls.

For instance, the single pair of vertically adjoining sidewalls can include a sidewall A of the gate electrode of the first transistor that directly contacts a sidewall B of the gate electrode of the second transistor. Since they do not overlap, the gate electrode of the first transistor is present exclusively to a side (A) of the sidewall A opposite the sidewall B. and the gate electrode of the second transistor is present exclusively to a side (B) of the sidewall B opposite the sidewall A.

Employing separate/distinct gate electrodes advantageously enables tuning of the gate materials (or combination of materials), thicknesses, etc. independently in the pFET and nFET transistors. For example, the gate electrode of the first transistor can include at least one first workfunction-setting metal and the gate electrode of the second transistor can include at least one second workfunction-setting metal, where the at least one first workfunction-setting metal is different from the at least one second workfunction-setting metal. By contrast, in conventional fabrication flows where gate materials are shared amongst the pFET and nFET transistors, there is always some overlap in their construction where the work function metal(s) and gate electrode extend from one polarity FET (for instance, nFET) to the other polarity FET (for instance, pFET).

In another aspect of the invention, another semiconductor device is provided. The semiconductor device includes: a wafer: and at least a first transistor of a first polarity and a second transistor of a second polarity on the wafer, where the first transistor includes a stack of first active layers and a first gate electrode that surrounds a portion of each of the first active layers, where the second transistor includes a stack of second active layers and a second gate electrode that surrounds a portion of each of the second active layers, and where the first gate electrode and the second gate electrode have a single pair of vertical adjoining sidewalls. For instance, the single pair of vertical adjoining sidewalls can include a sidewall A of the first gate electrode that directly contacts a sidewall B of the second gate electrode, where the first gate electrode is present exclusively to a side (A) of the sidewall A opposite the sidewall B, and where the second gate electrode is present exclusively to a side (B) of the sidewall B opposite the sidewall A.

In yet another aspect of the invention, yet another semiconductor device is provided. The semiconductor device includes: a wafer; and at least a first transistor of a first polarity and a second transistor of a second polarity on the wafer, where the first transistor includes a stack of first active layers, a first interfacial layer disposed on the stack of first active layers, a first gate dielectric disposed on the first interfacial layer, and a first gate electrode disposed on the first gate dielectric and which surrounds a portion of each of the first active layers, wherein the second transistor includes a stack of second active layers, a second interfacial layer disposed on the stack of second active layers, a second gate dielectric disposed on the second interfacial layer, and a second gate electrode disposed on the second gate dielectric and which surrounds a portion of each of the second active layers, and where the first gate electrode and the second gate electrode have a single pair of vertically adjoining sidewalls. With regard to tuning of the gate materials, the first interfacial layer and/or the first gate dielectric can have a different composition and/or thickness from the second interfacial layer and/or the second gate dielectric. For instance, the first interfacial layer and/or the first gate dielectric can have at least one different dipole dopant from the second interfacial layer and/or the second gate dielectric.

In still yet another aspect of the invention, still yet another semiconductor device is provided. The semiconductor device includes: a wafer; and at least a first transistor of a first polarity and a second transistor of a second polarity on the wafer, where the first transistor includes a stack of first active layers, a first gate electrode that surrounds a portion of each of the first active layers, and both a first gate dielectric and a gate dielectric cap disposed on the stack of first active layers beneath the first gate electrode, where the second transistor includes a stack of second active layers, a second gate electrode that surrounds a portion of each of the second active layers, and a second gate dielectric disposed on the stack of second active layers beneath the second gate electrode, and where the first gate electrode and the second gate electrode have a single pair of vertically adjoining sidewalls. In one exemplary embodiment, the gate dielectric cap is present only in the first transistor.

In a further aspect of the invention, a method of fabricating a semiconductor device is provided. The method includes: forming at least a first transistor of a first polarity and a second transistor of a second polarity on a wafer, where the first transistor includes a first gate electrode, where the second transistor includes a second gate electrode, and where the first gate electrode and the second gate electrode have a single pair of vertically adjoining sidewalls. In one exemplary embodiment, a gate-last approach is implemented where a sacrificial gate hardmask and sacrificial gate are opened individually, first over a first device stack (of the first transistor) and then over a second device stack (of the second transistor). In an alternative embodiment, a global sacrificial hardmask open stage is instead employed.

A more complete understanding of the present invention, as well as further features and advantages of the present invention, will be obtained by reference to the following detailed description and drawings.

### BRIEF DESCRIPTION OF THE DRAWINGS

FIG. 1 is a top-down diagram illustrating the overall layout of the present semiconductor device and the orientations of the Y, X1 and X2 cross-sectional views shown in the figures according to an embodiment of the present invention;

FIG. 2A is a Y cross-sectional view, FIG. 2B is an X1 cross-sectional view, and FIG. 2C is an X2 cross-sectional view illustrating at least a (first) device stack and a (second) device stack having been formed on a wafer (each first/second device stack having alternating sacrificial layers and active layers), a shallow trench isolation region having been formed in the wafer between the first/second device stacks, a sacrificial gate oxide having been formed on the first/second device stacks, a sacrificial gate having been formed on the first/second device stacks using a sacrificial gate hardmask, dielectric spacers having been formed alongside the sacrificial gate hardmask and sacrificial gate, inner spacers having been formed alongside the sacrificial layers, nFET and pFET source/drain regions having been formed on opposite sides of the sacrificial gate alongside the sacrificial layers and active layers, and an interlayer dielectric having been deposited onto the semiconductor device structure according to an embodiment of the present invention;

FIG. 3A is a Y cross-sectional view, FIG. 3B is an X1 cross-sectional view, and FIG. 3C is an X2 cross-sectional view illustrating a lithographic stack having been used to selectively open the sacrificial gate hardmask over the first device stack according to an embodiment of the present invention;

FIG. 4A is a Y cross-sectional view, FIG. 4B is an X1 cross-sectional view, and FIG. 4C is an X2 cross-sectional view illustrating the sacrificial gate having been selectively removed from the first device stack according to an embodiment of the present invention;

FIG. 5A is a Y cross-sectional view, FIG. 5B is an X1 cross-sectional view, and FIG. 5C is an X2 cross-sectional view illustrating the sacrificial gate oxide also having been selectively removed from the first device stack according to an embodiment of the present invention;

FIG. 6A is a Y cross-sectional view, FIG. 6B is an X1 cross-sectional view, and FIG. 6C is an X2 cross-sectional view illustrating the sacrificial layers in the first device stack having been selectively removed according to an embodiment of the present invention;

FIG. 7A is a Y cross-sectional view, FIG. 7B is an X1 cross-sectional view, and FIG. 7C is an X2 cross-sectional view illustrating a (first) gate dielectric and a (first) gate dielectric cap having been deposited onto, and surrounding, the active layers of the first device stack, and a (first) sacrificial placeholder having been deposited over the first gate dielectric/first gate dielectric cap according to an embodiment of the present invention;

FIG. 8A is a Y cross-sectional view, FIG. 8B is an X1 cross-sectional view, and FIG. 8C is an X2 cross-sectional view illustrating the first sacrificial placeholder having been recessed down to the first gate dielectric cap according to an embodiment of the present invention;

FIG. 9A is a Y cross-sectional view, FIG. 9B is an X1 cross-sectional view, and FIG. 9C is an X2 cross-sectional view illustrating a hardmask having been deposited onto the first gate dielectric cap in an nFET region of the wafer and onto the sacrificial placeholder in a pFET region of the wafer according to an embodiment of the present invention;

FIG. 10A is a Y cross-sectional view, FIG. 10B is an X1 cross-sectional view, and FIG. 10C is an X2 cross-sectional view illustrating a lithographic stack having been formed on the hardmask according to an embodiment of the present invention;

FIG. 11A is a Y cross-sectional view, FIG. 11B is an X1 cross-sectional view, and FIG. 11C is an X2 cross-sectional view illustrating the lithographic stack having been used to selectively open the hardmask over the second device stack, and the (patterned) hardmask having been used to open the first gate dielectric and first gate dielectric cap over the second device stack according to an embodiment of the present invention;

FIG. 12A is a Y cross-sectional view, FIG. 12B is an X1 cross-sectional view, and FIG. 12C is an X2 cross-sectional view illustrating the sacrificial gate hardmask having been removed from over the second the device stack according to an embodiment of the present invention;

FIG. 13A is a Y cross-sectional view, FIG. 13B is an X1 cross-sectional view, and FIG. 13C is an X2 cross-sectional view illustrating any remaining portions of the sacrificial gate hardmask having been removed according to an embodiment of the present invention;

FIG. 14A is a Y cross-sectional view, FIG. 14B is an X1 cross-sectional view, and FIG. 14C is an X2 cross-sectional view illustrating the sacrificial gate having been removed from over the second device stack according to an embodiment of the present invention;

FIG. 15A is a Y cross-sectional view, FIG. 15B is an X1 cross-sectional view, and FIG. 15C is an X2 cross-sectional view illustrating the underlying sacrificial gate oxide having been selectively removed from the second device stack according to an embodiment of the present invention;

FIG. 16A is a Y cross-sectional view, FIG. 16B is an X1 cross-sectional view, and FIG. 16C is an X2 cross-sectional view illustrating exposed portions of the first gate dielectric and the first gate dielectric cap in the nFET region of the wafer having been removed according to an embodiment of the present invention;

FIG. 17A is a Y cross-sectional view, FIG. 17B is an X1 cross-sectional view, and FIG. 17C is an X2 cross-sectional view illustrating the sacrificial layers in the second device stack having been selectively removed according to an embodiment of the present invention;

FIG. 18A is a Y cross-sectional view, FIG. 18B is an X1 cross-sectional view, and FIG. 18C is an X2 cross-sectional view illustrating a (second) gate dielectric and a (second) gate dielectric cap having been deposited onto, and surrounding, the active layers of the second device stack, and a (second) sacrificial placeholder having been deposited over the second gate dielectric/second gate dielectric cap according to an embodiment of the present invention;

FIG. 19A is a Y cross-sectional view, FIG. 19B is an X1 cross-sectional view, and FIG. 19C is an X2 cross-sectional view illustrating a reliability anneal being performed according to an embodiment of the present invention;

FIG. 20A is a Y cross-sectional view, FIG. 20B is an X1 cross-sectional view, and FIG. 20C is an X2 cross-sectional view illustrating the second sacrificial placeholder and the second gate dielectric cap having been selectively removed from the nFET region of the wafer according to an embodiment of the present invention;

FIG. 21A is a Y cross-sectional view, FIG. 21B is an X1 cross-sectional view, and FIG. 21C is an X2 cross-sectional view illustrating an (nFET) gate electrode having been formed on the second gate dielectric surrounding a portion of each of the active layers in the second device stack in a gate all around configuration according to an embodiment of the present invention;

FIG. 22A is a Y cross-sectional view, FIG. 22B is an X1 cross-sectional view, and FIG. 22C is an X2 cross-sectional view illustrating the nFET gate electrode and second gate dielectric having been recessed down to the first sacrificial placeholder according to an embodiment of the present invention;

FIG. 23A is a Y cross-sectional view, FIG. 23B is an X1 cross-sectional view, and FIG. 23C is an X2 cross-sectional view illustrating the first sacrificial placeholder having been selectively removed according to an embodiment of the present invention;

FIG. 24A is a Y cross-sectional view, FIG. 24B is an X1 cross-sectional view, and FIG. 24C is an X2 cross-sectional view illustrating exposed portions of the second gate dielectric having been removed according to an embodiment of the present invention;

FIG. 25A is a Y cross-sectional view, FIG. 25B is an X1 cross-sectional view, and FIG. 25C is an X2 cross-sectional view illustrating a (pFET) gate electrode having been formed on the first gate dielectric/first gate dielectric cap surrounding a portion of each of the active layers in the first device stack in a gate all around configuration according to an embodiment of the present invention;

FIG. 26A is a Y cross-sectional view, FIG. 26B is an X1 cross-sectional view, and FIG. 26C is an X2 cross-sectional view illustrating the pFET gate electrode having been recessed down to the nFET gate electrode according to an embodiment of the present invention;

FIG. 27A is a Y cross-sectional view, FIG. 27B is an X1 cross-sectional view, and FIG. 27C is an X2 cross-sectional view, which follow from FIG. 2A, FIG. 2B and FIG. 2C, respectively, illustrating according to an alternative embodiment the sacrificial gate hardmask having been fully removed following patterning of the sacrificial gate according to an embodiment of the present invention;

FIG. 28A is a Y cross-sectional view, FIG. 28B is an X1 cross-sectional view, and FIG. 28C is an X2 cross-sectional view illustrating a masking layer having been formed on the sacrificial gate according to an embodiment of the present invention;

FIG. 29A is a Y cross-sectional view, FIG. 29B is an X1 cross-sectional view, and FIG. 29C is an X2 cross-sectional view illustrating a lithographic stack having been formed on the masking layer over the nFET region of the wafer according to an embodiment of the present invention;

FIG. 30A is a Y cross-sectional view, FIG. 30B is an X1 cross-sectional view, and FIG. 30C is an X2 cross-sectional view illustrating the lithographic stack having been used to selectively open the masking layer and the sacrificial gate over the first device stack according to an embodiment of the present invention;

FIG. 31A is a Y cross-sectional view, FIG. 31B is an X1 cross-sectional view, and FIG. 31C is an X2 cross-sectional view illustrating what remains of the lithographic stack after patterning the masking layer and the sacrificial gate having been removed according to an embodiment of the present invention;

FIG. 32A is a Y cross-sectional view, FIG. 32B is an X1 cross-sectional view, and FIG. 32C is an X2 cross-sectional view illustrating the sacrificial gate oxide having been selectively removed from the first device stack according to an embodiment of the present invention;

FIG. 33A is a Y cross-sectional view, FIG. 33B is an X1 cross-sectional view, and FIG. 33C is an X2 cross-sectional view illustrating the sacrificial layers in the first device stack having been selectively removed according to an embodiment of the present invention;

FIG. 34A is a Y cross-sectional view, FIG. 34B is an X1 cross-sectional view, and FIG. 34C is an X2 cross-sectional view illustrating a (first) gate dielectric and a (first) gate dielectric cap having been deposited onto, and surrounding, the active layers of the first device stack, and a (first) sacrificial placeholder having been deposited over the first gate dielectric/first gate dielectric cap according to an embodiment of the present invention;

FIG. 35A is a Y cross-sectional view, FIG. 35B is an X1 cross-sectional view, and FIG. 35C is an X2 cross-sectional view illustrating the first sacrificial placeholder having been recessed down to the first gate dielectric cap according to an embodiment of the present invention;

FIG. 36A is a Y cross-sectional view, FIG. 36B is an X1 cross-sectional view, and FIG. 36C is an X2 cross-sectional view illustrating a hardmask having been deposited onto the first gate dielectric cap in an nFET region of the wafer and onto the first sacrificial placeholder in a pFET region of the wafer according to an embodiment of the present invention;

FIG. 37A is a Y cross-sectional view, FIG. 37B is an X1 cross-sectional view, and FIG. 37C is an X2 cross-sectional view illustrating a lithographic stack having been formed on the hardmask according to an embodiment of the present invention;

FIG. 38A is a Y cross-sectional view, FIG. 38B is an X1 cross-sectional view, and FIG. 38C is an X2 cross-sectional view illustrating the lithographic stack having been used to selectively open the hardmask over the second device stack, and the (patterned) hardmask having been used to open the first gate dielectric and first gate dielectric cap over the second device stack according to an embodiment of the present invention;

FIG. 39A is a Y cross-sectional view, FIG. 39B is an X1 cross-sectional view, and FIG. 39C is an X2 cross-sectional view illustrating the remaining masking layer over the second device stack having been removed, as well as the underlying sacrificial gate according to an embodiment of the present invention;

FIG. 40A is a Y cross-sectional view, FIG. 40B is an X1 cross-sectional view, and FIG. 40C is an X2 cross-sectional view illustrating the sacrificial gate oxide having been removed from the second device stack according to an embodiment of the present invention;

FIG. 41A is a Y cross-sectional view, FIG. 41B is an X1 cross-sectional view, and FIG. 41C is an X2 cross-sectional view illustrating exposed portions of the first gate dielectric in the nFET region of the wafer having been removed according to an embodiment of the present invention;

FIG. 42A is a Y cross-sectional view, FIG. 42B is an X1 cross-sectional view, and FIG. 42C is an X2 cross-sectional view illustrating the remaining hardmask and exposed portions of the first gate dielectric cap in the nFET region of the wafer having been removed according to an embodiment of the present invention;

FIG. 43A is a Y cross-sectional view, FIG. 43B is an X1 cross-sectional view, and FIG. 43C is an X2 cross-sectional view illustrating the sacrificial layers in the second device stack having been selectively removed according to an embodiment of the present invention;

FIG. 44A is a Y cross-sectional view, FIG. 44B is an X1 cross-sectional view, and FIG. 44C is an X2 cross-sectional view illustrating a (second) gate dielectric and a (second) gate dielectric cap having been deposited onto, and surrounding, the active layers of the second device stack, and a (second) sacrificial placeholder having been deposited over the second gate dielectric/second gate dielectric cap according to an embodiment of the present invention;

FIG. 45A is a Y cross-sectional view, FIG. 45B is an X1 cross-sectional view, and FIG. 45C is an X2 cross-sectional view illustrating a reliability anneal being performed according to an embodiment of the present invention;

FIG. 46A is a Y cross-sectional view, FIG. 46B is an X1 cross-sectional view, and FIG. 46C is an X2 cross-sectional view illustrating the second sacrificial placeholder and the second gate dielectric cap having been selectively removed from the nFET region of the wafer according to an embodiment of the present invention;

FIG. 47A is a Y cross-sectional view, FIG. 47B is an X1 cross-sectional view, and FIG. 47C is an X2 cross-sectional view illustrating an (nFET) gate electrode having been formed on the second gate dielectric surrounding a portion of each of the active layers in the second device stack in a gate all around configuration according to an embodiment of the present invention;

FIG. 48A is a Y cross-sectional view, FIG. 48B is an X1 cross-sectional view, and FIG. 48C is an X2 cross-sectional view illustrating the nFET gate electrode and second gate dielectric having been recessed down to the first sacrificial placeholder according to an embodiment of the present invention;

FIG. 49A is a Y cross-sectional view, FIG. 49B is an X1 cross-sectional view, and FIG. 49C is an X2 cross-sectional view illustrating the first sacrificial placeholder having been selectively removed, followed by exposed portions of the second gate dielectric having been removed according to an embodiment of the present invention;

FIG. 50A is a Y cross-sectional view, FIG. 50B is an X1 cross-sectional view, and FIG. 50C is an X2 cross-sectional view illustrating a (pFET) gate electrode having been formed on the first gate dielectric/first gate dielectric cap surrounding a portion of each of the active layers in the first device stack in a gate all around configuration according to an embodiment of the present invention; and

FIG. 51A is a Y cross-sectional view, FIG. 51B is an X1 cross-sectional view, and FIG. 51C is an X2 cross-sectional view illustrating the pFET gate electrode having been recessed down to the nFET gate electrode according to an embodiment of the present invention.

### DETAILED DESCRIPTION OF PREFERRED EMBODIMENTS

Provided herein are semiconductor devices having distinct (i.e., non-vertically-overlapping) gate all around replacement metal gates that are exclusive to the respective n-channel and p-channel field effect transistors, i.e., nFET and pFET transistors, of the semiconductor device. As will be described in detail below, the present techniques involve selectively releasing the channels of the transistor(s) of a first polarity, followed by the formation of a first interfacial layer/first gate dielectric on the (first) channels, and deposition of a first sacrificial placeholder. The process is then repeated to release the channels of the transistor(s) of a second polarity, followed by the formation of a second interfacial layer/second gate dielectric on the (second) channels, and deposition of a second sacrificial placeholder. The first/second sacrificial placeholders can then be individually removed and replaced with the respective gate metals, without any stacking or otherwise vertical overlapping of the materials.

Given the above overview, an exemplary methodology for fabricating a semiconductor device in accordance with the present techniques having distinct (i.e., non-overlapping) pFET and nFET gate all around replacement metal gates is now described by way of reference to FIGS. 1-26. FIG. 1 is a top-down diagram illustrating an overall layout of the present semiconductor device design. As shown in FIG. 1, the present techniques employ a device architecture having at least one pFET and at least one nFET. As will become apparent from the description that follows, pFET(s) and nFET(s) are arbitrarily selected in the process flow as the transistors of the first polarity and second polarity, respectively. However, this selection is made merely as a non-limiting example in order to illustrate the present techniques. It is to be understood that the present processes are not limited to the fabrication of the pFET and nFET transistors in any particular order, and embodiments are contemplated herein where the nFET(s) and pFET(s) are the transistors of the first polarity and second polarity, respectively, and are fabricated in the same manner described.

As will be described in detail below, the pFET and nFET active areas (labeled ‘pFET’ and ‘nFET’ in FIG. 1) will each include a stack of active layers. At least one sacrificial gate will be formed over the pFET and nFET active areas. As shown in FIG. 1, the sacrificial gate is oriented orthogonal to the pFET and nFET active areas. The term ‘sacrificial,’ as used herein, refers to a material or structure that is used in one part of the process, and then later removed, in whole or in part, during fabrication of the semiconductor device. Thus, as is apparent from FIG. 1, a gate-last approach will be employed in the present examples. With a gate-last approach, a sacrificial gate is used as a placeholder during formation of the source/drain regions. The sacrificial gate is removed later on in the process, and replaced with the final gates of the device (also referred to herein as ‘replacement gates’). When the replacement gates are metal gates, they may also be referred to herein as ‘replacement metal gates.’ Advantageously, use of a gate-last process avoids exposing the replacement gate materials such as high-k dielectrics to potentially damaging conditions such as the high temperatures experienced during source/drain region formation. Thus, the orientation of the replacement metal gates vis-à-vis the pFET and nFET active areas will be the same as that of the sacrificial gate. Notably, as will become apparent from the description that follows, the sacrificial gate will later be replaced with separate and distinct (i.e., non-overlapping) pFET and nFET replacement metal gates that, while in contact with one another, do not vertically overlap one another.

FIG. 1 further illustrates the orientations of the cross-sectional views that will be shown in the following figures. For instance, as shown in FIG. 1, the Y cross-sectional views that will be shown in the following figures depict cuts perpendicular to the pFET and nFET active areas through the sacrificial gate. The X1 cross-sectional views depict cuts through the nFET active area perpendicular to the sacrificial gate. The X2 cross-sectional views depict cuts through the pFET active area perpendicular to the sacrificial gate.

Advantageously, the present techniques enable tuning of both the gate dielectric and replacement metal gate materials (or combination of materials), thicknesses, etc. fully separately in the pFET and nFET transistors. For example, as will be described in detail below, the gate dielectric materials, their thicknesses, etc. can be varied for the pFET vis-à-vis the nFET transistors, and vice versa. Similarly, different metals or different combinations of metals, their thicknesses, etc. can be varied for the pFET vis-à-vis the nFET transistors, and vice versa. By contrast, in conventional fabrication flows where gate materials are shared amongst the pFET and nFET transistors, there is always some overlap in their construction.

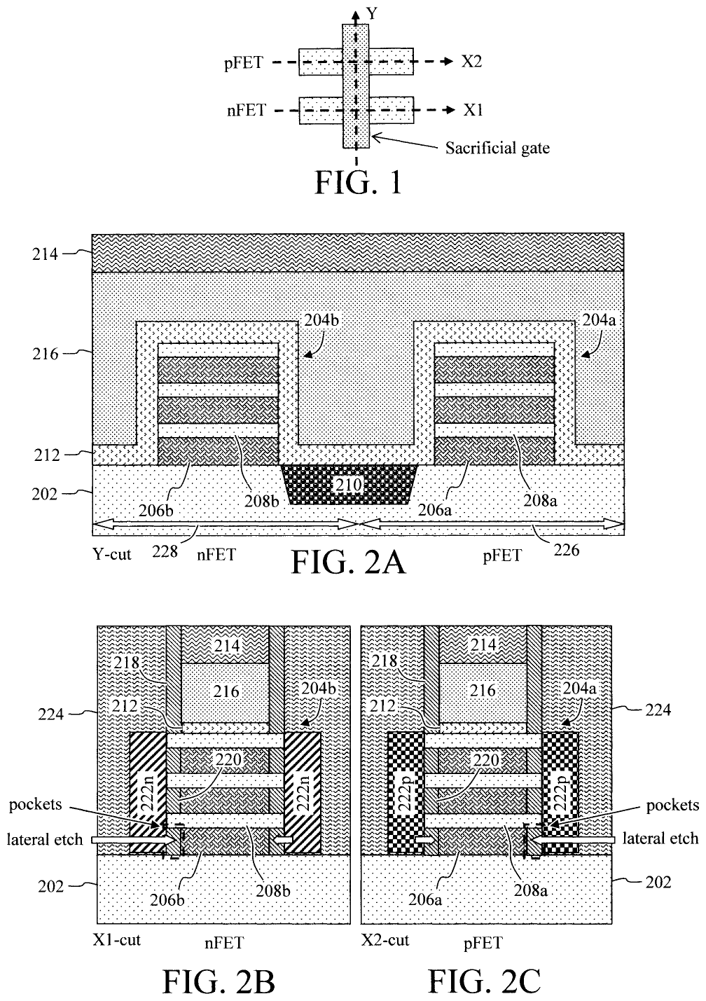

As shown in FIG. 2A (a Y cross-sectional view), FIG. 2B (an X1 cross-sectional view), and FIG. 2C (an X2 cross-sectional view), the process begins with the formation of at least a (first) device stack 204a and a (second) device stack 204b on a wafer 202 (each device stack 204a/b having alternating sacrificial layers 206a/b and active layers 208a/b), a shallow trench isolation region 210 is then formed in the wafer 202 between the device stacks 204a and 204b, a sacrificial gate oxide 212 is formed on the device stacks 204a and 204b, a sacrificial gate 216 is formed on the device stacks 204a and 204b (over the sacrificial gate oxide 212) using a sacrificial gate hardmask 214, dielectric spacers 218 are formed alongside the sacrificial gate hardmask 214 and sacrificial gate 216, inner spacers 220 are formed alongside the sacrificial layers 206a/b, pFET and nFET and source/drain regions 222p and 222n are formed on opposite sides of the sacrificial gate 216 alongside the sacrificial layers 206a/b and active layers 208a/b, and an interlayer dielectric 224 is deposited onto the semiconductor device structure.

According to an exemplary embodiment, wafer 202 is a bulk semiconductor wafer, such as a bulk silicon (Si), bulk germanium (Ge), bulk silicon germanium (SiGe) and/or bulk III-V semiconductor wafer. Alternatively, wafer 202 can be a semiconductor-on-insulator (SOI) wafer. A SOI wafer includes a SOI layer separated from an underlying substrate by a buried insulator. When the buried insulator is an oxide it is also referred to herein as a buried oxide or BOX. The SOI layer can include any suitable semiconductor material(s), such as Si, Ge, SiGe and/or a III-V semiconductor. Further, wafer 202 may already have pre-built structures (not shown) such as transistors, diodes, capacitors, resistors, interconnects, wiring, etc.

As highlighted above, each of device stacks 204a and 204b includes alternating sacrificial layers 206a/b and active layers 208a/b oriented horizontally one on top of another on the wafer 202. In one exemplary embodiment, the sacrificial layers 206a/b and active layers 208a/b are nanosheets. The term “nanosheet” as used herein, generally refers to a sheet or a layer having nanoscale dimensions. Further, the term “nanosheet” is meant to encompass other nanoscale structures such as nanowires. For instance, the term “nanosheet” can refer to a nanowire with a larger width, and/or the term “nanowire” can refer to a nanosheet with a smaller width, and vice versa. In the non-limiting example depicted in the figures, the device stack 204a corresponds to a pFET transistor that will be formed on the wafer 202 and device stack 204b corresponds to an nFET transistor that will be formed on the wafer 202. Again, this selection is arbitrary. Further, for clarity, reference may also be made herein to the region of the wafer 202 on which the pFET transistor will be formed (i.e., the pFET region of wafer 202—see arrow 226) and the region of the wafer 202 on which the nFET transistor will be formed (i.e., nFET region of wafer 202—see arrow 228).

As will be described in detail below, the sacrificial layers 206a/b will be removed later on in the process to permit the formation of a gate all around configuration for the semiconductor device. By contrast, the active layers 208a/b will remain in place and serve as channels of the pFET and nFET transistors. It is notable that the number of sacrificial layers 206a/b and active layers 208a/b shown in the figures is provided merely as an example to illustrate the present techniques. For instance, embodiments are contemplated herein where more or fewer sacrificial layers 206a/b and/or more or fewer active layers 208a/b are present than shown. According to an exemplary embodiment, each of the sacrificial layers 206a/b and each of the active layers 208a/b is deposited/formed on wafer 202 using an epitaxial growth process. According to an exemplary embodiment, each of the sacrificial layers 206a/b and each of the active layers 208a/b has a thickness of from about 3 nanometers (nm) to about 25 nm.

The materials employed for the sacrificial layers 206a/b and active layers 208a/b are such that the sacrificial layers 206a/b can be removed selective to the active layers 208a/b during fabrication. For instance, according to an exemplary embodiment, the sacrificial layers 206a/b are each formed from SiGe, while the active layers 208a/b are formed from Si. Etchants such as wet hot SC1, vapor phase hydrogen chloride (HCl), vapor phase chlorine trifluoride (CIF₃) and other reactive clean processes (RCP) are selective for etching of SiGe versus Si. This is, however, only one exemplary combination of sacrificial/active material that may be employed in accordance with the present techniques. For instance, by way of example only, the opposite configuration can instead be implemented where the sacrificial layers 206a/b are each formed from Si, and the active layers 208a/b are each formed from SiGe.

Shallow trench isolation region 210 serves to isolate the device stacks 204a and 204b. To form the shallow trench isolation region 210, a trench is patterned in the wafer 202 in between the device stacks 204a and 204b. A dielectric such as an oxide (which may also be generally referred to herein as a ‘shallow trench isolation oxide’) is then deposited into, and filling, the trench, followed by planarization and recess. Although not explicitly shown in the figures, a liner (e.g., a thermal oxide or silicon nitride (SiN)) may be deposited into the trench prior to the shallow trench isolation oxide. Suitable shallow trench isolation oxides include, but are not limited to, oxide low-K materials such as silicon oxide (SiOx) and/or oxide ultralow-K interlayer dielectric (ULK-ILD) materials, e.g., having a dielectric constant κ of less than 2.7. Suitable ultralow-K dielectric materials include, but are not limited to, porous organosilicate glass (pSiCOH). A process such as chemical vapor deposition (CVD), atomic layer deposition (ALD), or physical vapor deposition (PVD) can be employed to deposit the shallow trench isolation oxide, after which the shallow trench isolation oxide can be planarized using a process such as chemical mechanical polishing. The shallow trench isolation oxide is then recessed using a dry or wet etch process.

According to an exemplary embodiment, the sacrificial gate oxide 212 is formed on the device stacks 204a and 204b having a thickness of from about 1 nm to about 3 nm. Suitable materials for the sacrificial gate oxide 212 include, but are not limited to, SiOx. To form the sacrificial gate 216, a sacrificial gate material is first blanket deposited onto the device stacks 204a and 204b over the sacrificial gate oxide 212. Suitable sacrificial gate materials include, but are not limited to, poly-silicon and/or amorphous silicon. A process such as CVD, ALD or PVD can be employed to deposit the sacrificial gate material onto the device stacks 204a and 204b.

The sacrificial gate hardmask 214 is then formed on the sacrificial gate material. Suitable materials for sacrificial gate hardmask 214 include, but are not limited to, silicon nitride (SiN), silicon dioxide (SiO₂), titanium nitride (TiN) and/or silicon oxynitride (SiON). Standard lithography and etching techniques can be employed to pattern the sacrificial gate hardmask 214. With standard lithography and etching techniques, a lithographic stack (not shown), e.g., photoresist/anti-reflective coating/organic planarizing layer, is used to pattern the sacrificial gate hardmask 214 with the footprint and location of the sacrificial gate 216. Alternatively, the sacrificial gate hardmask 214 can be formed by other suitable techniques, including but not limited to, sidewall image transfer (SIT), self-aligned double patterning (SADP), self-aligned quadruple patterning (SAQP), and other self-aligned multiple patterning (SAMP). An etch employing the sacrificial gate hardmask 214 is then used to pattern the sacrificial gate material into the sacrificial gate 216 shown in FIGS. 2A-C.

To form the dielectric spacers 218, a dielectric spacer material is first deposited over the device stacks 204a and 204b, followed by a directional (anisotropic) etching process such as reactive ion etching to pattern the dielectric spacer material into the dielectric spacers 218 alongside the sacrificial gate hardmask 214 and sacrificial gate 216. Suitable dielectric spacer materials include, but are not limited to, SiOx, silicon carbide (SiC), silicon oxycarbide (SiCO). SiN, silicoboron carbonitride (SiBCN) and/or silicon oxycarbonitride (SiOCN), which can be deposited using a process such as CVD, ALD or PVD.

To form the inner spacers 220, a selective lateral etch is performed to first recess the sacrificial layers 206a/b. This recess etch forms pockets along the sidewalls of the device stacks 204a and 204b that are then filled with a dielectric spacer material to form the inner spacers 220 within the pockets. The inner spacers 220 will serve to offset the replacement metal gates (see below) from the pFET and nFET source/drain regions 222p and 222n. As provided above, the sacrificial layers 206a/b can be formed from SiGe. In that case, a SiGe-selective non-directional (isotropic) etching process can be used for the recess etch. Suitable dielectric spacer materials for inner spacers 220 include, but are not limited to, silicon nitride (SiN), SiOx, SiC and/or SiCO. A process such as CVD. ALD or PVD can be employed to deposit the dielectric spacer material into the pockets, after which excess spacer material can be removed using an isotropic etching process such as reactive ion etching.

According to an exemplary embodiment, the pFET and nFET source/drain regions 222p and 222n are each formed from an in-situ doped (i.e., during growth) or ex-situ doped (e.g., via ion implantation) epitaxial material such as epitaxial Si, epitaxial SiGe, etc. Suitable p-type dopants for pFET source/drain regions 222p include, but are not limited to, boron (B). Suitable n-type dopants for nFET source/drain regions 222n include, but are not limited to, phosphorous (P) and/or arsenic (As). With inner spacers 220 in place along the sidewalls of the device stacks 204a and 204b, epitaxial growth of the pFET and nFET source/drain regions 222p and 222n is templated only from the ends of the active layers 208a/b along the sidewalls of the device stacks 204a and 204b.

Following formation of the pFET and nFET source/drain regions 222p and 222n, interlayer dielectric 224 is deposited onto the semiconductor device structure. Suitable interlayer dielectric 224 materials include, but are not limited to, silicon nitride (SiN), SiOC and/or oxide low-K materials such as SiOx and/or oxide ULK-ILD materials such as pSiCOH, which can be deposited onto the semiconductor device structure using a process such as CVD, ALD or PVD. Following deposition, the interlayer dielectric 224 can be planarized using a process such as chemical mechanical polishing.

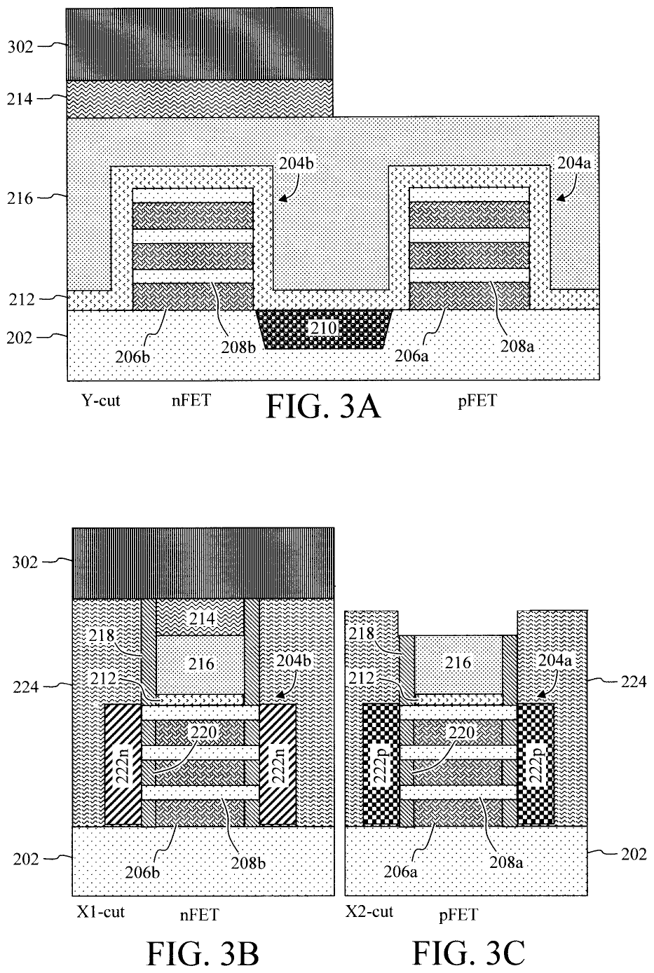

As shown in FIG. 3A (a Y cross-sectional view), FIG. 3B (an X1 cross-sectional view), and FIG. 3C (an X2 cross-sectional view), a lithographic stack 302 is used to selectively open the sacrificial gate hardmask 214 over the device stack 204a. While not explicitly shown in the figures, as described above, the lithographic stack 302 can contain a combination of layers. e.g., photoresist/anti-reflective coating/organic planarizing layer. A directional, i.e., anisotropic, etching process such as reactive ion etching can be employed to transfer the pattern from the lithographic stack 302 to the sacrificial gate hardmask 214, thereby opening the sacrificial gate hardmask 214 over the device stack 204a. After patterning the sacrificial gate hardmask 214, what remains of the lithographic stack 302 is removed. In this particular example, device stack 204a corresponds to the transistor(s) of a first polarity, more specifically a pFET transistor. However, as highlighted above, this pFET-first process flow is merely an example, and is in no way intended to limit the present techniques to any given order of fabrication.

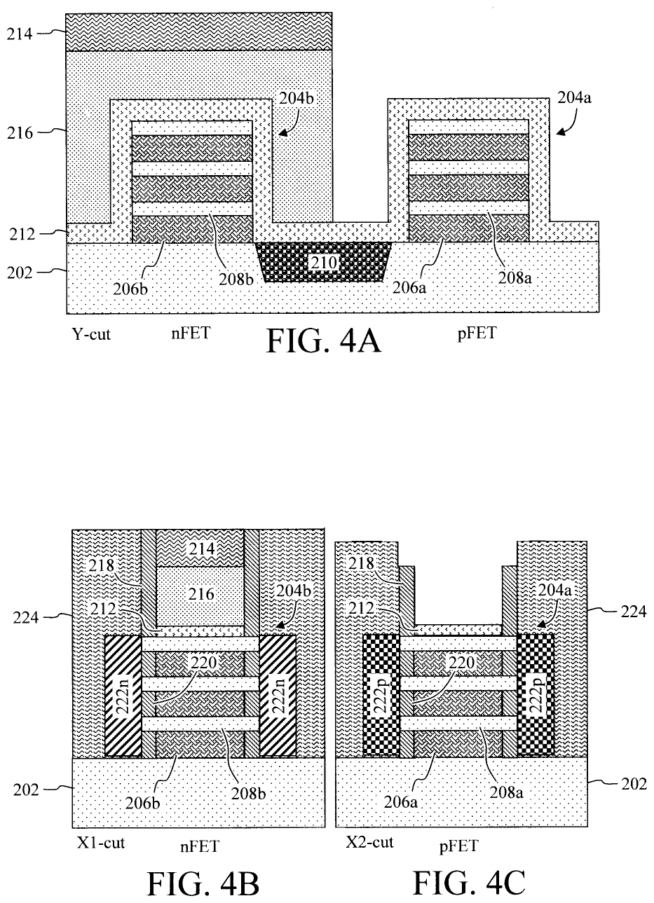

As shown in FIG. 4A (a Y cross-sectional view), FIG. 4B (an X1 cross-sectional view), and FIG. 4C (an X2 cross-sectional view), opening of the sacrificial gate hardmask 214 enables the selective removal of the sacrificial gate 216 from the device stack 204a. As provided above, the sacrificial gate 216 can be formed from poly-silicon and/or amorphous silicon. In that case, a poly-silicon and/or amorphous silicon-selective etch can be employed to remove the sacrificial gate 216 from the device stack 204a.

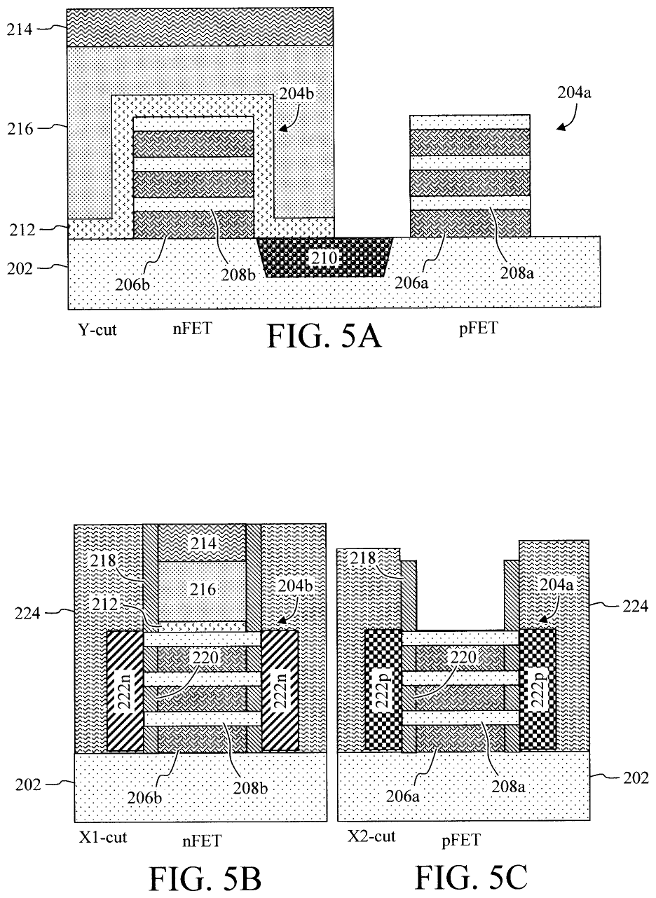

As shown in FIG. 5A (a Y cross-sectional view), FIG. 5B (an X1 cross-sectional view), and FIG. 5C (an X2 cross-sectional view), removal of the sacrificial gate 216 from the device stack 204a exposes the underlying sacrificial gate oxide 212, which is then also removed from the device stack 204a. An oxide-selective etching process may be employed to remove the sacrificial gate oxide 212.

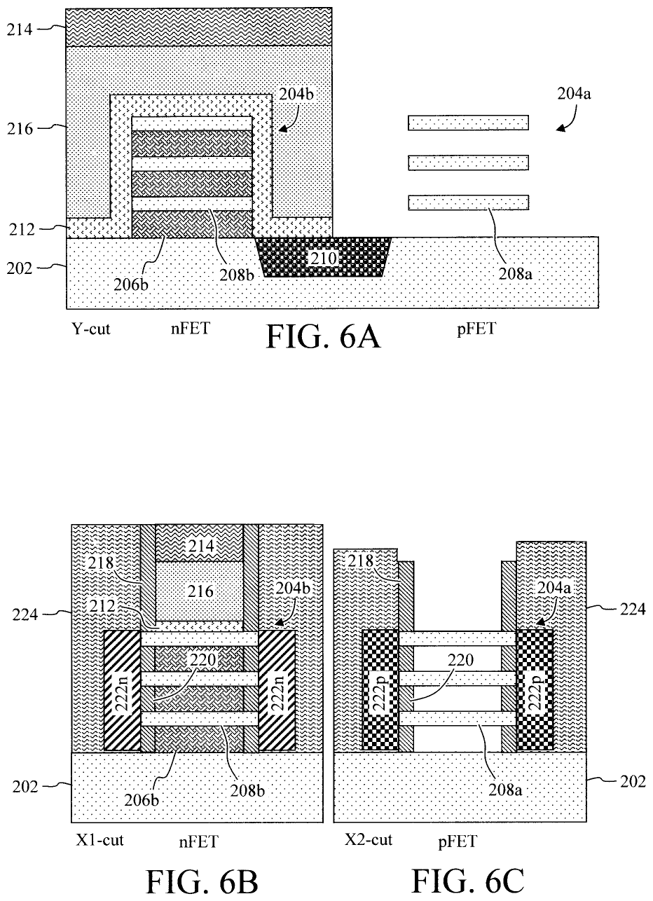

As shown in FIG. 6A (a Y cross-sectional view), FIG. 6B (an X1 cross-sectional view), and FIG. 6C (an X2 cross-sectional view), the now-exposed sacrificial layers 206a in the device stack 204a are then removed selective to the active layers 208a. According to an exemplary embodiment, the sacrificial layers 206a are formed from SiGe, while the active layers 208a are formed from Si. In that case, etchants such as wet hot SC1, vapor phase HCl, vapor phase ClF₃ and/or other reactive clean processes can be employed to remove the sacrificial layers 206a selective to the active layers 208a. Removal of the sacrificial layers 206a releases the active layers 208a from the device stack 204a. As highlighted above, these ‘released’ active layers 208a will be used to form the channels of the pFET transistor(s). Notably, at this point in the process, the sacrificial gate oxide 212 and sacrificial gate hardmask 214/sacrificial gate 216 remain covering the sacrificial layers 206b and active layers 208b of the device stack 204b.

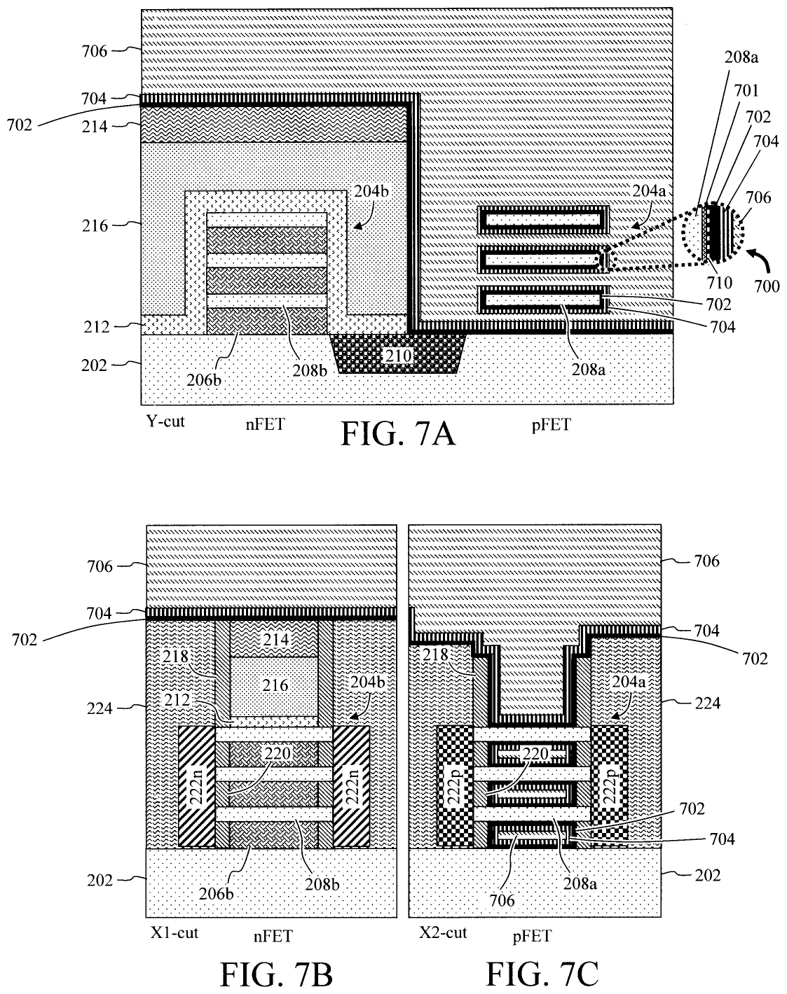

As shown in FIG. 7A (a Y cross-sectional view), FIG. 7B (an X1 cross-sectional view), and FIG. 7C (an X2 cross-sectional view), a (first) gate dielectric 702 and a (first) gate dielectric cap 704 are next deposited onto, and surrounding, the active layers 208a of the device stack 204a, and a (first) sacrificial placeholder 706 is deposited over the gate dielectric 702/gate dielectric cap 704. As shown in FIGS. 7A-C, deposition of the gate dielectric 702 and gate dielectric cap 704 in this manner also deposits these materials on the exposed surface of the wafer 202 beneath the device stack 204a, as well as on the top and sidewalls of the sacrificial gate hardmask 214/sacrificial gate 216 which remain present over the device stack 204b.

Referring to magnified view 700 in FIG. 7A, prior to depositing the gate dielectric 702, a (first) interfacial layer 701 is preferably first formed on the active layers 208a. Use of an interfacial layer 701 improves the channel/gate dielectric interface quality and channel carrier mobility. Suitable materials for the interfacial layer 701 include but are not limited to oxide materials such as SiOx. According to an exemplary embodiment, the interfacial layer 701 has a thickness of from about 0.5 nm to about 3 nm and ranges therebetween.

According to an exemplary embodiment, the thickness and/or composition of the interfacial layer 701 and/or the gate dielectric 702 in the pFET transistor differs from the thickness and/or composition of the interfacial layer and/or the gate dielectric in the nFET transistor (see below). For instance, an optional dipole layer 710 can be deposited onto the interfacial layer 701 prior to the gate dielectric 702. A subsequent reliability anneal (see below) will also serve to diffuse the metal or metals from the dipole layer 710 into the interfacial layer 701 and gate dielectric 702. Doing so can be used to tune the threshold voltage of the pFET transistor relative to the nFET transistor, or vice versa. As a result, the device will have different pFET and nFET threshold voltages. Suitable metals for the dipole layer 710 include, but are not limited to, lanthanum (La), yttrium (Y), magnesium (Mg) and/or gallium (Ga). By way of example only, the dipole layer 710 can have a thickness of from about 0.5 angstroms (Å) to about 30 Å. Following the reliability anneal (performed below), the interfacial layer 701 and the gate dielectric 702 will each contain at least one dipole dopant, e.g., La, Y, Mg and/or Ga. Preferably, different dipole dopants are used in the pFET versus nFET interfacial layer/gate dielectric in order to achieve different threshold voltages.

Additionally, the interfacial layer 701 and/or the gate dielectric 702 in the pFET transistor can optionally receive different treatments (e.g., oxidation and nitridation) from the interfacial layer and/or the gate dielectric (see below) in the nFET transistor in order to improve device performance. For example, according to an exemplary embodiment, an oxidation treatment is performed on the interfacial layer 701 and/or gate dielectric 702 before depositing the gate dielectric cap 704. As will be described in detail below, a nitridation treatment is preferably performed only for the nFET interfacial layer/gate dielectric, while the pFET interfacial layer/gate dielectric remains nitrogen-free.

Furthermore, even if the same material (e.g., HfO₂) is used as the gate dielectric 702 in the pFET transistor and as the gate dielectric in the nFET transistor, embodiments are contemplated herein where the gate dielectric used in the nFET transistor is thicker than gate dielectric 702 used in the pFET transistor. For example, as will be described in detail below, the thickness of the nFET gate dielectric is preferably from about 1 Å to about 2 Å greater than the thickness of the pFET gate dielectric 702.

In one exemplary embodiment, the gate dielectric 702 is a high-k material. The term “high-κ,” as used herein, refers to a material having a relative dielectric constant κ which is much higher than that of silicon dioxide (e.g., a dielectric constant κ=25 for hafnium oxide (HfO₂) rather than 4 for SiO₂). Suitable high-k gate dielectrics include, but are not limited to, hafnium oxide (HfO₂), lanthanum oxide (La₂O₃), hafnium-lanthanum oxide (HfLaO₂), hafnium zirconium oxide (HfZrO₂) and/or hafnium aluminum oxide (HfAlO₂). A process such as CVD, ALD or PVD can be employed to deposit the gate dielectric 702. According to an exemplary embodiment, gate dielectric 702 has a thickness of from about 1 nm to about 5 nm and ranges therebetween.

Suitable materials for the gate dielectric cap 704 include, but are not limited to, metal nitrides such as titanium nitride (TiN) and/or tantalum nitride (TaN), which can be deposited using a process such as CVD, ALD or PVD. According to an exemplary embodiment, the gate dielectric cap 704 has a thickness of from about 1 nm to about 10 nm and ranges therebetween. The gate dielectric cap 704 will serve to protect the gate dielectric 702 during subsequent processing steps including during later removal of the sacrificial placeholder 706 (see below).

Suitable materials for the sacrificial placeholder 706 include, but are not limited to, poly-silicon and/or amorphous silicon. A process such as CVD. ALD or PVD can be employed to deposit the sacrificial placeholder 706 material over the gate dielectric 702/gate dielectric cap 704. As will be described in detail below, the sacrificial placeholder 706 will be removed later on in the process, and replaced with the workfunction-setting metal(s) and optional fill metal(s) to complete the replacement metal gate of (in this case) the pFET transistor. As shown in FIGS. 7A-C, the sacrificial placeholder 706 fully covers the gate dielectric 702/gate dielectric cap 704 even over the device stack 204b. However, a subsequent polishing will remove that overburden from the nFET region of the wafer 202.

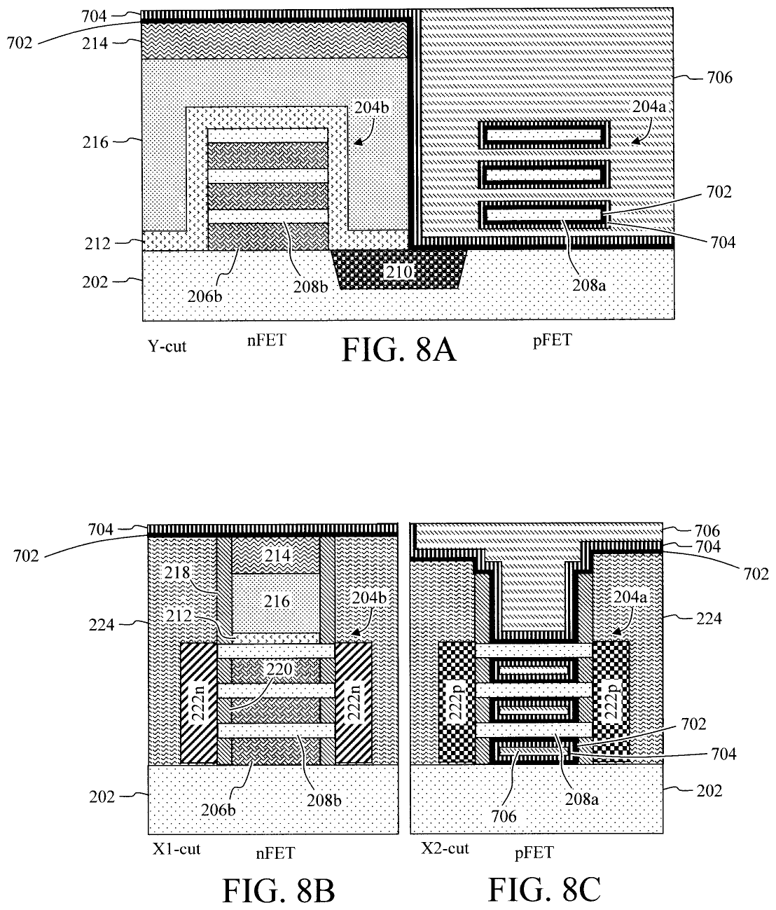

Namely, as shown in FIG. 8A (a Y cross-sectional view), FIG. 8B (an X1 cross-sectional view), and FIG. 8C (an X2 cross-sectional view), the sacrificial placeholder 706 is recessed down to the dielectric cap 704. This recessing of the sacrificial placeholder 706 can be performed using a process such as chemical mechanical polishing. The sacrificial placeholder 706 is now removed from the nFET region of wafer 202.

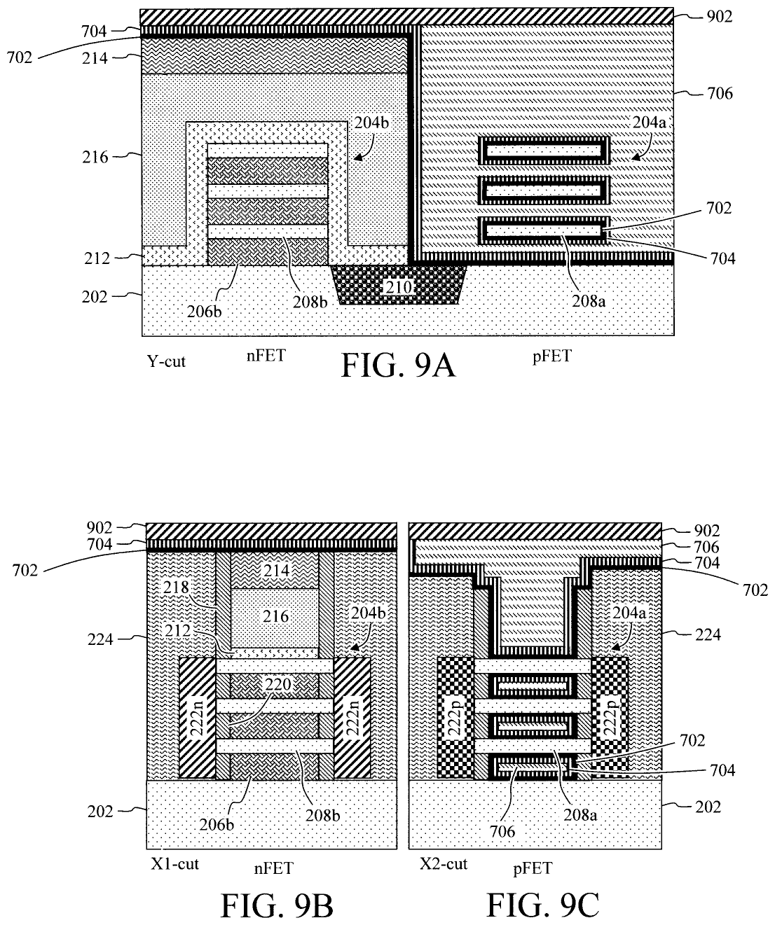

As shown in FIG. 9A (a Y cross-sectional view), FIG. 9B (an X1 cross-sectional view), and FIG. 9C (an X2 cross-sectional view), a hardmask 902 is next deposited onto the gate dielectric cap 704 in the nFET region of the wafer 202 and onto the sacrificial placeholder 706 in the pFET region of the wafer 202. As provided above, suitable hardmask materials include, but are not limited to, include, but are not limited to, SiN, SiO₂, TiN and/or SiON. According to an exemplary embodiment, the hardmask 902 has a thickness of from about 2 nm to about 10 nm and ranges therebetween. As will be described in detail below, the hardmask 902 will be used to remove the sacrificial gate hardmask 214, sacrificial gate 216 and sacrificial gate oxide 212 from the device stack 204b (in the nFET region of the wafer 202).

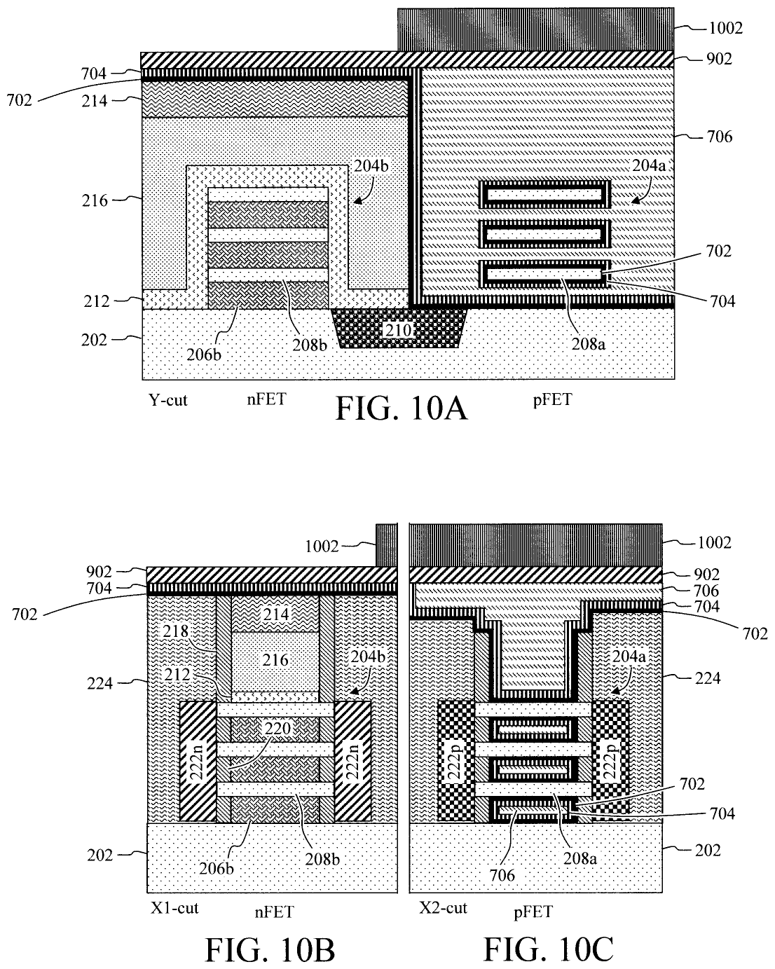

To do so, as shown in FIG. 10A (a Y cross-sectional view), FIG. 10B (an X1 cross-sectional view), and FIG. 10C (an X2 cross-sectional view), a lithographic stack 1002 is first formed on the hardmask 902. While not explicitly shown in the figures, as described above, the lithographic stack 1002 can contain a combination of layers, e.g., photoresist/anti-reflective coating/organic planarizing layer.

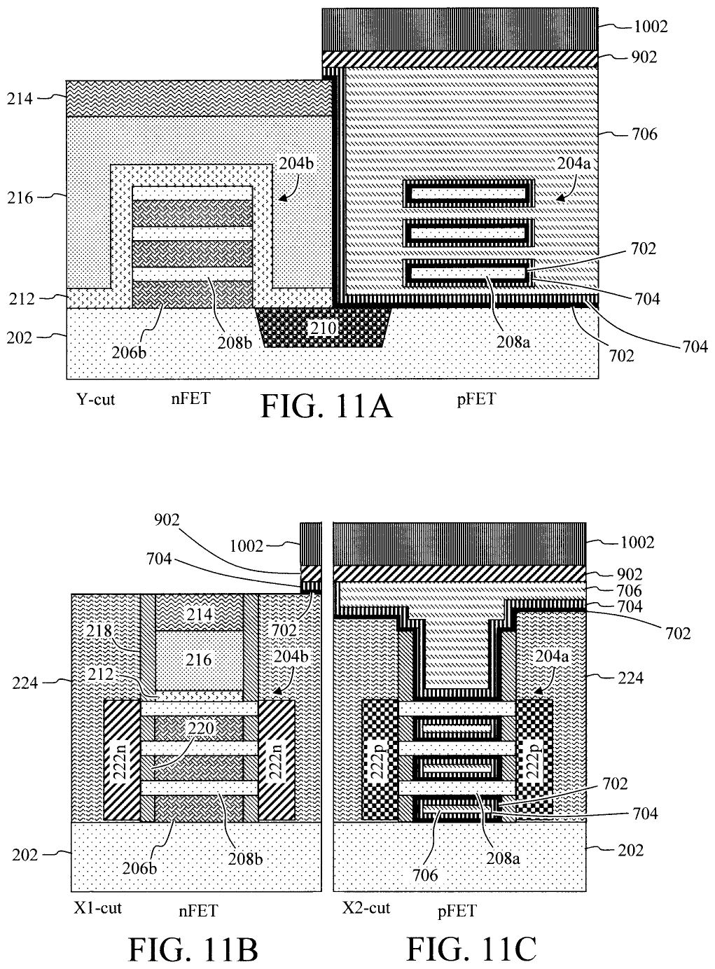

Next, as shown in FIG. 11A (a Y cross-sectional view), FIG. 11B (an X1 cross-sectional view), and FIG. 11C (an X2 cross-sectional view), the lithographic stack 1002 is used to selectively open the hardmask 902 over the device stack 204b. A directional, i.e., anisotropic, etching process such as reactive ion etching can be employed to transfer the pattern from the lithographic stack 1002 to the hardmask 902, thereby opening the hardmask 902 over the device stack 204b. After patterning the hardmask 902, what remains of the lithographic stack 1002 is removed. The (patterned) hardmask 902 is then used to open the gate dielectric 702 and gate dielectric cap 704 over the device stack 204b. A directional, i.e., anisotropic, etching process such as reactive ion etching can be employed to pattern the gate dielectric 702 and gate dielectric cap 704.

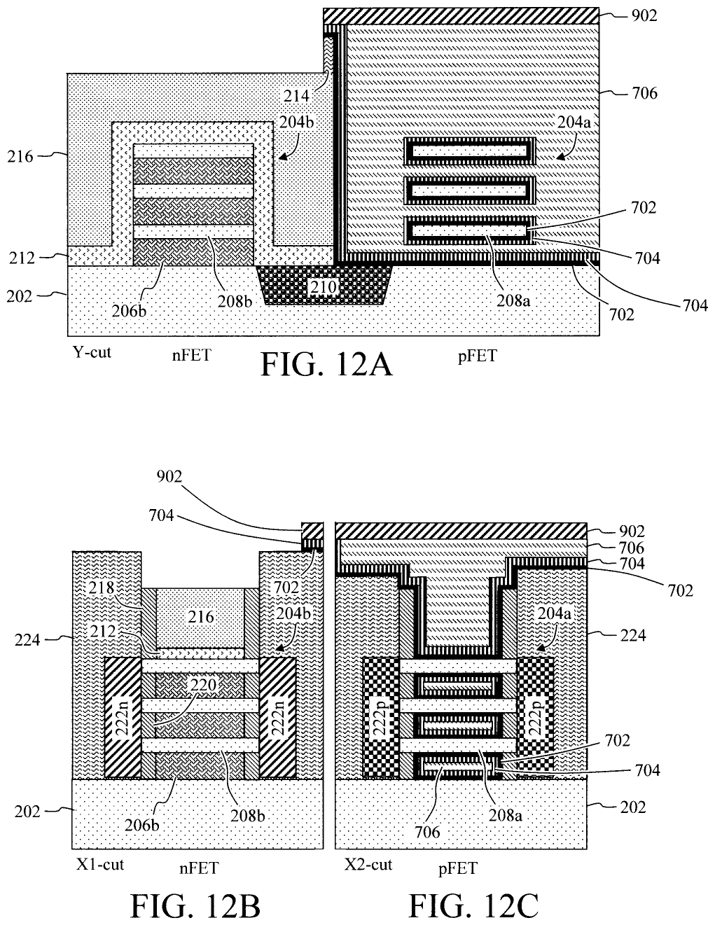

The sacrificial gate hardmask 214 over the device stack 204b is now exposed. As shown in FIG. 12A (a Y cross-sectional view), FIG. 12B (an X1 cross-sectional view), and FIG. 12C (an X2 cross-sectional view), the sacrificial gate hardmask 214 is then removed. As provided above, the sacrificial gate hardmask 214 can be formed from nitride and/or oxide materials such as SiN, SiO₂, TiN and/or SiON. In that case, a nitride- and/or oxide-selective directional, i.e., anisotropic, etching process such as reactive ion etching can be employed to remove the exposed sacrificial gate hardmask 214. It is notable that, depending on the particular hardmask and spacer materials being used, and the selectivity of the etch, some erosion of the dielectric spacers 218 can occur. See, e.g., FIG. 12B. It is also notable that, as shown in FIG. 12A, any overhang of the hardmask 902, gate dielectric 702 and gate dielectric cap 704 can result in a sliver of the sacrificial gate hardmask 214 to remain. That sliver of the sacrificial gate hardmask 214 is, however, removed in the next step.

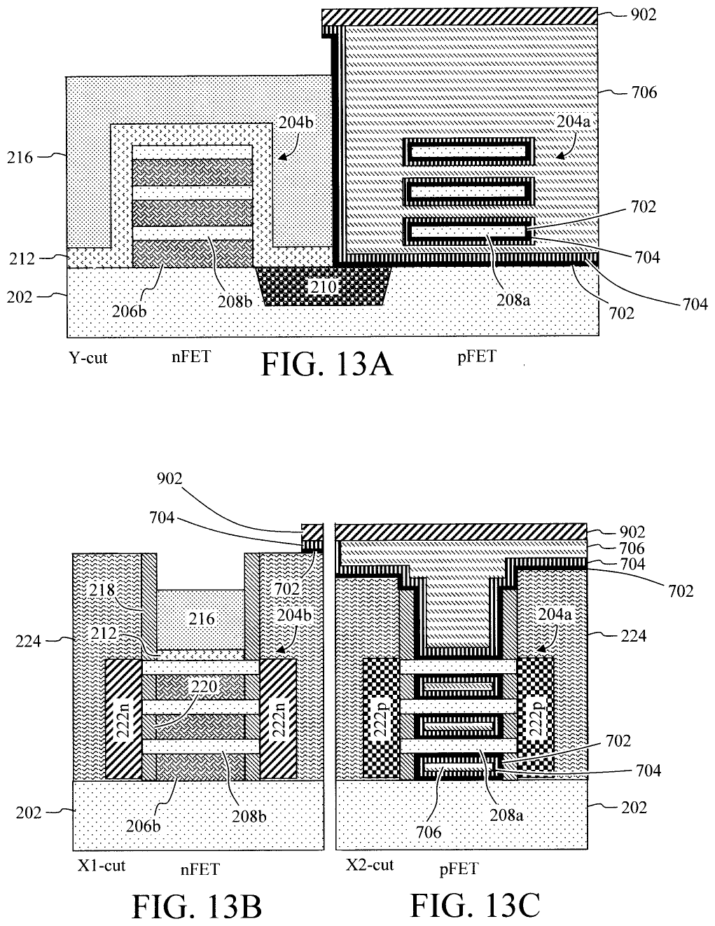

Namely, as shown in FIG. 13A (a Y cross-sectional view), FIG. 13B (an X1 cross-sectional view), and FIG. 13C (an X2 cross-sectional view), a follow-up non-directional, i.e., isotropic etching process is used to remove any remaining portions of the sacrificial gate hardmask 214. Suitable isotropic etching processes include, but are not limited to, a wet chemical etch such as hydrofluoric acid (HF) diluted by ethylene glycol (HFEG).

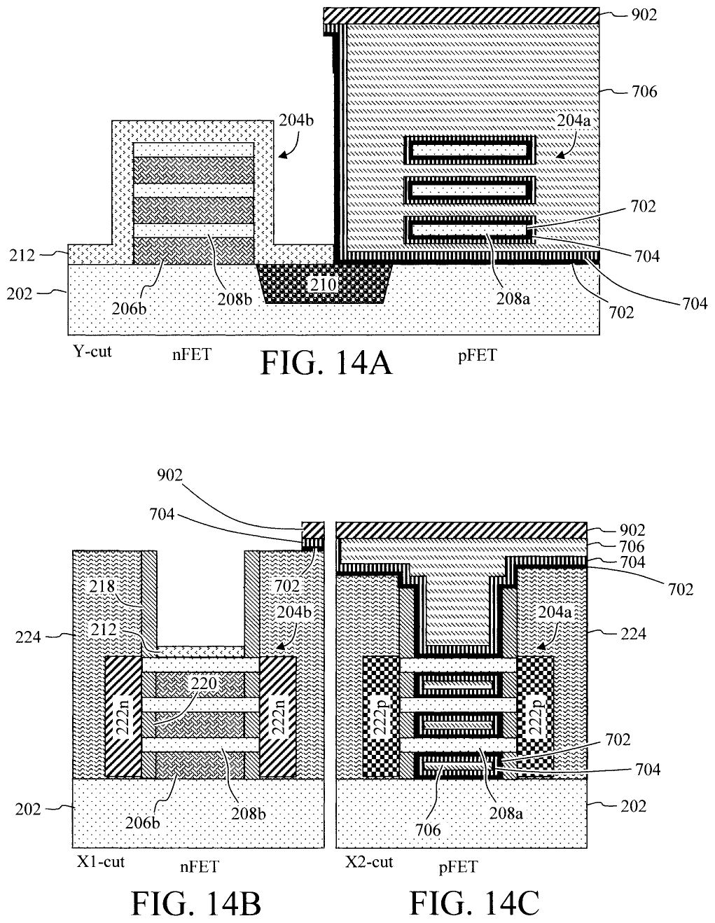

Removal of the sacrificial gate hardmask 214, exposes the underlying sacrificial gate 216 which, as shown in FIG. 14A (a Y cross-sectional view), FIG. 14B (an X1 cross-sectional view), and FIG. 14C (an X2 cross-sectional view), is then removed from over the device stack 204b. As provided above, the sacrificial gate 216 can be formed from poly-silicon and/or amorphous silicon. In that case, a poly-silicon and/or amorphous silicon-selective etch can be employed to remove the sacrificial gate 216 from the device stack 204b. After removal of the sacrificial gate 216, what remains of the hardmask 902 is removed.

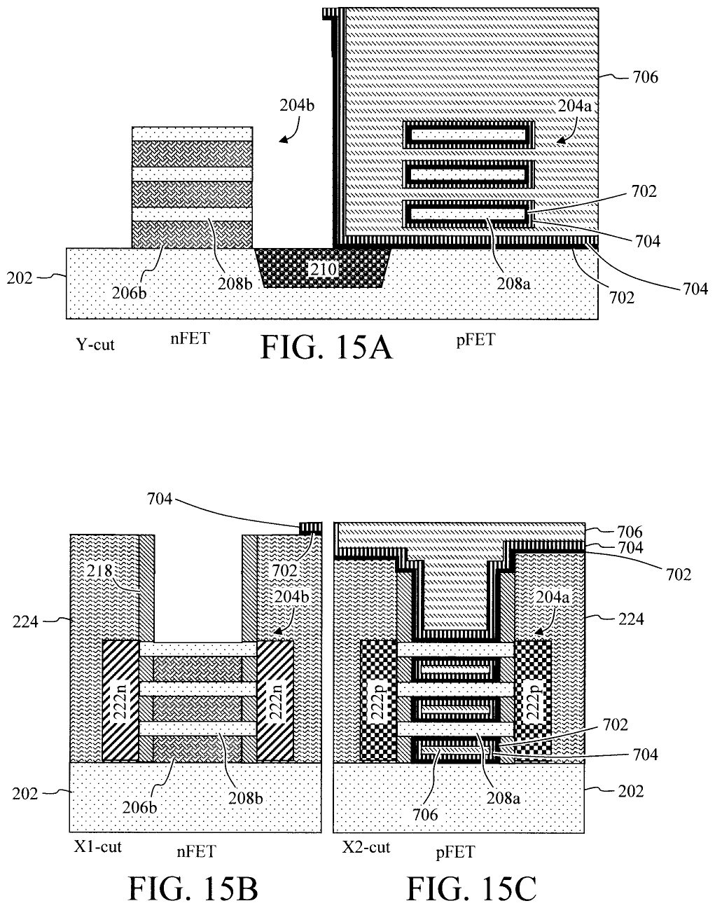

As shown in FIG. 15A (a Y cross-sectional view), FIG. 15B (an X1 cross-sectional view), and FIG. 15C (an X2 cross-sectional view), removal of the sacrificial gate 216 from the device stack 204b exposes the underlying sacrificial gate oxide 212, which is then also removed from the device stack 204b. An oxide-selective etching process may be employed to remove the sacrificial gate oxide 212.

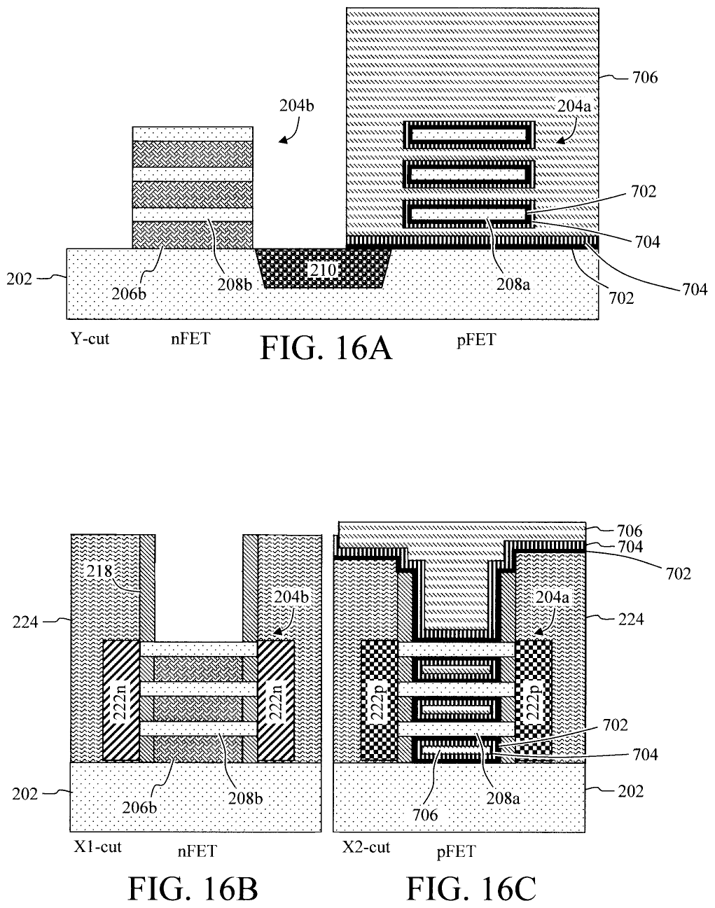

As shown in FIG. 16A (a Y cross-sectional view), FIG. 16B (an X1 cross-sectional view), and FIG. 16C (an X2 cross-sectional view), exposed portions of the gate dielectric 702 and gate dielectric cap 704 (including those portions of the gate dielectric 702 and gate dielectric cap 704 present along the sidewall of sacrificial placeholder 706 in the nFET region of the wafer 202) are then removed. As a result, the gate dielectric 702 and gate dielectric cap 704 are now present only in the pFET region of the wafer 202. As provided above, the gate dielectric cap 704 can be formed from a metal nitride material such as TiN and/or TaN, while the gate dielectric 702 can be formed from an oxide material such as HfO₂ and/or La₂O₃. In that case, successive nitride- and oxide-selective etching processes can be employed to remove the gate dielectric cap 704 and the gate dielectric 702, respectively.

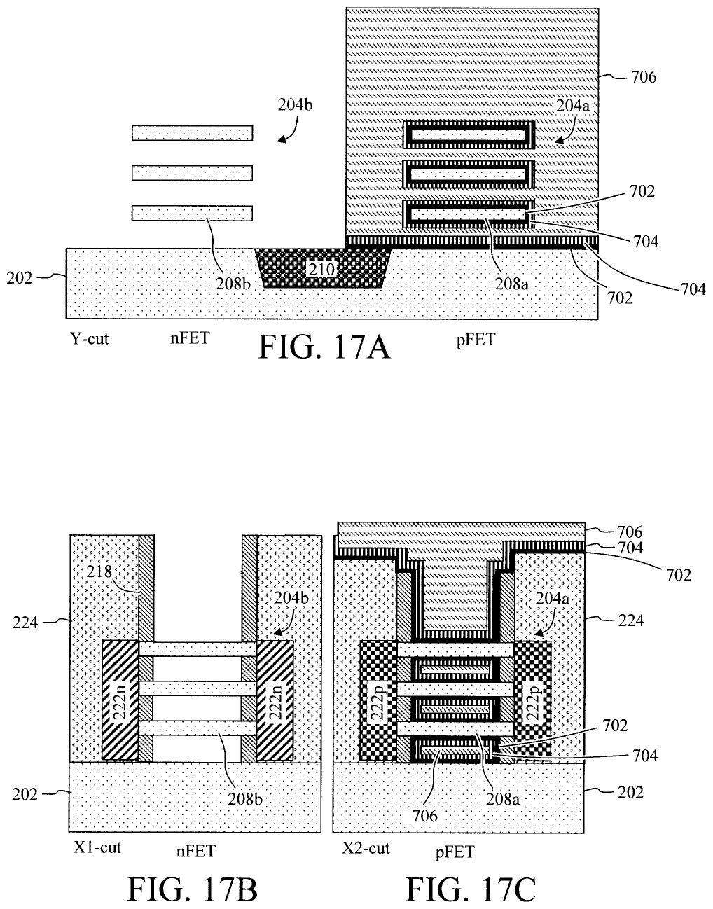

As shown in FIG. 17A (a Y cross-sectional view), FIG. 17B (an X1 cross-sectional view), and FIG. 17C (an X2 cross-sectional view), the now-exposed sacrificial layers 206b in the device stack 204b are then removed selective to the active layers 208b. According to an exemplary embodiment, sacrificial layers 206b are formed from SiGe, while active layers 208b are formed from Si. In that case, etchants such as wet hot SC1, vapor phase HCl, vapor phase ClF₃ and/or other reactive clean processes can be employed to remove the sacrificial layers 206b selective to the active layers 208b. Removal of the sacrificial layers 206b releases the active layers 208b from the device stack 204b. As highlighted above, these ‘released’ active layers 208b will be used to form the channels of the nFET transistor(s).

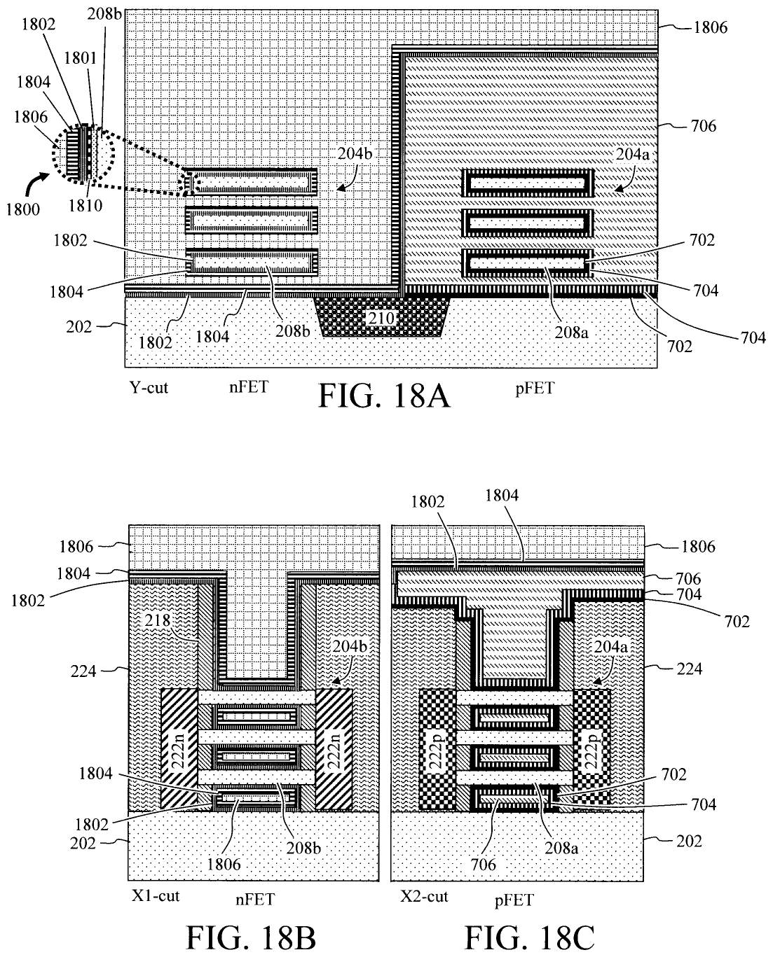

As shown in FIG. 18A (a Y cross-sectional view), FIG. 18B (an X1 cross-sectional view), and FIG. 18C (an X2 cross-sectional view), a (second) gate dielectric 1802 and a (second) gate dielectric cap 1804 are next deposited onto, and surrounding, the active layers 208b of the device stack 204b, and a (second) sacrificial placeholder 1806 is deposited over the gate dielectric 1802/gate dielectric cap 1804. As shown in FIGS. 18A-C, deposition of the gate dielectric 1802 and gate dielectric cap 1804 in this manner also deposits these materials on the exposed surface of the wafer 202 beneath the device stack 204b, as well as on the top and sidewalls of the sacrificial placeholder 706 which is present over the device stack 204a.

Referring to magnified view 1800 in FIG. 18A, prior to depositing the gate dielectric 1802, a (second) interfacial layer 1801 is preferably first formed on the active layers 208b. Use of an interfacial layer 1801 improves the channel/gate dielectric interface quality and channel carrier mobility. Suitable materials for the interfacial layer 1801 include but are not limited to oxide materials such as SiOx. According to an exemplary embodiment, the interfacial layer 1801 has a thickness of from about 0.5 nm to about 3 nm and ranges therebetween.

According to an exemplary embodiment, the thickness and/or composition of the interfacial layer 1801 and/or the gate dielectric 1802 in the nFET transistor differs from the thickness and/or composition of the interfacial layer 701 and/or the gate dielectric 702 in the pFET transistor. For instance, an optional dipole layer 1810 can be deposited onto the interfacial layer 1801 prior to the gate dielectric 1802. A subsequent reliability anneal (see below) will also serve to diffuse the metal or metals from the dipole layer 1810 into the interfacial layer 1801 and gate dielectric 1802. Doing so can be used to tune the threshold voltage of the nFET transistor relative to the pFET transistor, or vice versa. As a result, the device will have different nFET and pFET threshold voltages. Suitable metals for the dipole layer 1810 include, but are not limited to, La, Y, Mg and/or Ga. By way of example only, the dipole layer 1810 can have a thickness of from about 0.5 Å to about 30 Å. Following the reliability anneal (performed below), the interfacial layer 1801 and the gate dielectric 1802 will each contain at least one dipole dopant, e.g., La, Y. Mg and/or Ga. Preferably, different dipole dopants are used in the pFET versus nFET interfacial layer/gate dielectric in order to achieve different threshold voltages.

Additionally, the interfacial layer 1801 and/or the gate dielectric 1802 in the nFET transistor can optionally receive different treatments (e.g., oxidation and nitridation) from the interfacial layer 701 and/or the gate dielectric 702 in the pFET transistor in order to improve device performance. For example, according to an exemplary embodiment, a nitridation treatment is performed on the interfacial layer 1801 and/or the gate dielectric 1802 in the nFET transistor before depositing the gate dielectric cap 1804 to boost the capacitance and thereby improve device performance. Thus, in one exemplary embodiment, the nFET interfacial layer 1801 contains nitrogen (N) to form for example silicon oxynitride (SiON), whereas the pFET interfacial layer 701 is nitrogen-free SiO₂.

Furthermore, even if the same material (e.g., HfO₂) is used as the gate dielectric 1802 in the nFET transistor and as the gate dielectric 702 in the pFET transistor, embodiments are contemplated herein where the gate dielectric 1802 used in the nFET transistor is thicker than gate dielectric 702 used in the pFET transistor. For example, as will be described in detail below, the thickness of the nFET gate dielectric 1802 is preferably from about 1 Å to about 2 Å greater than the thickness of the pFET gate dielectric 702.

According to an exemplary embodiment, the gate dielectric 1802 is a high-K material such as HfO₂, La₂O₃, HfLaO₂, HfZrO₂ and/or HfAlO₂. A process such as CVD, ALD or PVD can be employed to deposit the gate dielectric 1802. According to an exemplary embodiment, gate dielectric 1802 has a thickness of from about 1 nm to about 5 nm and ranges therebetween. As highlighted above, the composition of the gate dielectric 1802 can differ from that of the gate dielectric 702. For instance, according to an exemplary embodiment, the (nFET) gate dielectric 1802 is HfLaO₂, whereas the (pFET) gate dielectric 702 is HfZrO₂ and/or HfAlOx. It is notable, however, that employing different pFET and nFET gate dielectrics 702 and 1802, respectively, is not a requirement, and embodiments are contemplated herein where the gate dielectric 702 and gate dielectric 1802 have the same composition and/or thickness as one another.

Suitable materials for the gate dielectric cap 1804 include, but are not limited to, metal nitrides such as TiN and/or TaN, which can be deposited using a process such as CVD, ALD or PVD. According to an exemplary embodiment, the gate dielectric cap 1804 has a thickness of from about 1 nm to about 10 nm and ranges therebetween. The gate dielectric cap 1804 will serve to protect the gate dielectric 1802 during subsequent processing steps including during removal of the sacrificial placeholder 1806.

Suitable materials for the sacrificial placeholder 1806 include, but are not limited to, poly-silicon and/or amorphous silicon. A process such as CVD, ALD or PVD can be employed to deposit the sacrificial placeholder 1806 material over the gate dielectric 1802/gate dielectric cap 1804. As will be described in detail below, the sacrificial placeholder 1806 will be removed later on in the process, and replaced with the workfunction-setting metal(s) and optional fill metal(s) to complete the replacement metal gate of (in this case) the nFET transistor.

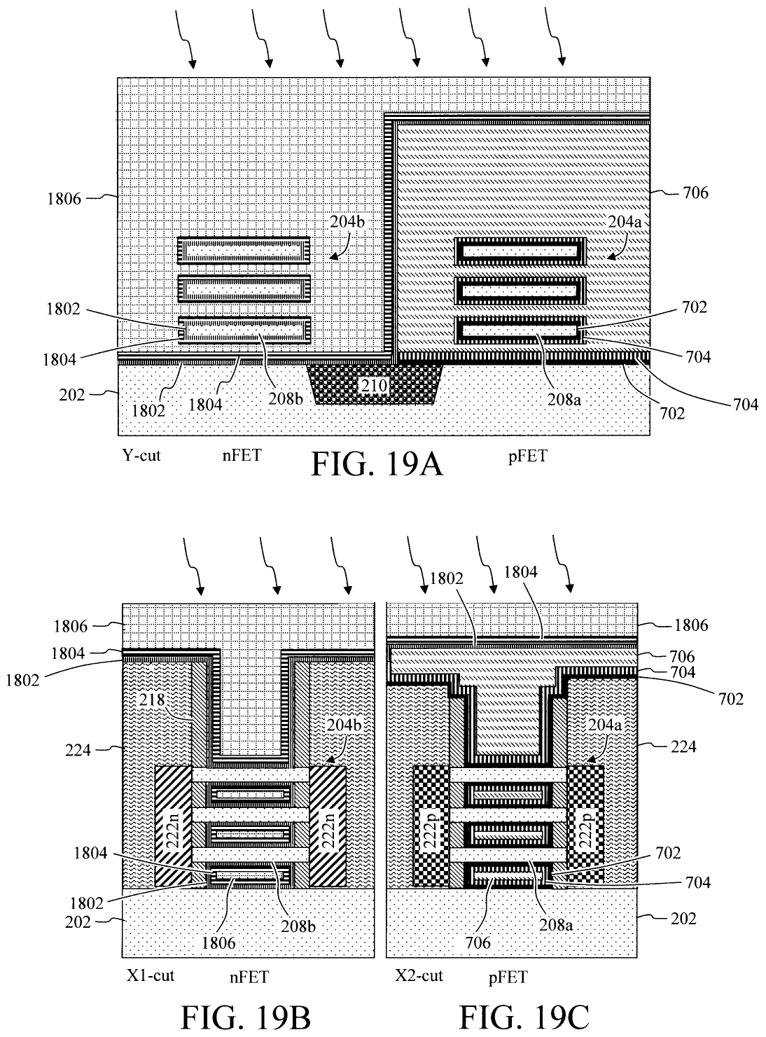

As shown in FIG. 19A (a Y cross-sectional view), FIG. 19B (an X1 cross-sectional view), and FIG. 19C (an X2 cross-sectional view), a reliability anneal is performed. According to an exemplary embodiment, the reliability anneal is performed at a temperature of from about 500° C. to about 1200° C. and ranges therebetween, for a duration of from about 1 nanosecond to about 30 seconds and ranges therebetween. Preferably, the reliability anneal is performed in the presence of an inert gas such as, but not limited to, nitrogen. As highlighted above, dipole layer 710 and/or dipole layer 1810 can optionally be implemented in the pFET and nFET transistors, respectively. The reliability anneal serves to diffuse the metal or metals from the dipole layer 710 and/or dipole layer 1810 into the interfacial layer 701/gate dielectric 702 and/or the interfacial layer 1801/gate dielectric 1802, respectively.

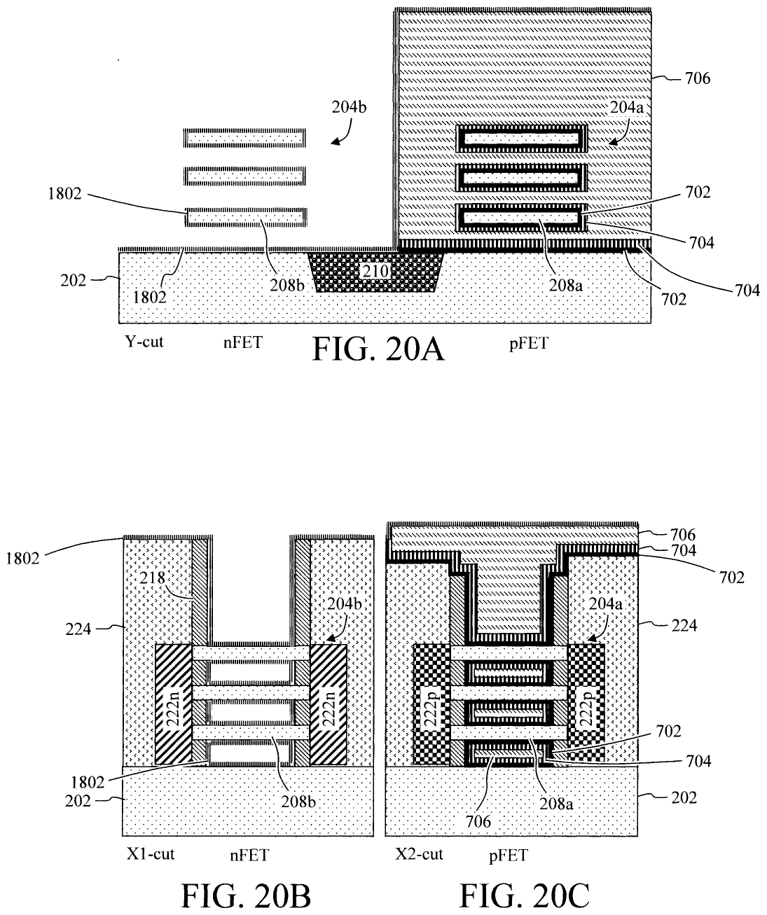

As shown in FIG. 20A (a Y cross-sectional view), FIG. 20B (an X1 cross-sectional view), and FIG. 20C (an X2 cross-sectional view), the sacrificial placeholder 1806 and the gate dielectric cap 1804 are then selectively removed from the nFET region of the wafer 202, exposing the underlying gate dielectric 1802. As provided above, the sacrificial placeholder 1806 can be formed from poly-silicon and/or amorphous silicon, and the gate dielectric cap 1804 can be formed from a metal nitride material such as TiN and/or TaN. In that case, a poly-silicon and/or amorphous silicon-selective etch can be employed to remove the sacrificial placeholder 1806, followed by a nitride-selective etch to remove the gate dielectric cap 1804. As shown in FIGS. 20A-C, the sacrificial placeholder 706 remains over the device stack 204a in the pFET region of the wafer 202.

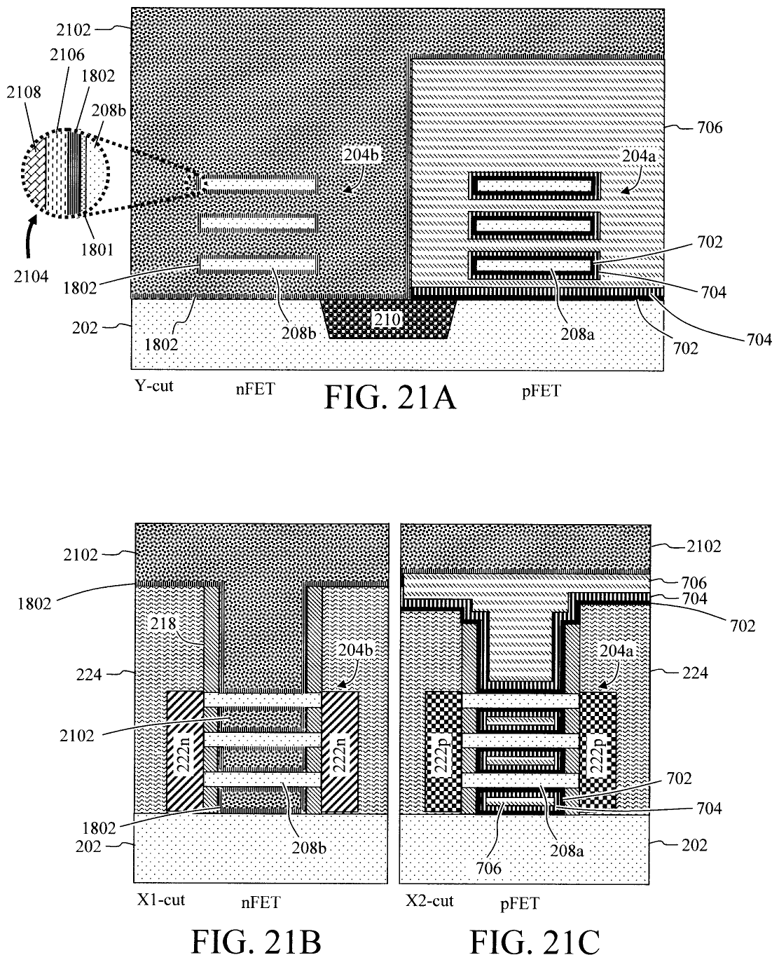

As shown in FIG. 21A (a Y cross-sectional view), FIG. 21B (an X1 cross-sectional view), and FIG. 21C (an X2 cross-sectional view), an nFET gate electrode 2102 is formed on the gate dielectric 1802 surrounding a portion of each of the active layers 208b in a gate all around configuration. As shown in magnified view 2104 in FIG. 21A, nFET gate electrode 2102 includes at least one workfunction-setting metal 2106 disposed on the gate dielectric 1802, and an optional (low-resistance) fill metal 2108 disposed on the workfunction-setting metal(s) 2106.

Suitable (n-type) workfunction-setting metals 2106 include, but are not limited to, titanium nitride (TiN), tantalum nitride (TaN) and/or aluminum (Al)-containing alloys such as titanium aluminide (TiAl), titanium aluminum nitride (TiAlN), titanium aluminum carbide (TiAlC), tantalum aluminide (TaAl), tantalum aluminum nitride (TaAlN), and/or tantalum aluminum carbide (TaAlC), and/or titanium (Ti)-containing alloys such as titanium carbide (TIC) and/or tantalum titanium (TaTi). It is notable, however, that this is not an exhaustive list and that these workfunction-setting metals are not meant to be exclusive to transistors of one polarity, e.g., TiAlC can be implemented as a workfunction-setting metal in both nFET and pFET transistors—see below. A process such as CVD, ALD or PVD can be employed to deposit the workfunction-setting metal(s) 2106. As will be described in detail below, the thickness and/or composition of the workfunction-setting metal(s) 2106 in the nFET transistor can differ from the thickness and/or composition of the workfunction-setting metal(s) in the pFET transistor (see below).

Suitable low-resistance fill metals 2108 include, but are not limited to, W, cobalt (Co), ruthenium (Ru) and/or Al. The low-resistance fill metals 2108 can be deposited using a process or combination of processes including, but not limited to, CVD, ALD, PVD, sputtering, plating, evaporation, ion beam deposition, electron beam deposition, laser assisted deposition, chemical solution deposition, etc.

As such, according to the above-described exemplary embodiment, the nFET replacement metal gate includes an interfacial layer 1801 disposed on the active layers 208b of the device stack 204b (in the nFET region of the wafer 202), the gate dielectric 1802 surrounding the active layers 208b over the interfacial layer 1801, and the gate electrode 2102 disposed on the gate dielectric 1802 surrounding a portion of each of the active layers 208b in a gate all around configuration. The gate electrode 2102 includes the at least one of workfunction-setting metal(s) 2106 disposed on the gate dielectric 1802, and the optional (low-resistance) fill metal 2108 disposed on the workfunction-setting metal(s) 2106.

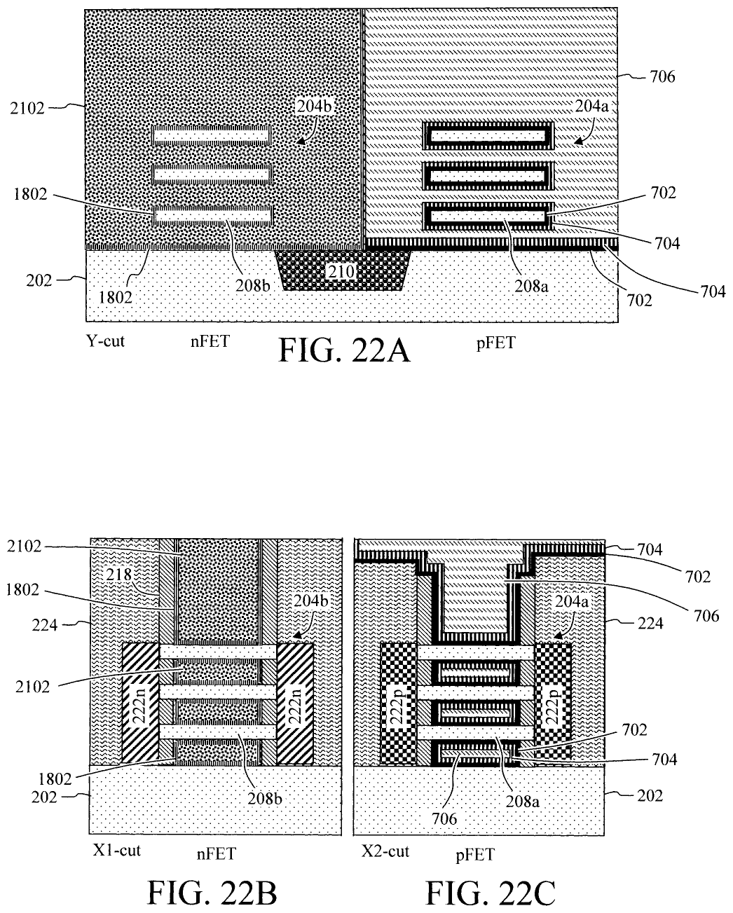

As shown in FIGS. 21A-C, the as-deposited nFET gate electrode 2102 extends over the pFET region of the wafer 202. However, a recess of the nFET gate electrode 2102 is next performed to remove the overburden from the pFET region of the wafer 202. Namely, as shown in FIG. 22A (a Y cross-sectional view), FIG. 22B (an X1 cross-sectional view), and FIG. 22C (an X2 cross-sectional view), the nFET gate electrode 2102 and gate dielectric 1802 are recessed down to the sacrificial placeholder 706. This recessing of the nFET gate electrode 2102 and gate dielectric 1802 can be performed using a process such as chemical mechanical polishing or reactive ion etching.

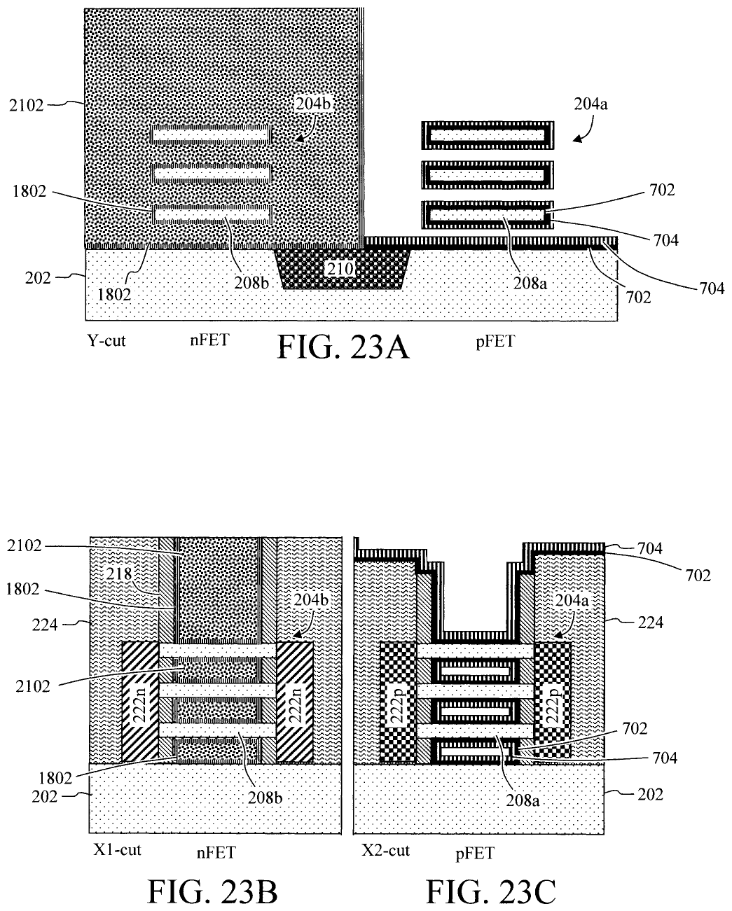

Removal of the nFET gate electrode 2102 and gate dielectric 1802 from the pFET regions of the wafer 202 exposes the underlying sacrificial placeholder 706 which, as shown in FIG. 23A (a Y cross-sectional view), FIG. 23B (an X1 cross-sectional view), and FIG. 23C (an X2 cross-sectional view), is then selectively removed. As provided above, the sacrificial placeholder 706 can be formed from poly-silicon and/or amorphous silicon. In that case, a poly-silicon and/or amorphous silicon-selective etch can be employed to remove the sacrificial placeholder 706.

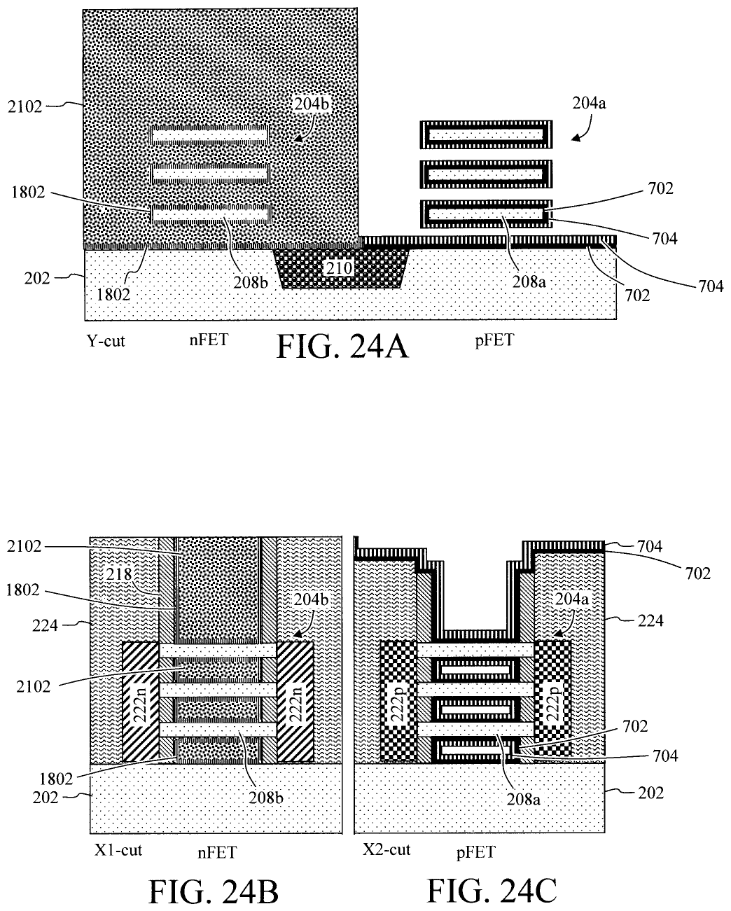

As shown in FIG. 24A (a Y cross-sectional view), FIG. 24B (an X1 cross-sectional view), and FIG. 24C (an X2 cross-sectional view), portions of the gate dielectric 1802 exposed after removal of the sacrificial placeholder 706, including those portions along the sidewall of the nFET gate electrode 2102, are then removed. As provided above, the gate dielectric 1802 can be formed from HfO₂ and/or La₂O₃. In that case, an oxide-selective etching process can be employed to remove the exposed gate dielectric 1802.

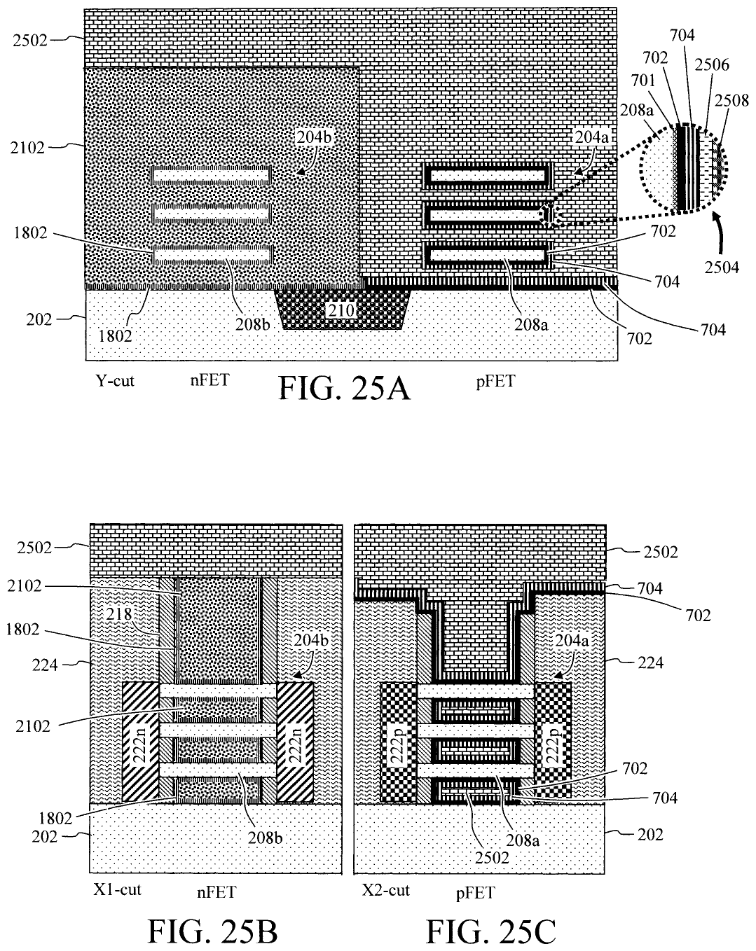

As shown in FIG. 25A (a Y cross-sectional view), FIG. 25B (an X1 cross-sectional view), and FIG. 25C (an X2 cross-sectional view), a pFET gate electrode 2502 is formed on the gate dielectric 702/gate dielectric cap 704 surrounding a portion of each of the active layers 208a in a gate all around configuration. For clarity, the terms ‘first’ and ‘second’ may also be used herein when referring to pFET gate electrode 2502 and nFET gate electrode 2102, respectively. As shown in magnified view 2504 in FIG. 25A, pFET gate electrode 2502 includes at least one workfunction-setting metal 2506 disposed on the gate dielectric cap 704, and an optional (low-resistance) fill metal 2508 disposed on the workfunction-setting metal(s) 2506. For clarity, the terms ‘first’ and ‘second’ may also be used herein when referring to workfunction-setting metal(s) 2506 and workfunction-setting metal(s) 2106, respectively.

Suitable (p-type) workfunction-setting metals 2506 include, but are not limited to, TiN, TaN, and/or tungsten (W). TiN and TaN are relatively thick (e.g., greater than about 2 nm) when used as p-type workfunction-setting metals. However, very thin TiN or TaN layers (e.g., less than about 2 nm) may also be used beneath Al-containing alloys in n-type workfunction-setting stacks to improve electrical properties such as gate leakage currents. Thus, there is some overlap in the exemplary n- and p-type workfunction-setting metals given above. A process such as CVD, ALD or PVD can be employed to deposit the workfunction-setting metal(s) 2506.

Notably, as highlighted above, the present techniques advantageously enable tuning of both the gate dielectric and replacement metal gate materials (or combination of materials) in terms of composition, thickness, etc. fully separately in the pFET and nFET transistors since there is no overlap in materials between the pFET and nFET replacement metal gates. For example, the workfunction-setting metal(s) 2506 used in the pFET transistor are wholly distinct from those workfunction-setting metal(s) 2106 used in the nFET transistor. This selective tuning of the workfunction-setting metals 2106 and 2506 can also be coupled with the selection of interfacial layers 701 and 1801 and/or gate dielectrics 702 and 1802 that are unique (in composition, thickness, etc.) to the pFET and nFET transistors as described in detail above. Even in instances where some of the (nFET) workfunction-setting metal(s) 2106 and the (pFET) workfunction-setting metal(s) 2506 are the same, they are not continuously extended from one polarity to another.

According to an exemplary embodiment, the workfunction-setting metal(s) 2106 in the nFET transistor differ in composition and/or thickness from the workfunction-setting metal(s) 2506 in the pFET transistor, and vice versa. For instance, to use an illustrative, non-limiting example, both the workfunction-setting metal(s) 2106 in the nFET transistor and the workfunction-setting metal(s) 2506 in the pFET transistor can both include TiAlC. However, the thickness of the TiAlC in the pFET is preferably less than the thickness of the TiAlC in the nFET. Further, when used as the pFET workfunction-setting metal, the concentration of Al in the TiAlC is preferably lower than when it is used as nFET workfunction-setting metal. In another, non-limiting example, TiN/TiAlC/TIN can be employed as both the workfunction-setting metal(s) 2106 in the nFET transistor and as the workfunction-setting metal(s) 2506 in the pFET transistor. However, when used as the workfunction-setting metal(s) 2106 in the nFET transistor, 0.5 nmTiN/3 nm TiAlC/3 nm TiN may be implemented, whereas when used as the workfunction-setting metal(s) 2506 in the pFET transistor, 5 nm TiN/2 nm TiAlC/4 nm TiN may be implemented.

Suitable low-resistance fill metals 2508 include, but are not limited to, W, Co, Ru and/or Al. The low-resistance fill metal 2508 can be deposited using a process or combination of processes including, but not limited to, CVD, ALD, PVD, sputtering, plating, evaporation, ion beam deposition, electron beam deposition, laser assisted deposition, chemical solution deposition, etc.

According to the above-described exemplary embodiment, the pFET replacement metal gate includes an interfacial layer 701 disposed on the active layers 208a of the device stack 204a (in the pFET region of the wafer 202), the gate dielectric 702 surrounding the active layers 208a over the interfacial layer 701, and the gate electrode 2502 disposed on the gate dielectric 702 surrounding a portion of each of the active layers 208a in a gate all around configuration. The gate electrode 2502 includes the at least one of workfunction-setting metal(s) 2506 disposed on the gate dielectric 702, and the optional (low-resistance) fill metal 2508 disposed on the workfunction-setting metal(s) 2506.

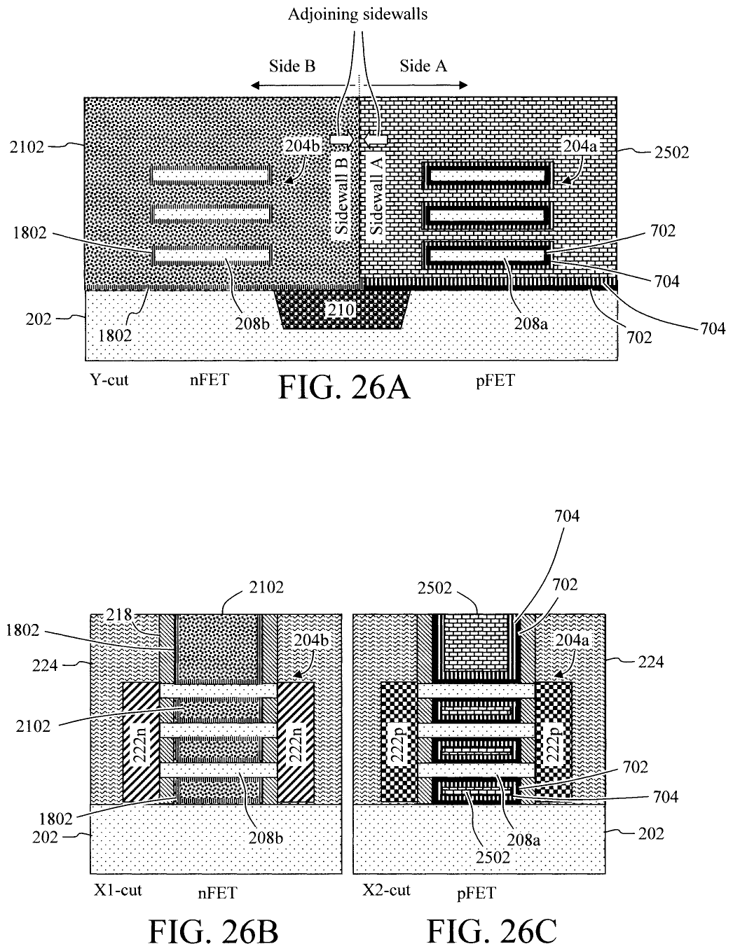

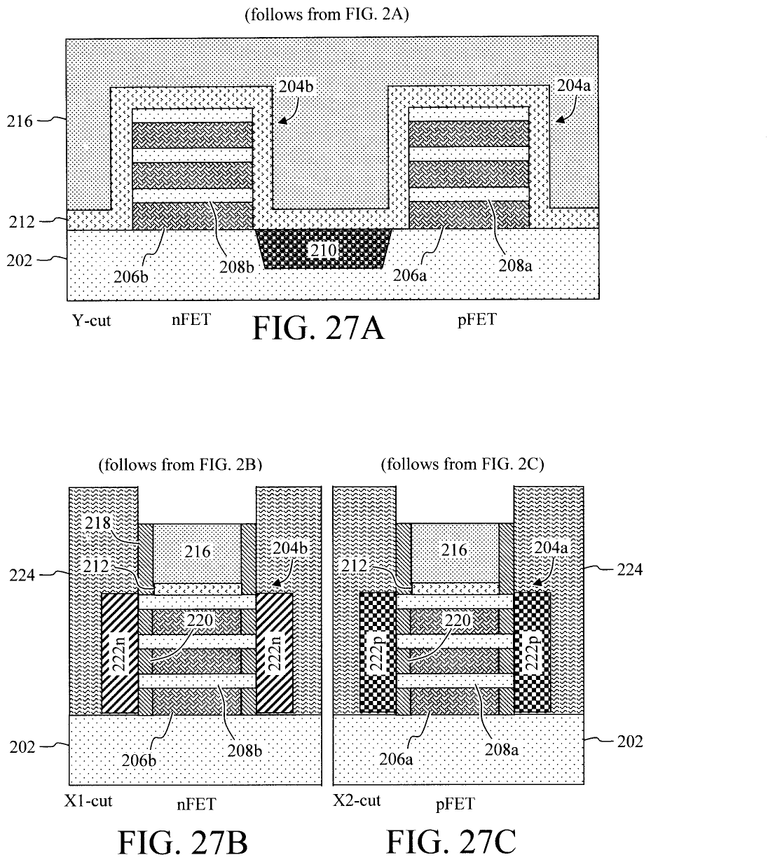

As shown in FIGS. 25A-C, the as-deposited pFET gate electrode 2502 extends over the nFET region of the wafer 202. However, a recess of the pFET gate electrode 2502 is next performed to remove the overburden from the nFET region of the wafer 202. Namely, as shown FIG. 26A (a Y cross-sectional view), FIG. 26B (an X1 cross-sectional view), and FIG. 26C (an X2 cross-sectional view), the pFET gate electrode 2502 is recessed down to the nFET gate electrode 2102 using a process such as chemical mechanical polishing or reactive ion etching.

As shown in FIGS. 26A-C, the nFET gate electrode 2102 directly contacts the pFET gate electrode 2502. Notably, however, the nFET gate electrode 2102 and the pFET gate electrode 2502 are in a non-vertically-overlapping position relative to one another and thus are not continuously extended from the nFET to pFET. To look at it another way, the nFET gate electrode 2102 and the pFET gate electrode 2502 have a single and continuous pair of vertically adjoining/directly-contacting sidewalls (see, e.g., sidewall A of the pFET gate electrode 2502 and sidewall B of the nFET gate electrode 2102 in FIG. 26A). Notably, since they do not overlap, the pFET gate electrode 2502 is present exclusively to a side (A) of the sidewall A opposite sidewall B, and the nFET gate electrode 2102 is present exclusively to a side (B) of the sidewall B opposite sidewall A. This would not be the case if any of the materials in the nFET gate electrode 2102 or the pFET gate electrode 2502 overlapped one another vertically, since that would result in both vertical and horizontal junctions.

Further, as shown, e.g., in FIGS. 26B-C the pFET and nFET transistors each includes source/drain regions 222p and 222n on opposite sides of the pFET gate electrode 2502 and the nFET gate electrode 2102, and a stack of active layers 208a and 208b interconnecting the source/drain regions 222p and 222n, respectively. Notably, the pFET gate electrode 2502 and the nFET gate electrode 2102 surround a portion of each of the active layers 208a and 208b, respectively, in a gate all around configuration which enhances device performance. In the pFET transistor, both the gate dielectric 702 and the gate dielectric cap 704 are disposed on the stack of active layers 208a beneath the pFET gate electrode 2502. In the nFET transistor, the gate dielectric 1802 is disposed on the stack of active layers 208b beneath the nFET gate electrode 2102. Thus, the gate dielectric cap 704 is present only in the pFET transistor.

In another exemplary embodiment, an alternative process flow is presented by way of reference to FIGS. 27-51 involving a global sacrificial hardmask open stage. Thus, while providing the benefits highlighted above relating to independent gate tunability, a simplified patterning scheme is also realized. The same Y, X1 and X2 cross-sectional views will be presented in the figures below, and these cross-sectional views follow the same corresponding orientations depicted in FIG. 1.

The process begins in the same manner as described in conjunction with the description of FIGS. 2A-C above, i.e., at least the (first) device stack 204a and the (second) device stack 204b are formed on the wafer 202 (each device stack 204a/b having alternating sacrificial layers 206a/b and active layers 208a/b), shallow trench isolation region 210 is formed in the wafer 202 between the device stacks 204a and 204b, the sacrificial gate oxide 212 is formed on the device stacks 204a and 204b, the sacrificial gate 216 is formed on the device stacks 204a and 204b (over the sacrificial gate oxide 212) using the sacrificial gate hardmask 214, the dielectric spacers 218 are formed alongside the sacrificial gate hardmask 214 and sacrificial gate 216, the inner spacers 220 are formed alongside the sacrificial layers 206a/b, the pFET and nFET and source/drain regions 222p and 222n are formed on opposite sides of the sacrificial gate 216 alongside the sacrificial layers 206a/b and active layers 208a/b, and the interlayer dielectric 224 is deposited onto the semiconductor device structure. Thus, what is shown in FIGS. 27A-C follow from the structures described in conjunction with the description of FIGS. 2A-C, respectively, above. It is notable that like structures are numbered alike in the figures.

However, in this alternative embodiment, the sacrificial gate hardmask 214 is opened over both the pFET and nFET regions of the wafer 202. Namely, as shown FIG. 27A (a Y cross-sectional view), FIG. 27B (an X1 cross-sectional view), and FIG. 27C (an X2 cross-sectional view), sacrificial gate hardmask 214 is fully removed following patterning of the sacrificial gate 216. As provided above, the sacrificial gate hardmask 214 can be formed from nitride and/or oxide materials such as SiN, SiO₂, TiN and/or SiON. In that case, a nitride- and/or oxide-selective directional, i.e., anisotropic, etching process such as reactive ion etching can be employed to remove the sacrificial gate hardmask 214. As shown in FIGS. 27A-C, depending on the selectivity of the etching process employed, some erosion of the dielectric spacers 218 can occur.

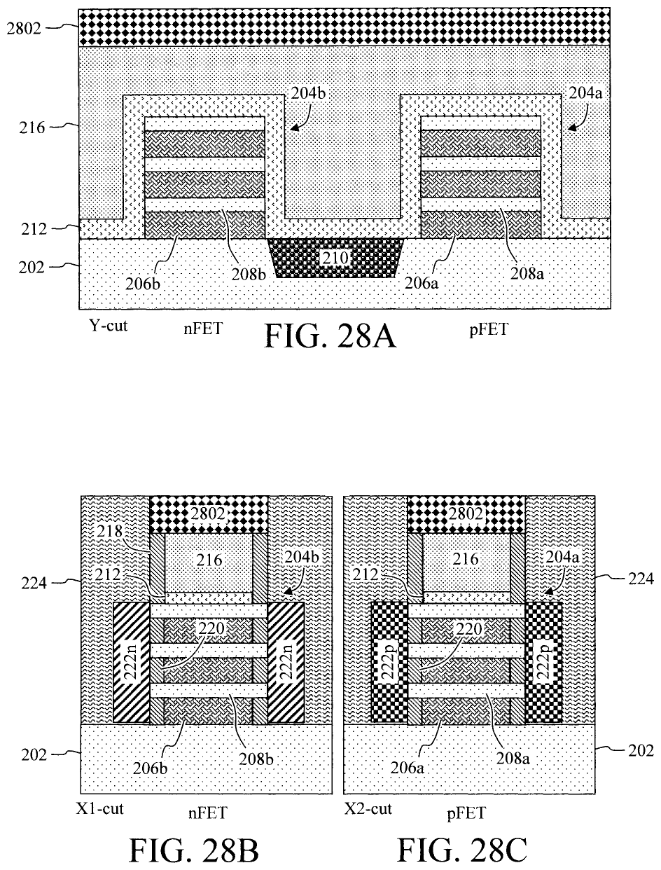

As shown FIG. 28A (a Y cross-sectional view), FIG. 28B (an X1 cross-sectional view), and FIG. 28C (an X2 cross-sectional view), following removal of the sacrificial gate hardmask 214, a masking layer 2802 is formed on the sacrificial gate 216. Suitable materials for the masking layer 2802 include, but are not limited to, amorphous silicon, which can be deposited using a process such as CVD, ALD or PVD. According to an exemplary embodiment, the masking layer 2802 has a thickness of from about 5 nm to about 10 nm and ranges therebetween.

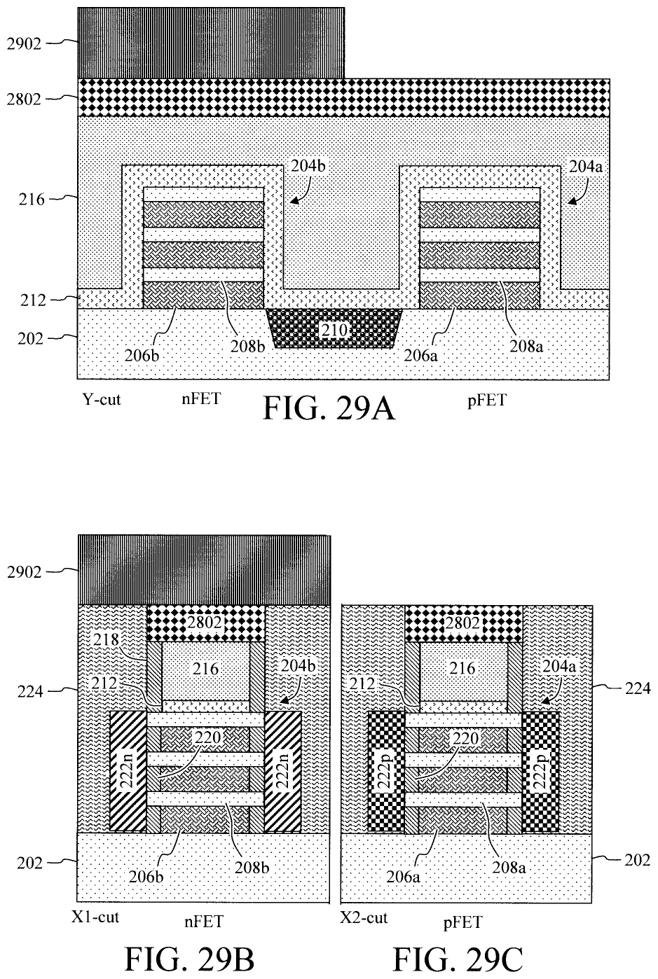

As shown FIG. 29A (a Y cross-sectional view), FIG. 29B (an X1 cross-sectional view), and FIG. 29C (an X2 cross-sectional view), a lithographic stack 2902 is formed on the masking layer 2802 over the nFET region of the wafer 202. While not explicitly shown in the figures, as described above, the lithographic stack 2902 can contain a combination of layers, e.g., photoresist/anti-reflective coating/organic planarizing layer.

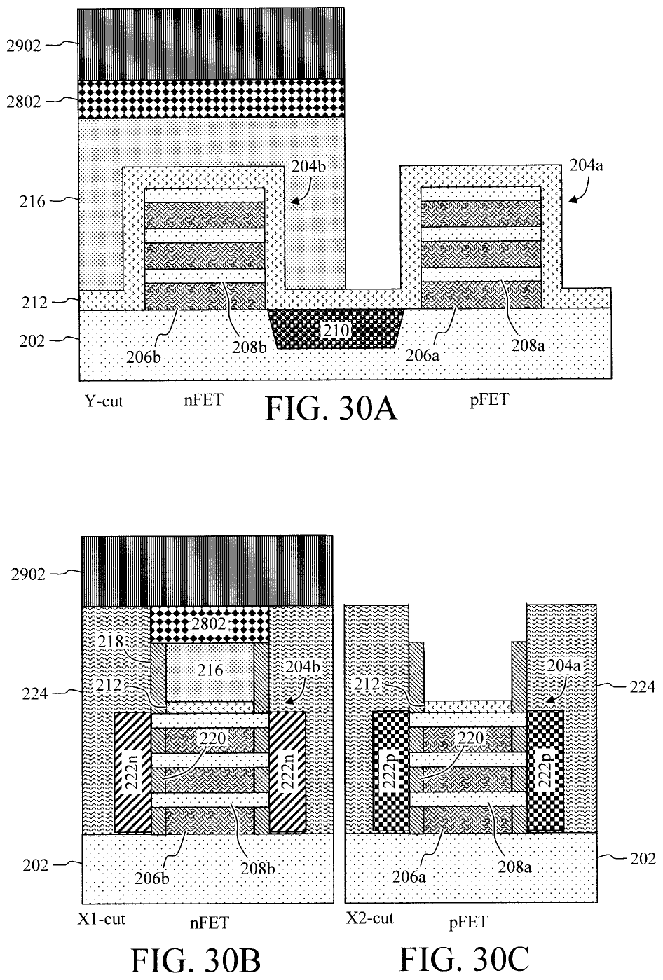

As shown FIG. 30A (a Y cross-sectional view), FIG. 30B (an X1 cross-sectional view), and FIG. 30C (an X2 cross-sectional view), the lithographic stack 2902 is then used to selectively open the masking layer 2802 and the sacrificial gate 216 over the device stack 204a. As provided above, the masking layer 2802 and the sacrificial gate 216 can both be formed from a silicon-based material such as amorphous silicon for the masking layer 2802, and poly-silicon and/or amorphous silicon for the sacrificial gate 216. In that case, an amorphous silicon and/or poly-silicon selective etch can be employed to open the masking layer 2802 and the sacrificial gate 216.

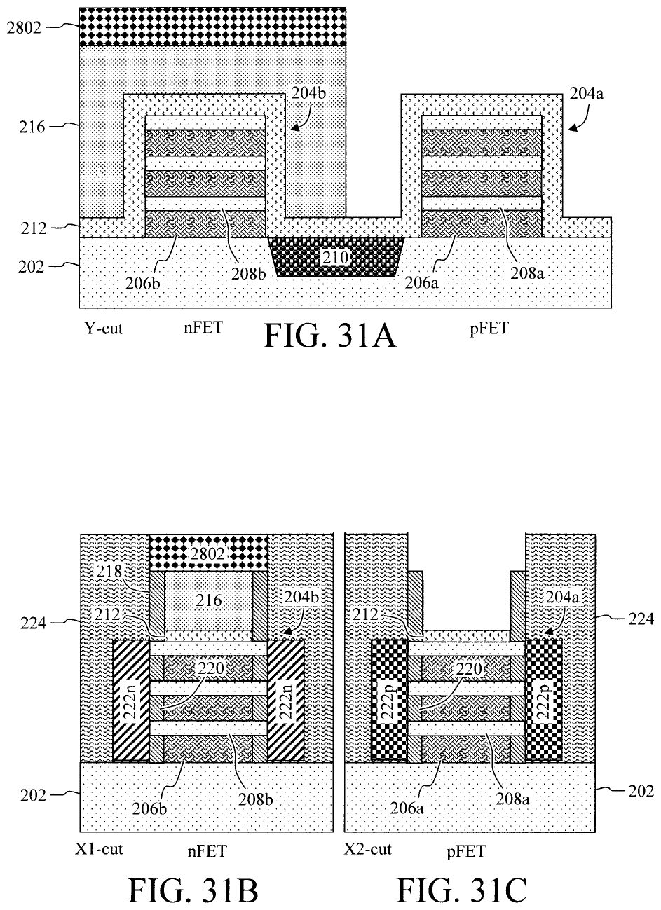

As shown FIG. 31A (a Y cross-sectional view), FIG. 31B (an X1 cross-sectional view), and FIG. 31C (an X2 cross-sectional view), after patterning the masking layer 2802 and the sacrificial gate 216, what remains of the lithographic stack 2902 is removed. The sacrificial gate oxide 212 covering the device stack 204a is now exposed.

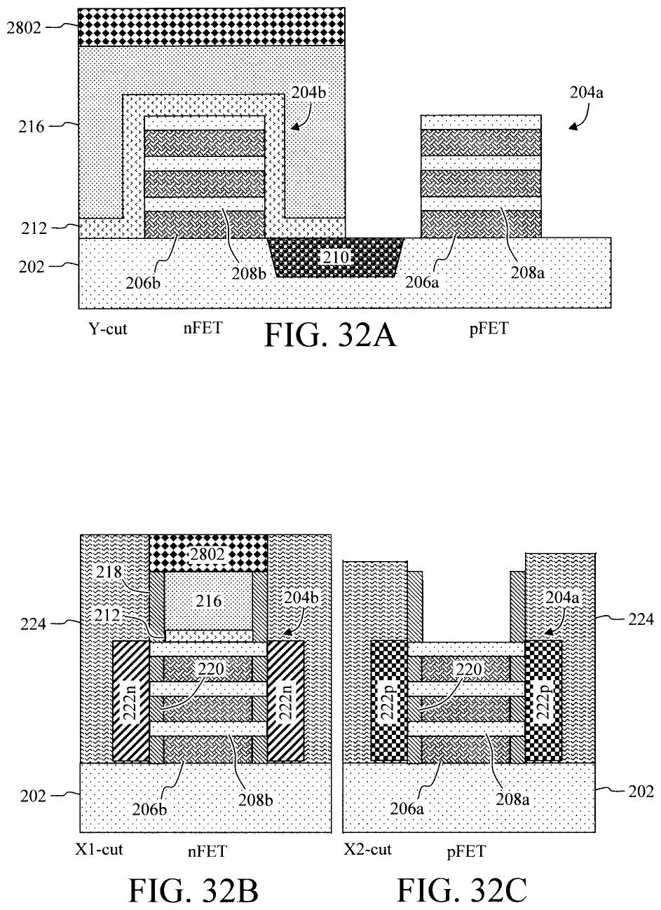

As shown FIG. 32A (a Y cross-sectional view), FIG. 32B (an X1 cross-sectional view), and FIG. 32C (an X2 cross-sectional view), the sacrificial gate oxide 212 is then also selectively removed from the device stack 204a. An oxide-selective etching process may be employed to remove the sacrificial gate oxide 212 from the device stack 204a.

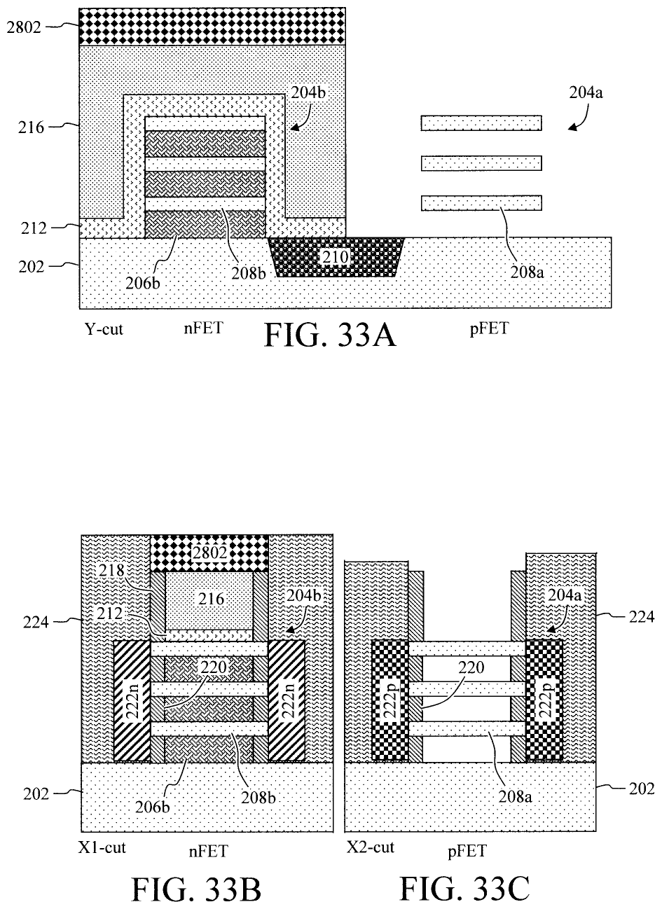

As shown in FIG. 33A (a Y cross-sectional view), FIG. 33B (an X1 cross-sectional view), and FIG. 33C (an X2 cross-sectional view), the now-exposed sacrificial layers 206a in the device stack 204a are then removed selective to the active layers 208a. According to an exemplary embodiment, sacrificial layers 206a are formed from SiGe, while active layers 208a are formed from Si. In that case, etchants such as wet hot SC1, vapor phase HCl, vapor phase ClF₃ and/or other reactive clean processes can be employed to remove the sacrificial layers 206a selective to the active layers 208a. Removal of the sacrificial layers 206a releases the active layers 208a from the device stack 204a. As highlighted above, these ‘released’ active layers 208a will be used to form the channels of the pFET transistor(s). Notably, at this point in the process, the sacrificial gate oxide 212 and sacrificial gate hardmask 214/sacrificial gate 216 remain covering the sacrificial layers 206b and active layers 208b of the device stack 204b.

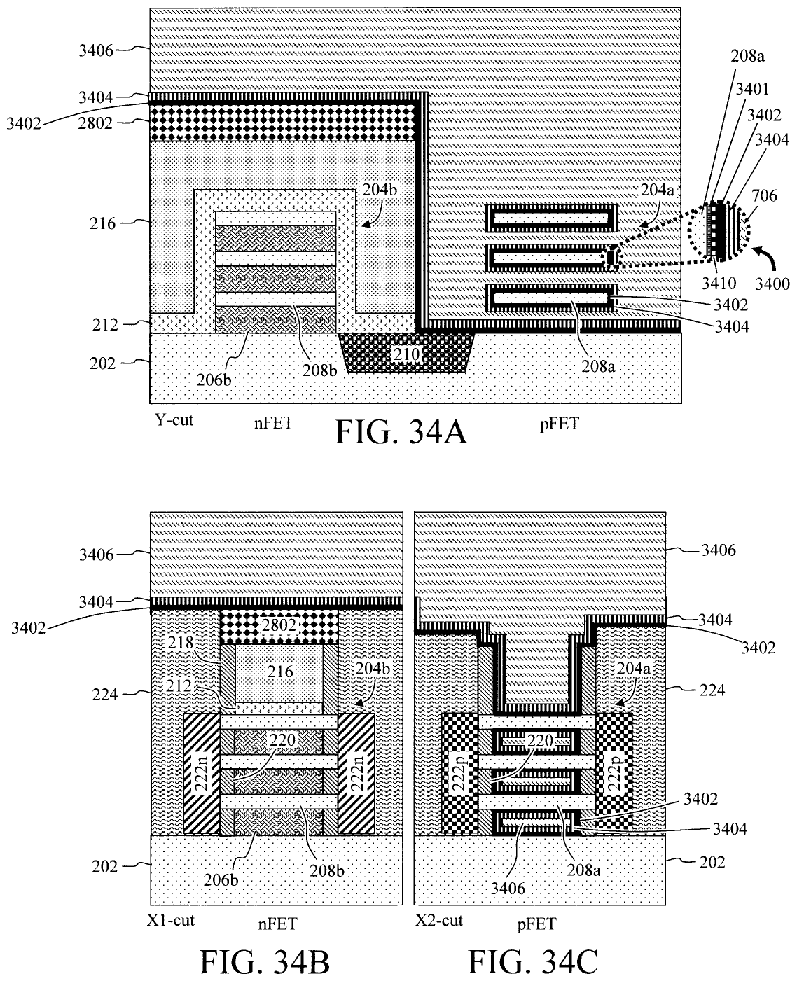

As shown in FIG. 34A (a Y cross-sectional view), FIG. 34B (an X1 cross-sectional view), and FIG. 34C (an X2 cross-sectional view), a (first) gate dielectric 3402 and a (first) gate dielectric cap 3404 are next deposited onto, and surrounding, the active layers 208a of the device stack 204a, and a (first) sacrificial placeholder 3406 is deposited over the gate dielectric 3402/gate dielectric cap 3404. As shown in FIGS. 34A-C, deposition of the gate dielectric 3402 and gate dielectric cap 3404 in this manner also deposits these materials on the exposed surface of the wafer 202 beneath the device stack 204a, as well as on the top and sidewalls of the masking layer 2802/sacrificial gate 216 which remain present over the device stack 204b.

Referring to magnified view 3400 in FIG. 34A, prior to depositing the gate dielectric 3402, a (first) interfacial layer 3401 is preferably first formed on the active layers 208a. As provided above, use of an interfacial layer 3401 improves the channel/gate dielectric interface quality and channel carrier mobility. Suitable materials for the interfacial layer 3401 include but are not limited to oxide materials such as SiOx. According to an exemplary embodiment, the interfacial layer 3401 has a thickness of from about 1 nm to about 3 nm and ranges therebetween.

According to an exemplary embodiment, the thickness and/or composition of the interfacial layer 3401 and/or the gate dielectric 3402 in the pFET transistor differs from the thickness and/or composition of the interfacial layer and/or the gate dielectric in the nFET transistor (see below). For instance, an optional dipole layer 3410 can be deposited onto the interfacial layer 3401 prior to the gate dielectric 3402. A subsequent reliability anneal (see below) will also serve to diffuse the metal or metals from the dipole layer 3410 into the interfacial layer 3401 and gate dielectric 3402. Doing so can be used to tune the threshold voltage of the pFET transistor relative to the nFET transistor, or vice versa. As a result, the device will have different pFET and nFET threshold voltages. Suitable metals for the dipole layer 3410 include, but are not limited to, La, Y, Mg and/or Ga. By way of example only, the dipole layer 3410 can have a thickness of from about 0.5 Å to about 30 Å. Following the reliability anneal (performed below), the interfacial layer 3401 and the gate dielectric 3402 will each contain at least one dipole dopant, e.g., La, Y, Mg and/or Ga. Preferably, different dipole dopants are used in the pFET versus nFET interfacial layer/gate dielectric in order to achieve different threshold voltages.

Additionally, the interfacial layer 3401 and/or the gate dielectric 3402 in the pFET transistor can optionally receive different treatments (e.g., oxidation and nitridation) from the interfacial layer and/or the gate dielectric (see below) in the nFET transistor in order to improve device performance. For example, according to an exemplary embodiment, an oxidation treatment is performed on the interfacial layer 3401 and/or gate dielectric 3402 before depositing the gate dielectric cap 3404. As will be described in detail below, a nitridation treatment is preferably performed only for the nFET interfacial layer/gate dielectric, while the pFET interfacial layer/gate dielectric remains nitrogen-free.

Furthermore, even if the same material (e.g., HfO₂) is used as the gate dielectric 3402 in the pFET transistor and as the gate dielectric in the nFET transistor, embodiments are contemplated herein where the gate dielectric used in the nFET transistor is thicker than gate dielectric 3402 used in the pFET transistor. For example, as will be described in detail below, the thickness of the nFET gate dielectric is preferably from about 1 Å to about 2 Å greater than the thickness of the pFET gate dielectric 3402.

In one exemplary embodiment, the gate dielectric 3402 is a high-k material. As provided above, suitable high-k gate dielectrics include, but are not limited to, HfO₂, La₂O₃, HfLaO₂, HfZrO₂ and/or HfAlO₂. A process such as CVD, ALD or PVD can be employed to deposit the gate dielectric 3402. According to an exemplary embodiment, gate dielectric 3402 has a thickness of from about 1 nm to about 5 nm and ranges therebetween.

Suitable materials for the gate dielectric cap 3404 include, but are not limited to, metal nitrides such as TiN and/or TaN, which can be deposited using a process such as CVD, ALD or PVD. According to an exemplary embodiment, the gate dielectric cap 3404 has a thickness of from about 2 nm to about 10 nm and ranges therebetween. The gate dielectric cap 3404 will serve to protect the gate dielectric 3402 during subsequent processing steps including during later removal of the sacrificial placeholder 3406 (see below).

Suitable materials for the sacrificial placeholder 3406 include, but are not limited to, poly-silicon and/or amorphous silicon. A process such as CVD, ALD or PVD can be employed to deposit the sacrificial placeholder 3406 material over the gate dielectric 3402/gate dielectric cap 3404. As will be described in detail below, the sacrificial placeholder 3406 will be removed later on in the process, and replaced with the workfunction-setting metal(s) and optional fill metal(s) to complete the replacement metal gate of (in this case) the pFET transistor. As shown in FIGS. 34A-C, the sacrificial placeholder 3406 fully covers the gate dielectric 3402/gate dielectric cap 3404 even over the device stack 204b. However, a subsequent polishing will remove that overburden from the nFET region of the wafer 202.

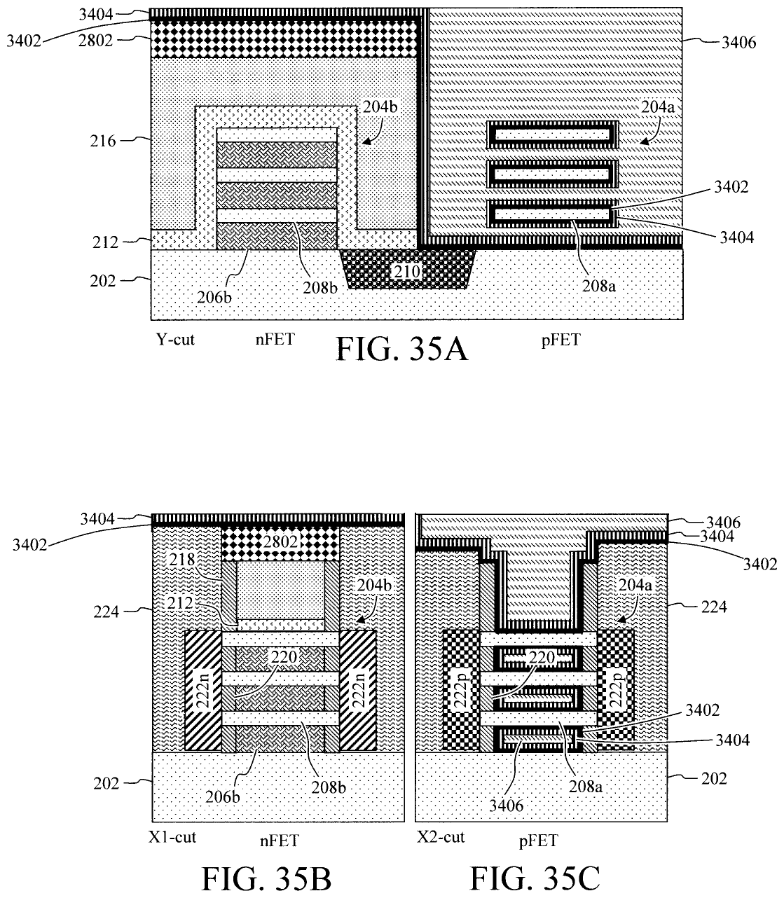

Namely, as shown in FIG. 35A (a Y cross-sectional view), FIG. 35B (an X1 cross-sectional view), and FIG. 35C (an X2 cross-sectional view), the sacrificial placeholder 3406 is recessed down to the gate dielectric cap 3404. This recessing of the sacrificial placeholder 3406 can be performed using a process such as chemical mechanical polishing. The sacrificial placeholder 3406 is now removed from the nFET region of wafer 202.

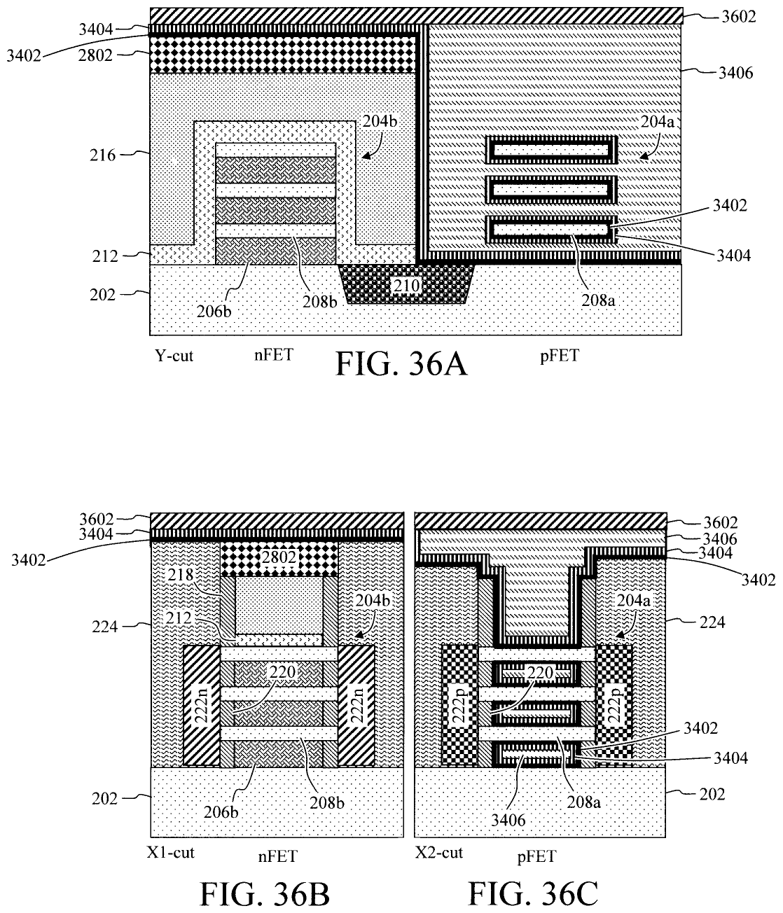

As shown in FIG. 36A (a Y cross-sectional view), FIG. 36B (an X1 cross-sectional view), and FIG. 36C (an X2 cross-sectional view), a hardmask 3602 is next deposited onto the gate dielectric cap 3404 in the nFET region of the wafer 202 and onto the sacrificial placeholder 3406 in the pFET region of the wafer 202. As provided above, suitable hardmask materials generally include, but are not limited to, SiN, SiO₂, TiN and/or SiON. However, in one exemplary implementation, hardmask 3602 is formed from a nitride material (e.g., SiN, TiN and/or SiON). Doing so will enable the selective removal of the (oxide) gate dielectric 3402 later on in the process, and subsequent co-removal of the hardmask 3602 and gate dielectric cap 3404. According to an exemplary embodiment, the hardmask 3602 has a thickness of from about 2 nm to about 10 nm and ranges therebetween. As will be described in detail below, the hardmask 3602 will be used to remove the sacrificial gate hardmask 214, sacrificial gate 216 and sacrificial gate oxide 212 from the device stack 204b (in the nFET region of the wafer 202).

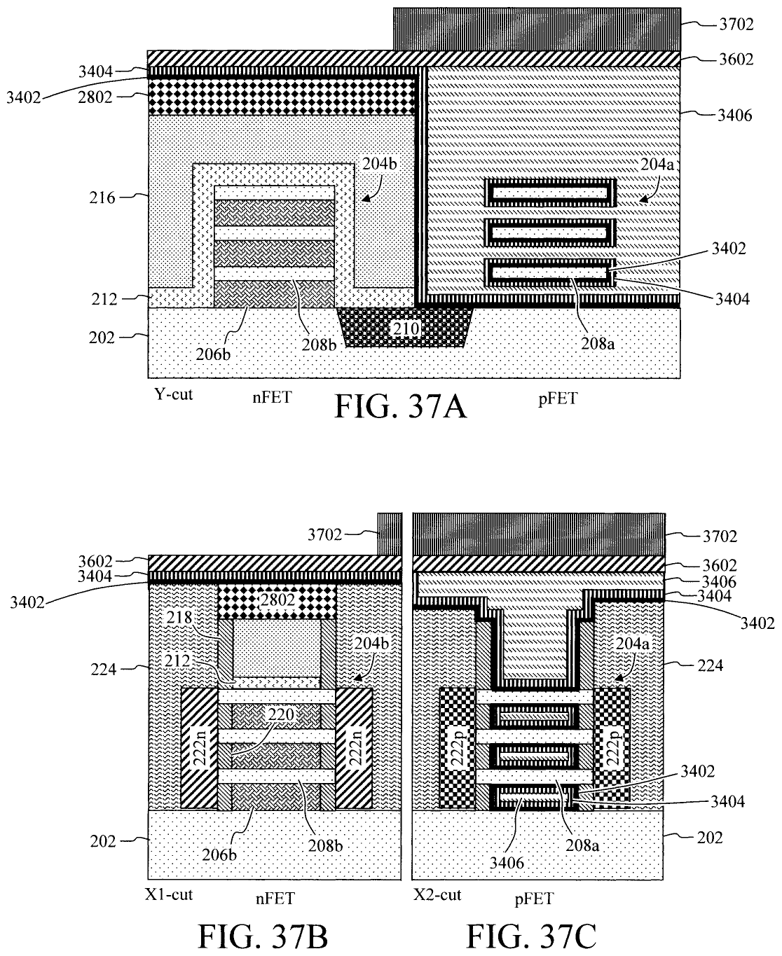

To do so, as shown in FIG. 37A (a Y cross-sectional view), FIG. 37B (an X1 cross-sectional view), and FIG. 37C (an X2 cross-sectional view), a lithographic stack 3702 is first formed on the hardmask 3602. While not explicitly shown in the figures, as described above, the lithographic stack 3702 can contain a combination of layers, e.g., photoresist/anti-reflective coating/organic planarizing layer.

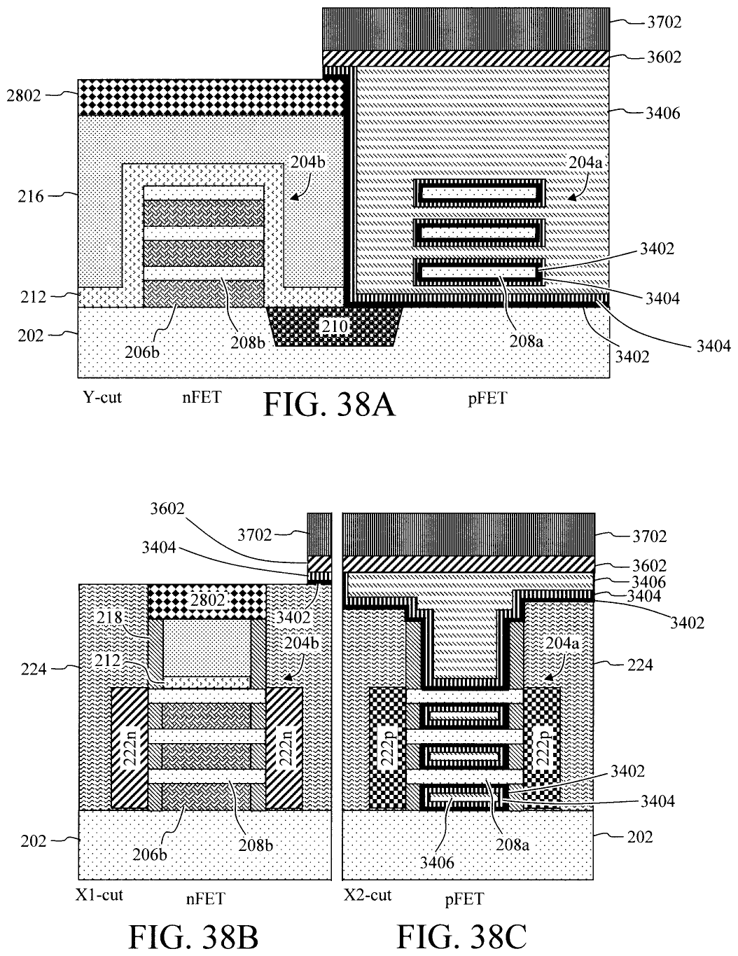

Next, as shown in FIG. 38A (a Y cross-sectional view), FIG. 38B (an X1 cross-sectional view), and FIG. 38C (an X2 cross-sectional view), the lithographic stack 3702 is used to selectively open the hardmask 3602 over the device stack 204b. A directional, i.e., anisotropic, etching process such as reactive ion etching can be employed to transfer the pattern from the lithographic stack 3702 to the hardmask 3602, thereby opening the hardmask 3602 over the device stack 204b. After patterning the hardmask 3602, what remains of the lithographic stack 3702 is removed. The (patterned) hardmask 3602 is then used to open the gate dielectric 3402 and gate dielectric cap 3404 over the device stack 204b. A directional, i.e., anisotropic, etching process such as reactive ion etching can be employed to pattern the gate dielectric 3402 and gate dielectric cap 3404. After patterning the gate dielectric 3402 and gate dielectric cap 3404, what remains of the lithographic stack 3702 is removed.

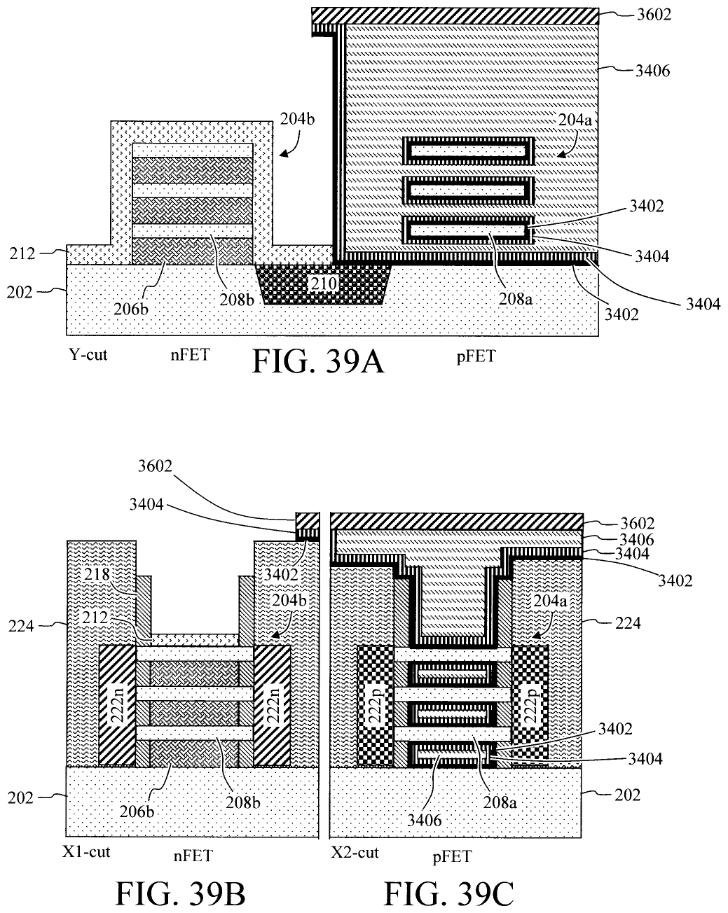

The masking layer 2802 over the device stack 204b is now exposed. As shown in FIG. 39A (a Y cross-sectional view), FIG. 39B (an X1 cross-sectional view), and FIG. 39C (an X2 cross-sectional view), the remaining masking layer 2802 over the device stack 204b is then removed, as is the underlying sacrificial gate 216. As provided above, the masking layer 2802 and the sacrificial gate 216 can both be formed from a silicon-based material such as amorphous silicon for the masking layer 2802, and poly-silicon and/or amorphous silicon for the sacrificial gate 216. In that case, an amorphous silicon and/or poly-silicon selective etch can be employed to remove the remaining masking layer 2802 and the sacrificial gate 216 from over the device stack 204b.

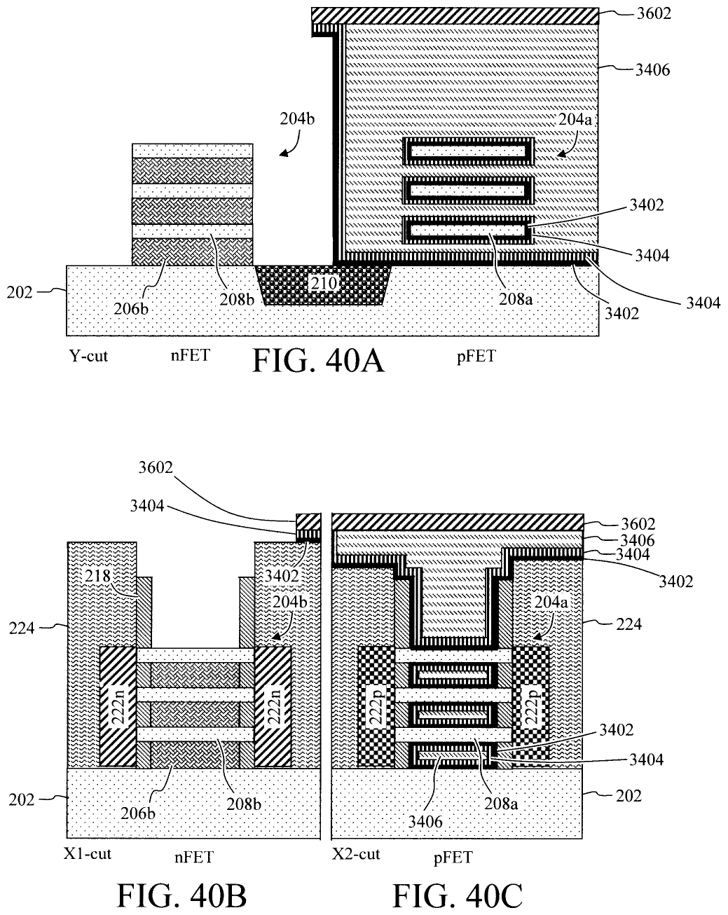

As shown in FIG. 40A (a Y cross-sectional view), FIG. 40B (an X1 cross-sectional view), and FIG. 40C (an X2 cross-sectional view), removal of the sacrificial gate 216 from the device stack 204b exposes the underlying sacrificial gate oxide 212, which is then also removed from the device stack 204b. An oxide-selective etching process may be employed to remove the sacrificial gate oxide 212.

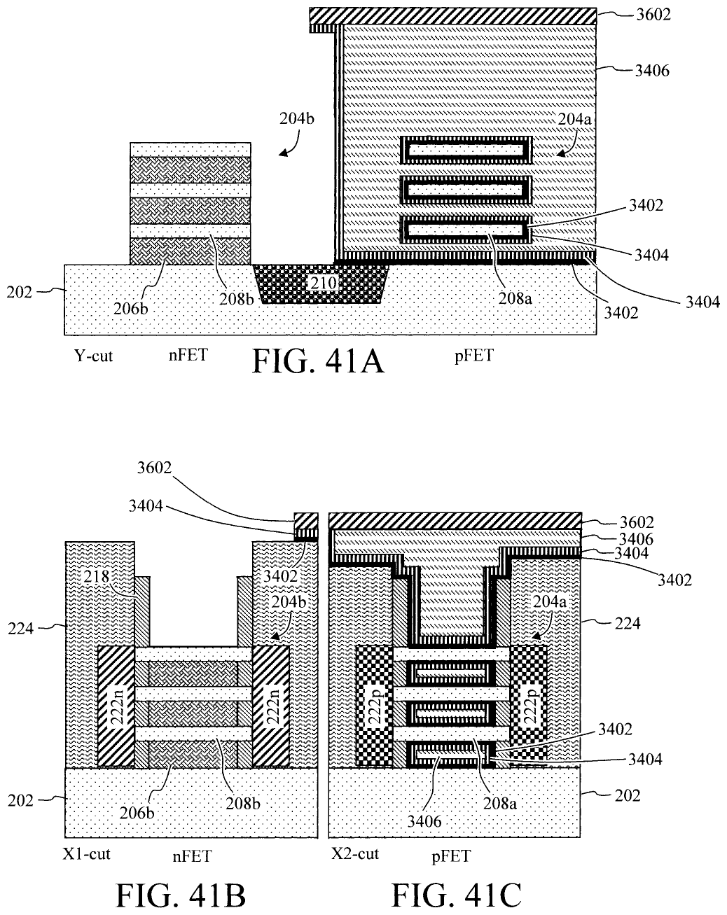

As shown in FIG. 41A (a Y cross-sectional view), FIG. 41B (an X1 cross-sectional view), and FIG. 41C (an X2 cross-sectional view), exposed portions of the gate dielectric 3402 (including those portions of the gate dielectric 3402 present along the sidewall of sacrificial placeholder 3406 in the nFET region of the wafer 202) are then removed. As provided above, the gate dielectric 3402 can be formed from an oxide material such as HfO₂ and/or La₂O₃. In that case, an oxide-selective etching process can be employed to remove the gate dielectric 3402.

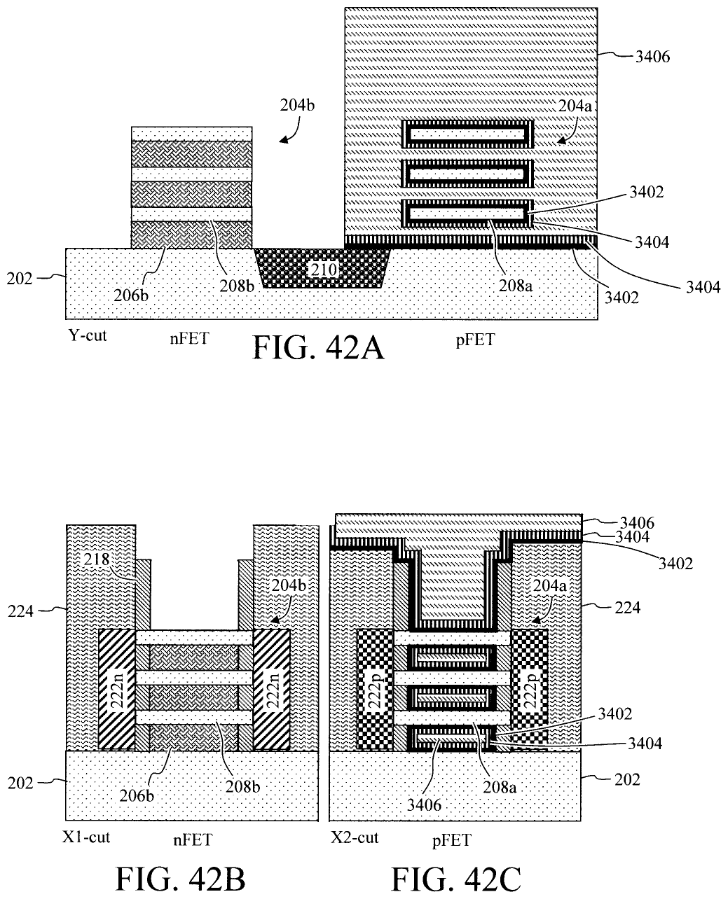

As shown in FIG. 42A (a Y cross-sectional view), FIG. 42B (an X1 cross-sectional view), and FIG. 42C (an X2 cross-sectional view), what remains of the hardmask 3602 is removed, as are the exposed portions of the gate dielectric cap 3404 (including those portions of the gate dielectric cap 3404 present along the sidewall of sacrificial placeholder 3406 in the nFET region of the wafer 202). As shown in FIGS. 42A-C, the gate dielectric 3402 and gate dielectric cap 3404 are now present only in the pFET region of the wafer 202. As provided above, in one exemplary implementation, both the hardmask 3602 and the gate dielectric cap 3404 are formed from a nitride material. In that case, a nitride-selective etching process can be employed to remove the hardmask 3602 and the exposed gate dielectric cap 3404 in a single step.

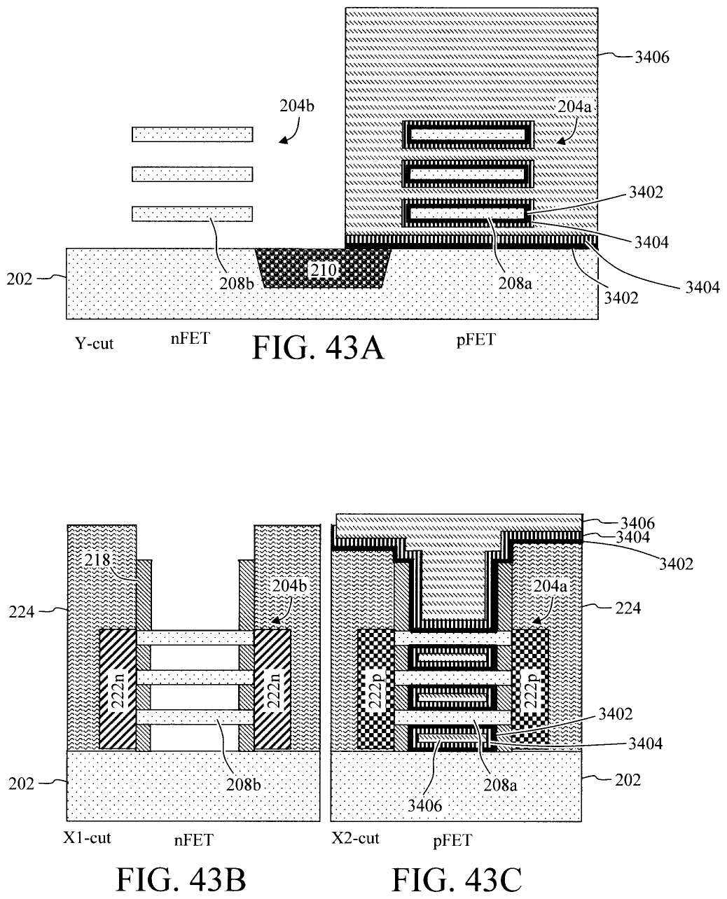

As shown in FIG. 43A (a Y cross-sectional view), FIG. 43B (an X1 cross-sectional view), and FIG. 43C (an X2 cross-sectional view), the now-exposed sacrificial layers 206b in the device stack 204b are then removed selective to the active layers 208b. According to an exemplary embodiment, sacrificial layers 206b are formed from SiGe, while active layers 208b are formed from Si. In that case, etchants such as wet hot SC1, vapor phase HCl, vapor phase ClF₃ and/or other reactive clean processes can be employed to remove the sacrificial layers 206b selective to the active layers 208b. Removal of the sacrificial layers 206b releases the active layers 208b from the device stack 204b. As highlighted above, these ‘released’ active layers 208b will be used to form the channels of the nFET transistor(s).

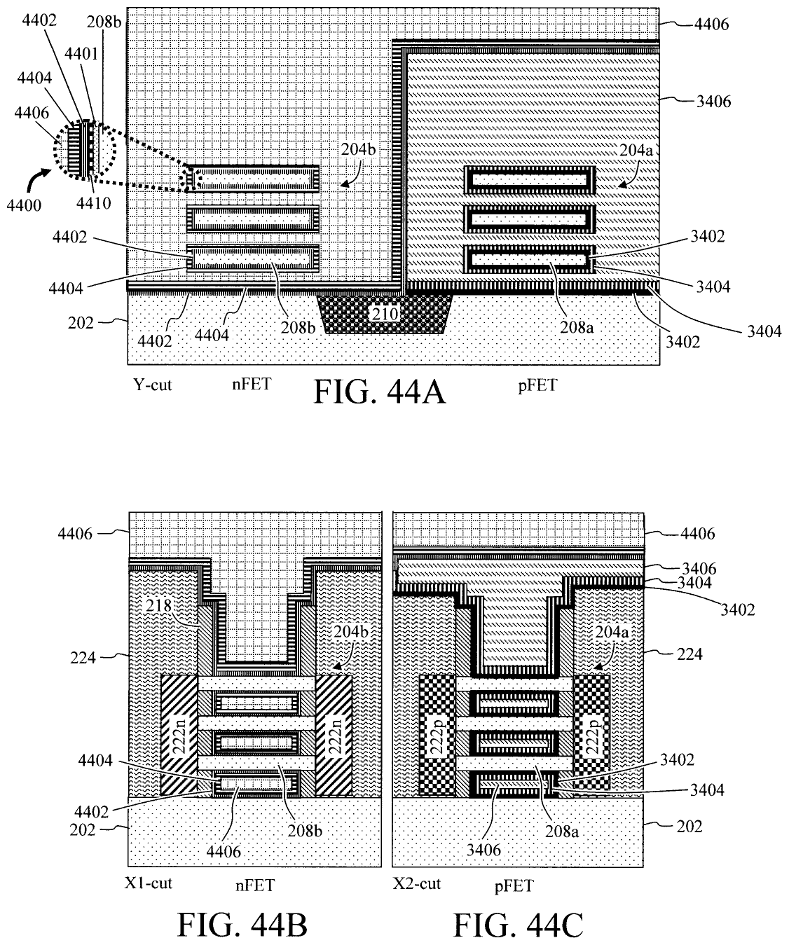

As shown in FIG. 44A (a Y cross-sectional view), FIG. 44B (an X1 cross-sectional view), and FIG. 44C (an X2 cross-sectional view), a (second) gate dielectric 4402 and a (second) gate dielectric cap 4404 are next deposited onto, and surrounding, the active layers 208b of the device stack 204b, and a (second) sacrificial placeholder 4406 is deposited over the gate dielectric 4402/gate dielectric cap 4404. As shown in FIGS. 44A-C, deposition of the gate dielectric 4402 and gate dielectric cap 4404 in this manner also deposits these materials on the exposed surface of the wafer 202 beneath the device stack 204b, as well as on the top and sidewalls of the sacrificial placeholder 3406 which is present over the device stack 204a.

Referring to magnified view 4400 in FIG. 44A, prior to depositing the gate dielectric 4402, a (second) interfacial layer 4401 is preferably first formed on the active layers 208b. Use of an interfacial layer 4401 improves the channel/gate dielectric interface quality and channel carrier mobility. Suitable materials for the interfacial layer 4401 include but are not limited to oxide materials such as SiOx. According to an exemplary embodiment, the interfacial layer 4401 has a thickness of from about 1 nm to about 3 nm and ranges therebetween.

According to an exemplary embodiment, the thickness and/or composition of the interfacial layer 4401 and/or the gate dielectric 4402 in the nFET transistor differs from the thickness and/or composition of the interfacial layer 3401 and/or the gate dielectric 3402 in the pFET transistor. For instance, an optional dipole layer 4410 can be deposited onto the interfacial layer 4401 prior to the gate dielectric 4402. A subsequent reliability anneal (see below) will also serve to diffuse the metal or metals from the dipole layer 4410 into the interfacial layer 4401 and gate dielectric 4402. Doing so can be used to tune the threshold voltage of the nFET transistor relative to the pFET transistor, or vice versa. As a result, the device will have different nFET and pFET threshold voltages. Suitable metals for the dipole layer 4410 include, but are not limited to, La, Y, Mg and/or Ga. By way of example only, the dipole layer 4410 can have a thickness of from about 0.5 Å to about 30 Å. Following the reliability anneal (performed below), the interfacial layer 4401 and the gate dielectric 4402 will each contain at least one dipole dopant, e.g., La, Y. Mg and/or Ga. Preferably, different dipole dopants are used in the pFET versus nFET interfacial layer/gate dielectric in order to achieve different threshold voltages.

Additionally, the interfacial layer 4401 and/or the gate dielectric 4402 in the nFET transistor can optionally receive different treatments (e.g., oxidation and nitridation) from the interfacial layer 3401 and/or the gate dielectric 3402 in the pFET transistor in order to improve device performance. For example, according to an exemplary embodiment, a nitridation treatment is performed on the interfacial layer 4401 and/or the gate dielectric 4402 in the nFET transistor before depositing the gate dielectric cap 4404 to boost the capacitance and thereby improve device performance. Thus, in one exemplary embodiment, the nFET interfacial layer 4401 contains nitrogen (N) to form for example SiON, whereas the pFET interfacial layer 3401 is nitrogen-free SiO₂.

Furthermore, even if the same material (e.g., HfO₂) is used as the gate dielectric 4402 in the nFET transistor and as the gate dielectric 3402 in the pFET transistor, embodiments are contemplated herein where the gate dielectric 4402 used in the nFET transistor is thicker than gate dielectric 3402 used in the pFET transistor. For example, as will be described in detail below, the thickness of the nFET gate dielectric 4402 is preferably from about 1 Å to about 2 Å greater than the thickness of the pFET gate dielectric 3402.

According to an exemplary embodiment, the gate dielectric 4402 is a high-K material such as HfO₂, La₂O₃, HfLaO₂, HfZrO₂ and/or HfAlO₂ and has a thickness of from about 1 nm to about 5 nm and ranges therebetween. A process such as CVD, ALD or PVD can be employed to deposit the gate dielectric 4402. As highlighted above, the composition of the gate dielectric 4402 can differ from that of the gate dielectric 3402. For instance, according to an exemplary embodiment, the (nFET) gate dielectric 4402 is HfLaO₂, whereas the (pFET) gate dielectric 3402 is HfZrO₂ and/or HfAlOx. It is notable, however, that employing different pFET and nFET gate dielectrics 3402 and 4402, respectively, is not a requirement, and embodiments are contemplated herein where the gate dielectric 3402 and gate dielectric 4402 have the same composition and/or thickness as one another.

Suitable materials for the gate dielectric cap 4404 include, but are not limited to, metal nitrides such as TiN and/or TaN, which can be deposited using a process such as CVD, ALD or PVD. According to an exemplary embodiment, the gate dielectric cap 4404 has a thickness of from about 2 nm to about 10 nm and ranges therebetween. The gate dielectric cap 4404 will serve to protect the gate dielectric 4402.

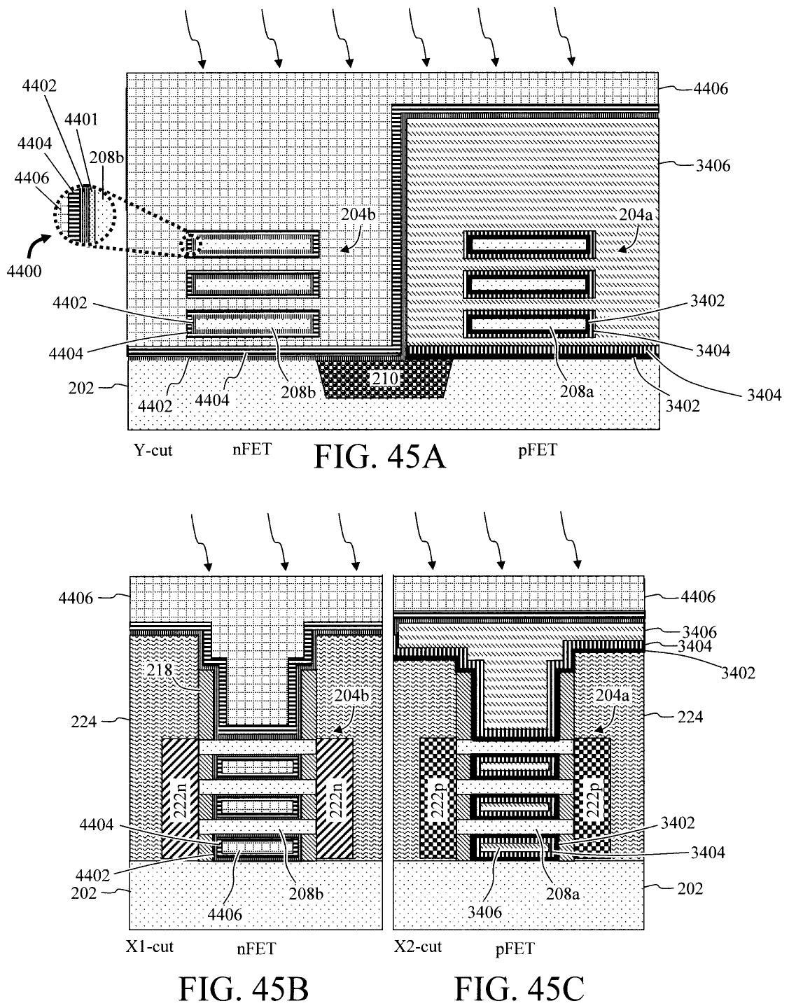

As shown in FIG. 45A (a Y cross-sectional view), FIG. 45B (an X1 cross-sectional view), and FIG. 45C (an X2 cross-sectional view), a reliability anneal is performed. According to an exemplary embodiment, the reliability anneal is performed at a temperature of from about 500° ° C. to about 1200° ° C. and ranges therebetween, for a duration of from about 1 nanosecond to about 30 seconds and ranges therebetween. Preferably, the reliability anneal is performed in the presence of an inert gas such as, but not limited to, nitrogen. As highlighted above, dipole layer 3410 and/or dipole layer 4410 can optionally be implemented in the pFET and nFET transistors, respectively. The reliability anneal serves to diffuse the metal or metals from the dipole layer 3410 and/or dipole layer 4410 into the interfacial layer 3401/gate dielectric 3402 and/or the interfacial layer 4401/gate dielectric 4402, respectively.

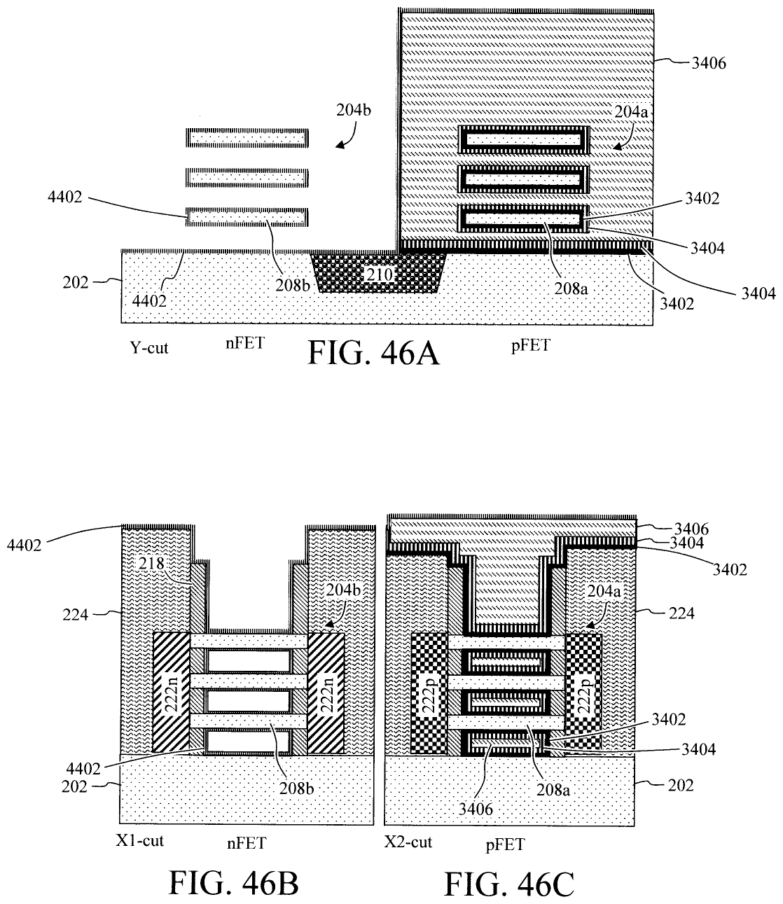

As shown in FIG. 46A (a Y cross-sectional view), FIG. 46B (an X1 cross-sectional view), and FIG. 46C (an X2 cross-sectional view), the sacrificial placeholder 4406 and the gate dielectric cap 4404 are then selectively removed from the nFET region of the wafer 202, exposing the underlying gate dielectric 4402. As provided above, the sacrificial placeholder 4406 can be formed from poly-silicon and/or amorphous silicon, and the gate dielectric cap 4404 can be formed from a metal nitride material such as TiN and/or TaN. In that case, a poly-silicon and/or amorphous silicon-selective etch can be employed to remove the sacrificial placeholder 4406, followed by a nitride-selective etch to remove the gate dielectric cap 4404. As shown in FIGS. 46A-C, the sacrificial placeholder 3406 remains over the device stack 204a in the pFET region of the wafer 202.

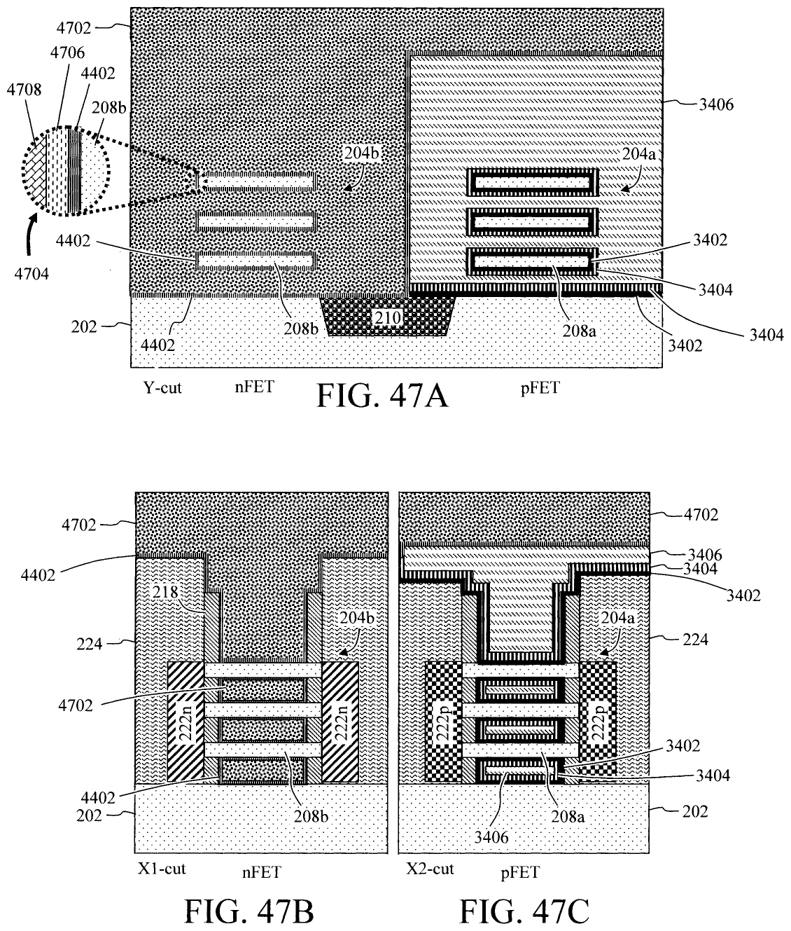

As shown in FIG. 47A (a Y cross-sectional view), FIG. 47B (an X1 cross-sectional view), and FIG. 47C (an X2 cross-sectional view), an nFET gate electrode 4702 is formed on the gate dielectric 4402 surrounding a portion of each of the active layers 208b in a gate all around configuration. As shown in magnified view 4704 in FIG. 47A, nFET gate electrode 4702 includes at least one workfunction-setting metal 4706 disposed on the gate dielectric 4402, and an optional (low-resistance) fill metal 4708 disposed on the workfunction-setting metal(s) 4706.

Suitable (n-type) workfunction-setting metals 4706 include, but are not limited to, TiN, TaN and/or Al-containing alloys such as TiAl, TiAlN, TiAlC, TaAl, TaAlN, and/or TaAlC. It is notable, however, that this is not an exhaustive list and that these workfunction-setting metals are not meant to be exclusive to transistors of one polarity, e.g., TiAlC can be implemented as a workfunction-setting metal in both nFET and pFET transistors—see below. A process such as CVD, ALD or PVD can be employed to deposit the workfunction-setting metal(s) 4706. As will be described in detail below, the thickness and/or composition of the workfunction-setting metal(s) 4706 in the nFET transistor can differ from the thickness and/or composition of the workfunction-setting metal(s) in the pFET transistor (see below).

Suitable low-resistance fill metals 4708 include, but are not limited to, W, Co, Ru and/or Al. The low-resistance fill metals 4708 can be deposited using a process or combination of processes including, but not limited to, CVD, ALD, PVD, sputtering, plating, evaporation, ion beam deposition, electron beam deposition, laser assisted deposition, chemical solution deposition, etc.

As such, according to the above-described exemplary embodiment, the nFET replacement metal gate includes an interfacial layer 4401 disposed on the active layers 208b of the device stack 204b (in the nFET region of the wafer 202), the gate dielectric 4402 surrounding the active layers 208b over the interfacial layer 4401, and the gate electrode 4702 disposed on the gate dielectric 4402 surrounding a portion of each of the active layers 208b in a gate all around configuration. The gate electrode 4702 includes the at least one of workfunction-setting metal 4706 disposed on the gate dielectric 4402, and the optional (low-resistance) fill metal 4708 disposed on the workfunction-setting metal(s) 4706.

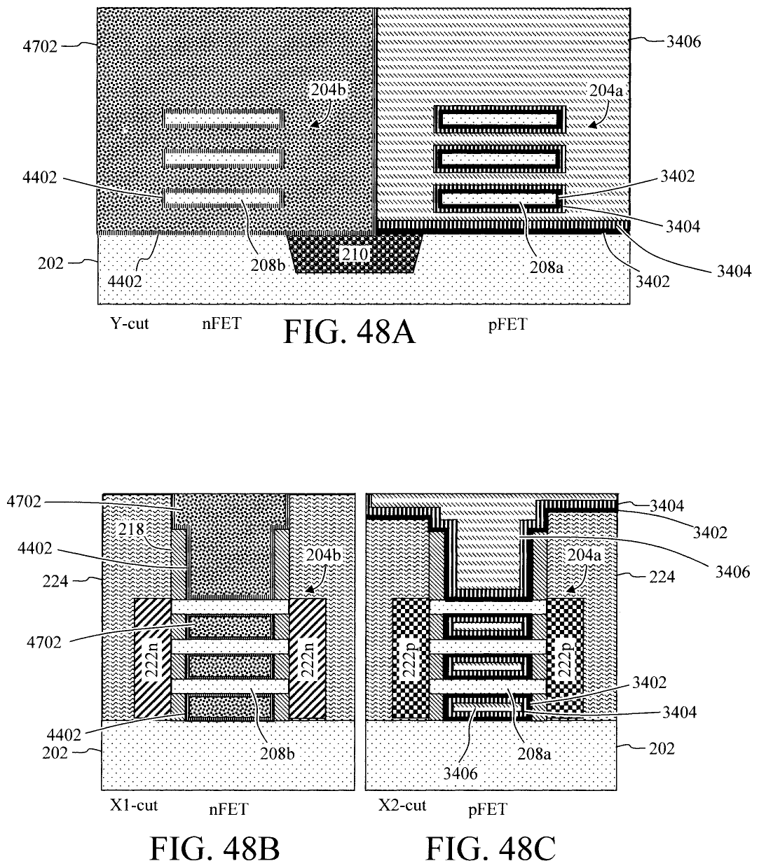

As shown in FIGS. 47A-C, the as-deposited nFET gate electrode 4702 extends over the pFET region of the wafer 202. However, a recess of the nFET gate electrode 4702 is next performed to remove the overburden from the pFET region of the wafer 202. Namely, as shown in FIG. 48A (a Y cross-sectional view), FIG. 48B (an X1 cross-sectional view), and FIG. 48C (an X2 cross-sectional view), the nFET gate electrode 4702 and gate dielectric 4402 are recessed down to the sacrificial placeholder 3406. This recessing of the nFET gate electrode 4702 and gate dielectric 4402 can be performed using a process such as chemical mechanical polishing or reactive ion etching.

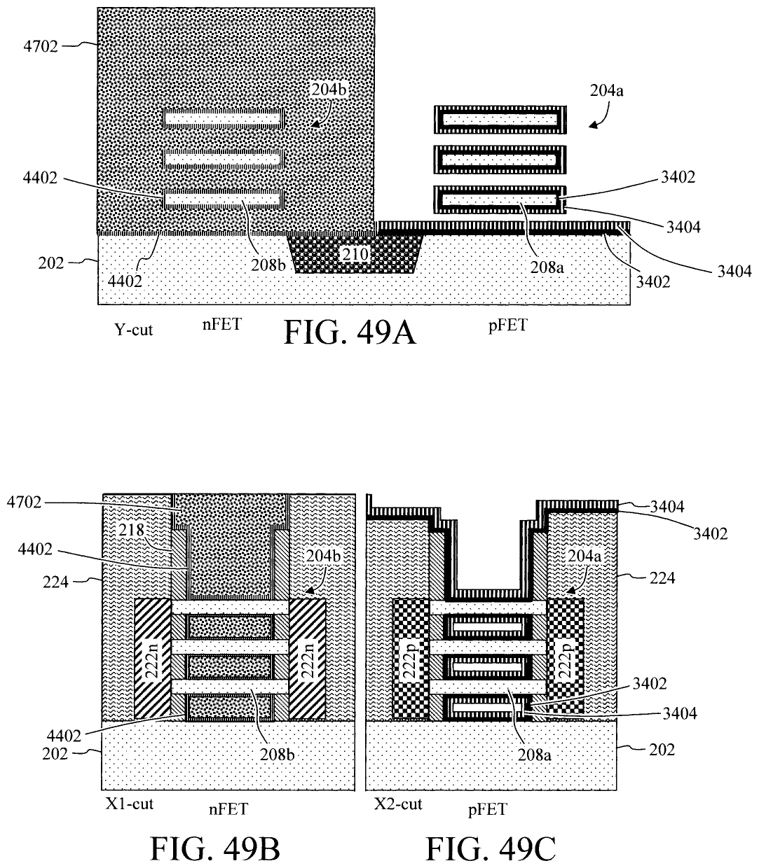

Removal of the nFET gate electrode 4702 and gate dielectric 4402 from the pFET regions of the wafer 202 exposes the underlying sacrificial placeholder 3406 which, as shown in FIG. 49A (a Y cross-sectional view), FIG. 49B (an X1 cross-sectional view), and FIG. 49C (an X2 cross-sectional view), is then selectively removed, exposing portions of the gate dielectric 4402 along the sidewall of the nFET gate electrode 4702, which are also removed. As provided above, the sacrificial placeholder 3406 can be formed from poly-silicon and/or amorphous silicon, and the gate dielectric 4402 can be formed from HfO₂ and/or La₂O₃. In that case, a poly-silicon and/or amorphous silicon-selective etch can be employed to remove the sacrificial placeholder 3406, followed by an oxide-selective etching process to remove the exposed gate dielectric 4402.

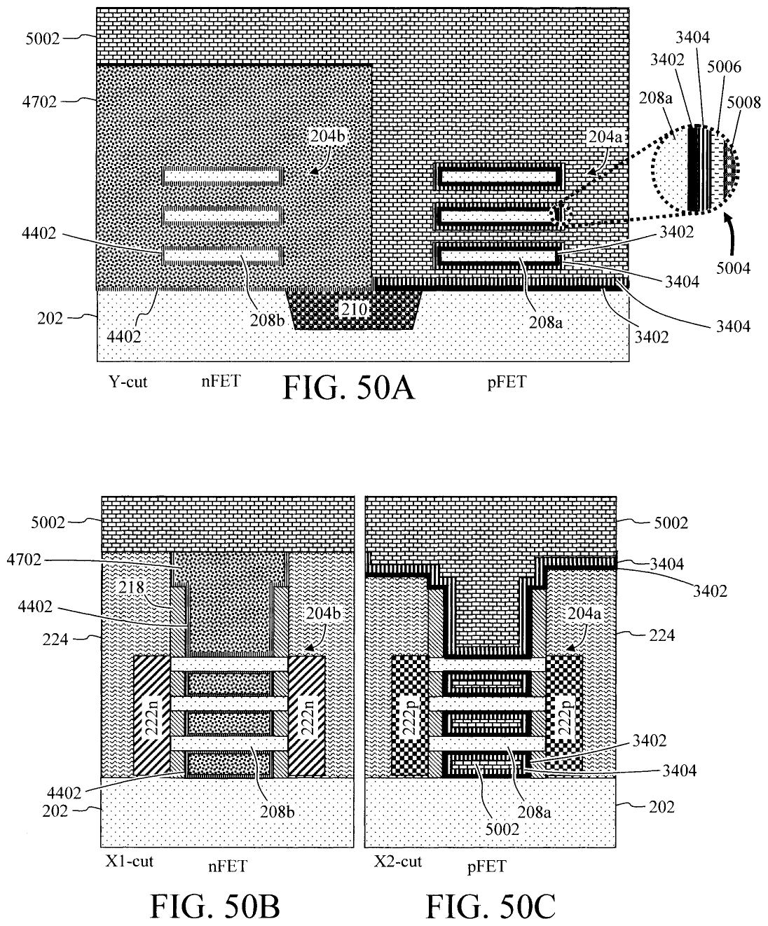

As shown in FIG. 50A (a Y cross-sectional view), FIG. 50B (an X1 cross-sectional view), and FIG. 50C (an X2 cross-sectional view), a pFET gate electrode 5002 is formed on the gate dielectric 3402/gate dielectric cap 3404 surrounding a portion of each of the active layers 208a in a gate all around configuration. For clarity, the terms ‘first’ and ‘second’ may also be used herein when referring to pFET gate electrode 5002 and nFET gate electrode 4702, respectively. As shown in magnified view 5004 in FIG. 50A, pFET gate electrode 5002 includes at least one workfunction-setting metal 5006 disposed on the gate dielectric cap 3404, and an optional (low-resistance) fill metal 5008 disposed on the workfunction-setting metal(s) 5006. For clarity, the terms ‘first’ and ‘second’ may also be used herein when referring to workfunction-setting metal(s) 5006 and workfunction-setting metal(s) 4706, respectively.

Suitable (p-type) workfunction-setting metals 5006 include, but are not limited to, TiN, TaN, and/or W. TiN and TaN are relatively thick (e.g., greater than about 2 nm) when used as p-type workfunction-setting metals. However, very thin TiN or TaN layers (e.g., less than about 2 nm) may also be used beneath Al-containing alloys in n-type workfunction-setting stacks to improve electrical properties such as gate leakage currents. Thus, there is some overlap in the exemplary n- and p-type workfunction-setting metals given above. A process such as CVD, ALD or PVD can be employed to deposit the workfunction-setting metal(s) 5006.

Notably, as highlighted above, the present techniques advantageously enable tuning of both the gate dielectric and replacement metal gate materials (or combination of materials) in terms of composition, thicknesses, etc. fully separately in the pFET and nFET transistors since there is no overlap in materials between the pFET and nFET replacement metal gates. For example, the workfunction-setting metal(s) 5006 used in the pFET transistor are wholly distinct from those workfunction-setting metal(s) 4706 used in the nFET transistor. This selective tuning of the workfunction-setting metals 4706 and 5006 can also be coupled with the selection of interfacial layers 3401 and 4401 and/or gate dielectrics 3402 and 4402 that are unique (in composition, thickness, etc.) to the pFET and nFET transistors as described in detail above. Even in instances where some of the (nFET) workfunction-setting metal(s) 4706 and the (pFET) workfunction-setting metal(s) 5006 are the same, they are not continuously extended from one polarity to another.

According to an exemplary embodiment, the workfunction-setting metal(s) 4706 in the nFET transistor differ in composition and/or thickness from the workfunction-setting metal(s) 5006 in the pFET transistor, and vice versa. For instance, to use an illustrative, non-limiting example, both the workfunction-setting metal(s) 4706 in the nFET transistor and the workfunction-setting metal(s) 5006 in the pFET transistor can both include TiAlC. However, the thickness of the TiAlC in the pFET is preferably less than the thickness of the TiAlC in the nFET. Further, when used as the pFET workfunction-setting metal, the concentration of Al in the TiAlC is preferably lower than when it is used as nFET workfunction-setting metal. In another, non-limiting example, TiN/TiAlC/TIN can be employed as both the workfunction-setting metal(s) 4706 in the nFET transistor and as the workfunction-setting metal(s) 5006 in the pFET transistor. However, when used as the workfunction-setting metal(s) 4706 in the nFET transistor, 0.5 nmTiN/3 nm TiAlC/3 nm TiN may be implemented, whereas when used as the workfunction-setting metal(s) 5006 in the pFET transistor, 5 nm TiN/2 nm TiAlC/4 nm TiN may be implemented.

Suitable low-resistance fill metals 5008 include, but are not limited to, W, Co, Ru and/or Al. The low-resistance fill metal 5008 can be deposited using a process or combination of processes including, but not limited to, CVD, ALD, PVD, sputtering, plating, evaporation, ion beam deposition, electron beam deposition, laser assisted deposition, chemical solution deposition, etc.

According to the above-described exemplary embodiment, the pFET replacement metal gate includes an interfacial layer 4401 disposed on the active layers 208a of the device stack 204a (in the pFET region of the wafer 202), the gate dielectric 4402 surrounding the active layers 208a over the interfacial layer 4401, and the gate electrode 5002 disposed on the gate dielectric 4402 surrounding a portion of each of the active layers 208a in a gate all around configuration. The gate electrode 5002 includes the at least one of workfunction-setting metal 5006 disposed on the gate dielectric 4402, and the optional (low-resistance) fill metal 5008 disposed on the workfunction-setting metal(s) 5006.

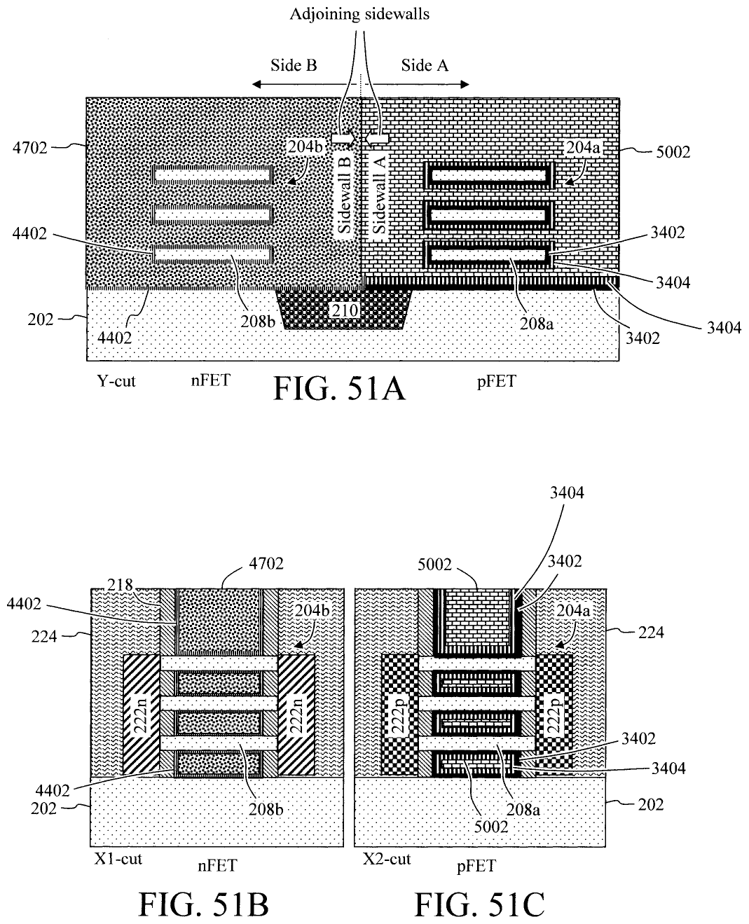

As shown in FIGS. 50A-C, the as-deposited pFET gate electrode 5002 extends over the nFET region of the wafer 202. However, a recess of the pFET gate electrode 5002 is next performed to remove the overburden from the nFET region of the wafer 202. Namely, as shown in FIG. 51A (a Y cross-sectional view), FIG. 51B (an X1 cross-sectional view), and FIG. 51C (an X2 cross-sectional view), the pFET gate electrode 5002 is recessed down to the nFET gate electrode 4702 using a process such as chemical mechanical polishing or reactive ion etching.

As shown in FIGS. 51A-C, the nFET gate electrode 4702 directly contacts the pFET gate electrode 5002. Notably, however, the nFET gate electrode 4702 and the pFET gate electrode 5002 are in a non-vertically-overlapping position relative to one another and thus are not continuously extended from the nFET to pFET. To look at it another way, the nFET gate electrode 4702 and the pFET gate electrode 5002 have a single and continuous pair of vertically adjoining/directly-contacting sidewalls (see, e.g., sidewall A of the pFET gate electrode 5002 and sidewall B of the nFET gate electrode 4702 in FIG. 51A). Notably, since they do not overlap, the pFET gate electrode 5002 is present exclusively to a side (A) of the sidewall A opposite sidewall B, and the nFET gate electrode 4702 is present exclusively to a side (B) of the sidewall B opposite sidewall A. This would not be the case if any of the materials in the nFET gate electrode 4702 or the pFET gate electrode 5002 overlapped one another vertically, since that would result in both vertical and horizontal junctions.

Further, as shown, e.g., in FIGS. 51B-C the pFET and nFET transistors each includes source/drain regions 222p and 222n on opposite sides of the pFET gate electrode 5002 and the nFET gate electrode 4702, and a stack of active layers 208a and 208b interconnecting the source/drain regions 222p and 222n, respectively. Notably, the pFET gate electrode 5002 and the nFET gate electrode 4702 surround a portion of each of the active layers 208a and 208b, respectively, in a gate all around configuration which enhances device performance. In the pFET transistor, both the gate dielectric 3402 and the gate dielectric cap 3404 are disposed on the stack of active layers 208a beneath the pFET gate electrode 5002. In the nFET transistor, the gate dielectric 4402 is disposed on the stack of active layers 208b beneath the nFET gate electrode 4702. Thus, the gate dielectric cap 3404 is present only in the pFET transistor.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A semiconductor device, comprising:
a wafer; and
at least a first transistor of a first polarity and a second transistor of a second polarity on the wafer, wherein a gate electrode of the first transistor and a gate electrode of the second transistor have a single pair of vertically adjoining sidewalls.

2. The semiconductor device of claim 1, wherein the single pair of vertically adjoining sidewalls comprises a sidewall A of the gate electrode of the first transistor that directly contacts a sidewall B of the gate electrode of the second transistor.

3. The semiconductor device of claim 2, wherein the gate electrode of the first transistor is present exclusively to a side of the sidewall A opposite the sidewall B, and wherein the gate electrode of the second transistor is present exclusively to a side of the sidewall B opposite the sidewall A.

4. The semiconductor device of claim 1, wherein either the first transistor comprises a p-channel field-effect transistor (pFET) and the second transistor comprises an n-channel field-effect transistor (nFET), or the first transistor comprises an nFET and the second transistor comprises a pFET.

5. The semiconductor device of claim 1, wherein the gate electrode of the first transistor comprises at least one first workfunction-setting metal and the gate electrode of the second transistor comprises at least one second workfunction-setting metal, and wherein the at least one first workfunction-setting metal is different from the at least one second workfunction-setting metal.

6. A semiconductor device, comprising:
a wafer; and
at least a first transistor of a first polarity and a second transistor of a second polarity on the wafer, wherein the first transistor comprises a stack of first active layers and a first gate electrode that surrounds a portion of each of the first active layers, wherein the second transistor comprises a stack of second active layers and a second gate electrode that surrounds a portion of each of the second active layers, and wherein the first gate electrode and the second gate electrode have a single pair of vertical adjoining sidewalls.

7. The semiconductor device of claim 6, wherein the single pair of vertical adjoining sidewalls comprises a sidewall A of the first gate electrode that directly contacts a sidewall B of the second gate electrode, wherein the first gate electrode is present exclusively to a side of the sidewall A opposite the sidewall B, and wherein the second gate electrode is present exclusively to a side of the sidewall B opposite the sidewall A.

8. The semiconductor device of claim 6, wherein the first gate electrode comprises at least one first workfunction-setting metal and the second gate electrode comprises at least one second workfunction-setting metal, and wherein the at least one first workfunction-setting metal is different from the at least one second workfunction-setting metal.

9. A semiconductor device, comprising:
a wafer; and
at least a first transistor of a first polarity and a second transistor of a second polarity on the wafer, wherein the first transistor comprises a stack of first active layers, a first interfacial layer disposed on the stack of first active layers, a first gate dielectric disposed on the first interfacial layer, and a first gate electrode disposed on the first gate dielectric and which surrounds a portion of each of the first active layers, wherein the second transistor comprises a stack of second active layers, a second interfacial layer disposed on the stack of second active layers, a second gate dielectric disposed on the second interfacial layer, and a second gate electrode disposed on the second gate dielectric and which surrounds a portion of each of the second active layers, and wherein the first gate electrode and the second gate electrode have a single pair of vertically adjoining sidewalls.

10. The semiconductor device of claim 9, wherein the single pair of vertically adjoining sidewalls comprises a sidewall A of the first gate electrode that directly contacts a sidewall B of the second gate electrode, wherein the first gate electrode is present exclusively to a side of the sidewall A opposite the sidewall B, and wherein the second gate electrode is present exclusively to a side of the sidewall B opposite the sidewall A.

11. The semiconductor device of claim 9, wherein the first interfacial layer has at least one of a different composition and a different thickness from the second interfacial layer.

12. The semiconductor device of claim 9, wherein the first gate dielectric has at least one of a different composition and a different thickness from the second gate dielectric.

13. The semiconductor device of claim 9, wherein the first interfacial layer comprises at least one different dipole dopant from the second interfacial layer.

14. The semiconductor device of claim 9, wherein the first gate dielectric comprises at least one different dipole dopant from the second gate dielectric.

15. The semiconductor device of claim 9, wherein the first gate electrode comprises at least one first workfunction-setting metal and the second gate electrode comprises at least one second workfunction-setting metal, and wherein the at least one first workfunction-setting metal is different from the at least one second workfunction-setting metal.

16. A semiconductor device, comprising:
a wafer; and
at least a first transistor of a first polarity and a second transistor of a second polarity on the wafer, wherein the first transistor comprises a stack of first active layers, a first gate electrode that surrounds a portion of each of the first active layers, and both a first gate dielectric and a gate dielectric cap disposed on the stack of first active layers beneath the first gate electrode, wherein the second transistor comprises a stack of second active layers, a second gate electrode that surrounds a portion of each of the second active layers, and a second gate dielectric disposed on the stack of second active layers beneath the second gate electrode, and wherein the first gate electrode and the second gate electrode have a single pair of vertically adjoining sidewalls.

17. The semiconductor device of claim 16, wherein the single pair of vertically adjoining sidewalls comprises a sidewall A of the first gate electrode that directly contacts a sidewall B of the second gate electrode, wherein the first gate electrode is present exclusively to a side of the sidewall A opposite the sidewall B, and wherein the second gate electrode is present exclusively to a side of the sidewall B opposite the sidewall A.

18. The semiconductor device of claim 16, wherein the gate dielectric cap is present only in the first transistor.

19. The semiconductor device of claim 16, wherein the gate dielectric cap comprises a material selected from the group consisting of: TiN, TaN, and combinations thereof.

20. A method of fabricating a semiconductor device, the method comprising:
forming at least a first transistor of a first polarity and a second transistor of a second polarity on a wafer, wherein the first transistor comprises a first gate electrode, wherein the second transistor comprises a second gate electrode, and wherein the first gate electrode and the second gate electrode have a single pair of vertically adjoining sidewalls.

21. The method of claim 20, wherein the single pair of vertically adjoining sidewalls comprises a sidewall A of the first gate electrode that directly contacts a sidewall B of the second gate electrode, wherein the first gate electrode is present exclusively to a side of the sidewall A opposite the sidewall B, and wherein the second gate electrode is present exclusively to a side of the sidewall B opposite the sidewall A.

22. The method of claim 20, wherein the forming comprises:
forming at least a first device stack and a second device stack on a wafer, wherein the first device stack and the second device stack each comprises alternating active layers and sacrificial layers;
forming a sacrificial gate over the first device stack and the second device stack using a sacrificial hardmask;
selectively opening the sacrificial gate hardmask over the first device stack;
selectively removing the sacrificial gate and the sacrificial layers from the first device stack;
forming a first gate dielectric on the active layers of the first device stack;
depositing a first sacrificial placeholder over the first gate dielectric;
removing the sacrificial gate hardmask from over the second device stack;
selectively removing the sacrificial gate and the sacrificial layers from the second device stack;
forming a second gate dielectric on the active layers of the second device stack;
depositing a second sacrificial placeholder over the second gate dielectric;
performing a reliability anneal;
removing the second sacrificial placeholder;
forming the second gate electrode over the second gate dielectric that surrounds a portion of each of the active layers in the second device stack;
removing the first sacrificial placeholder; and
forming the first gate electrode over the first gate dielectric that surrounds a portion of each of the active layers in the first device stack.

23. The method of claim 22, wherein the first sacrificial placeholder and the second sacrificial placeholder are each formed from a material selected from the group consisting of: poly-silicon, amorphous silicon, and combinations thereof.

24. The method of claim 20, wherein the forming comprises:
forming at least a first device stack and a second device stack on a wafer, wherein the first device stack and the second device stack each comprises alternating active layers and sacrificial layers;
forming a sacrificial gate over the first device stack and the second device stack using a sacrificial gate hardmask;
fully removing the sacrificial gate hardmask;
forming a masking layer on the sacrificial gate;
selectively opening the masking layer and the sacrificial gate over the first device stack;
selectively removing the sacrificial layers from the first device stack;
forming a first gate dielectric on the active layers of the first device stack;
depositing a first sacrificial placeholder over the first gate dielectric;
removing the masking layer and the sacrificial gate from over the second device stack;
selectively removing the sacrificial layers from the second device stack;
forming a second gate dielectric on the active layers of the second device stack;
depositing a second sacrificial placeholder over the second gate dielectric;
performing a reliability anneal;
removing the second sacrificial placeholder;
forming the second gate electrode over the second gate dielectric that surrounds a portion of each of the active layers in the second device stack;
removing the first sacrificial placeholder; and
forming the first gate electrode over the first gate dielectric that surrounds a portion of each of the active layers in the first device stack.

25. The method of claim 24, wherein first sacrificial placeholder and the second sacrificial placeholder are each formed from a material selected from the group consisting of: poly-silicon, amorphous silicon, and combinations thereof, and wherein the masking layer is formed from amorphous silicon.
